(19) United States
(12) Patent Application Publication
(10) Pub. No.: US 2024/0413829 A1
(43) Pub. Date: Dec. 12, 2024

(54) METHODS AND APPARATUSES FOR RYDBERG EXCITATION, SPECTROSCOPY, AND QUANTUM TECHNOLOGY, AND IMPROVEMENTS IN RECEIVING AND TRANSMITTING ELECTROMAGNETIC WAVES AND SIGNALS AND ATOM RADIO COMMUNICATION APPARATUSES THEREFOR

(71) Applicant: Rydberg Technologies Inc., Ann Arbor, MI (US)

(72) Inventors: David A. ANDERSON, Ann Arbor, MI (US); Georg RAITHEL, Ann Arbor, MI (US)

(21) Appl. No.: 18/735,450

(22) Filed: Jun. 6, 2024

Related U.S. Application Data
(60) Provisional application No. 63/471,519, filed on Jun. 7, 2023.

(51) Int. Cl. H03L 7/26; H03C 7/02

(52) U.S. Cl. CPC H03L 7/26; H03C 7/02

(57) ABSTRACT

The present disclosure relates to atomic quantum and photonic apparatuses and methods, for example, atomic radio apparatuses and methods. The disclosure describes various aspects of atomic radio. More specifically, the disclosure describes an atomic radio apparatus and associated hardware. Methods for performing radio communications, sensing, and imaging, are described. The disclosure further describes laser, optical, photonics, atom-photonics, and hybrid micro-integrated subsystems for Rydberg excitation, spectroscopy, and quantum technology.

### CROSS REFERENCE TO RELATED APPLICATION

This application claims priority to U.S. Provisional Application No. 63/471,519, filed Jun. 7, 2023, which is hereby incorporated herein in its entirety by reference.

This invention was made with government support under contract HR00112190065 awarded by Defense Advanced Research Projects Agency (DARPA). This invention was made with government support under contract HQ08452192004 awarded by National Security Innovation Capital (NSIC). The government has certain rights in the invention.

### FIELD

The present disclosure relates to atomic quantum, photonic, and laser apparatuses and methods, for example, atom-based radio apparatuses and methods and laser and photonic subsystems.

### BACKGROUND

Rydberg atom technology harnesses atoms and light for the detection and generation of electromagnetic fields across the electromagnetic spectrum from DC to THz frequencies with broad capabilities relevant to many application domains. Atom-based electromagnetic radiation electric-field and power sensing, measurement, and imaging by measuring the electric field of electromagnetic radiation using the spectroscopic responses of Rydberg atoms to the electromagnetic radiation field has been realized (U.S. application Ser. No. 15/783,419, filed Jun. 15, 2016, now U.S. Pat. No. 9,970,973, claiming priority to U.S. Provisional Application No. 62/175,805, which are hereby incorporated herein in their entireties by reference). Methods and apparatuses have also been invented for sensing or measuring electromagnetic fields with Rydberg atoms, including time-varying electric field amplitude, frequency, and phase, and modulated fields and RF waveforms, including apparatuses such as atom probes and detectors or array of detectors (U.S. application Ser. No. 16/222,384, filed Dec. 17, 2018, now U.S. Pat. No. 10,823,775, claiming priority to U.S. Provisional Application Nos. 62/607,034 and 62/727,764, which are hereby incorporated herein in their entireties by reference). Atom-based closed-loop control methods for operational function of Rydberg atom sensor and technologies have since been established, such as applying one or more signal processing functions to the one or more Rydberg states, and regulating a characteristic of the applied one or more signal processing functions based on, at least in part, a response of the one or more Rydberg states to the one or more signal processing functions. An atomic receiver and transmitter, and a transceiver based on Rydberg atoms, an RF phase-sensitive Rydberg atom sensor, quantum-state RF interferometry, atom-based automatic level control, baseband processors, phase-locked loops, voltage transducers, raster RF imagers and waveform analyzers have also been developed (U.S. application Ser. No. 17/333,503, filed May 28, 2021, now U.S. Pat. No. 11,592,469, claiming priority to U.S. Provisional Application Nos. 63/077,244 and 63/032,041, which are hereby incorporated herein in their entireties by reference). Rydberg atom technology has advanced rapidly from new fundamental capabilities demonstrated. Further advances in methods and apparatus and designs for Rydberg atom technologies are needed to realize new capabilities, hardware, and software for deployable devices.

### SUMMARY

Accordingly, the advancement of new sensing performance capabilities to address various application domains demands a need for device architectures and hardware modalities to make quantum atomic and photonic Rydberg atom-based devices and devices for the spectroscopy of Rydberg states of atoms and molecules.

In this disclosure, new methods and apparatuses for Rydberg atom technologies are described including a millimeter-wave atomic sensor and receiver with phase-sensitivity, Rydberg lasers and photonics for Rydberg excitation and spectroscopy in Rydberg atom quantum technologies including sensing, measurement, metrology, imaging, communications, radar, synthetic apertures, quantum computing, networking, security, quantum key distribution, deterministic single photon generation involving Rydberg states of atoms.

A general Rydberg atom-based device architecture and modality requires a number of aspects including: (1) capability to meet technical performance specifications such as high stability and agility of laser parameters for Rydberg spectroscopy such as wavelength, frequency, phase, amplitude, polarization, and power, (2) a reduction in size, weight, and electrical power consumption (SWaP) for the physical use, implementation, and/or integration as a sub-component of other systems devices, and (3) sufficient robustness in operational environments, including being tolerant to environmental temperature, humidity, shock, vibration, and other conditions caused by external human and non-human environmental factors. Finally, the new hardware modality for subcomponents and fully integrated devices and systems should also be designed for scalability to higher volume manufacturing at lower cost of goods sold using developed manufacturing processes and techniques.

In some embodiments, an atom radio apparatus comprises Rydberg atoms sending or receiving an electromagnetic signal, a conduit carrying signals to or from the atoms to or from a front-end, a front-end that includes a reference local oscillator field and hardware for light generation for Rydberg excitation, readout, or spectroscopy and detectors for signal readout, a control unit to change a parameter of the radio such as frequency/channel tuning with the local oscillator, a digital signal processor, and an interface for input and output of signals. Electromagnetic wave signals and waveforms including continuous-wave, amplitude, frequency, phase, polarization, and direction modulation, are sent or received by the radio apparatus.

In some embodiments, an atom radio comprises atoms to transmit and or receive electromagnetic signals, a conduit to transfer signal information to/from the atoms from/to a front-end, a front-end configured to generate and send/receive a signal through the conduit to/from the atoms, a controller to adjust at least one parameter of the radio front-end, a signal processor for signal processing such as modulation or demodulation, and an interface to input/output signal information. A front-end may include, for example, one or more laser sources and or photonics to generate light sent to the atoms for spectroscopy, a signal generator such as a voltage-controlled oscillator to generate RF signals, and or a detector to detect signals derived from the atoms.

In some embodiments, two or more atom radio apparatuses transmit and receive signals to one another forming a communication link, system, or network. Two or more radio apparatuses are configured such as by being tuned to amplitude, phase, or frequency-match between transmitter and receiver.

In some embodiments, an atom radio apparatus sends and or receives multiple signals in a multiple-in multiple-out (MIMO) configuration.

In some embodiments, an atom radio apparatus sends and or receives signals to and or from a base station.

In some embodiments, an atom radio receiver (ARX) device comprises atoms, an atomic detector, aperture, front-end, and back-end for signal reception based on atoms in Rydberg states.

In some embodiments, an atom sensor or radio receiver comprises atoms to transmit or receive with adjustable or fixed parameters including RF frequency tuning, sensitivity, linear dynamic range, non-linear, P1dB compression, IP2, IP3, intermodulation distortion (IMD), selectivity, channel rejection ratio, bandwidth, instantaneous bandwidth, filter, filter roll-off, or filter shape factor.

In some embodiments, an atom radio sensor and receiver for long-wavelength signal sensing and reception comprises atoms to receive electromagnetic signals in the UHF-band, VHF-band, HF-band and below, a conduit to transfer signal information to/from the atoms from/to a front-end, a front-end configured to generate and send/receive a signal through the conduit to/from the atoms, a controller to adjust at least one parameter of the radio front-end, a signal processor for signal processing such as modulation or demodulation, and an interface to input/output signal information. A front-end may include, for example, one or more laser sources and or photonics to generate light sent to the atoms for spectroscopy, a signal generator such as a voltage-controlled oscillator to generate RF signals such as local oscillators, and or a detector to detect optical or electronic signals derived from the atoms.

In some embodiments, a vapor cell probe or atom radio sensor and conduit apparatus comprises a vapor cell, an optical fiber conduit guiding light into and or out of the vapor cell, a supporting structure made of hard plastic or similar material housing fiber and or optics component in the vicinity of the cell to condition light, a long fiber for input and or output of light through the atomic gas.

In some embodiments, a Rydberg micro-integrated frequency-agile laser comprises (1) a semiconductor laser, such as an external-cavity diode laser (ECDL), a distributed feedback (DFB) laser diode, Fabry-Perot laser, fiber laser, injection locked laser, or a reflective semiconductor optical amplifier (RSOA) laser with piezoelectrical actuators on ultra-low loss silicon nitride photonic integrated circuits with micro-resonator Vernier filters, (2) a laser-light conditioning sub-unit that includes an electronically-controlled laser wavelength tuning element such as an electronically-controlled interference filter in a cats-eye laser architecture, a photonic integrated circuit with Vernier filters, an aluminum nitride (AlN) piezoelectric actuator for tuning optical resonance modes of silicon nitride photonic resonators, (3) a gain-stage or amplifier, (4) a wavelength multiplier such as a PPLN frequency doubler, (5) a modulator, (6) a photodetector. Combining Rydberg atom technology and Rydberg lasers and photonics with hybrid micro-integration technology (H. Christopher et al., “Narrow linewidth micro-integrated high power diode laser module for deployment in space,” 2017 IEEE International Conference on Space Optical Systems and Applications (ICSOS), Naha, Japan, 2017, pp. 150-153) with functional capabilities for Rydberg atom spectroscopy, sensing, and other applications. The micro-integrated optics or laser subsystem may include a micro-integrated cats-eye laser architecture or similar with electronic tuning of the filter or feedback or tuning element.

In some embodiments, a Rydberg laser system or apparatus comprises an atomic reference or optical cavity reference or similar reference, and one or more lasers for Rydberg excitation or spectroscopy, optics or photonics or electronic components, and a device such as a frequency-comb and or RF mixer electronics to transfer frequency-stability to or from one or more lasers and a reference. One of the lasers may be a frequency-agile laser tunable over more than 1 GHz and up to nanometers, with high power output >0.01 Watt with small <1 MHz linewidth for accessing Rydberg states of atoms. One of the lasers may be referenced to an optical frequency tracker or comb with a free-spectral range of MHz to GHz, and or to an Rydberg atom reference. The Rydberg laser system or apparatus may include a photonic integrated circuit or an optical or photonic micro-electromechanical system (MEMS) for one or more of laser light frequency stabilization, tuning, doubling or multiplying, as well as power amplification, optical isolation, power splitting, switching, beam steering, fiber coupling, atom coupling.

In some embodiments, a millimeter-wave Rydberg atom sensor or receiver comprises a Rydberg atom vapor, a reference field local oscillator at a millimeter-wave frequency, an atomic or optical cavity frequency-stabilized Rydberg laser system, a frequency-comb, and a photodetector or charge readout of a continuous or modulated millimeter-wave signal field at the atomic vapor.

In some embodiments, an atom quantum aperture front-end comprises an atomic vapor for the reception of an electromagnetic wave, an optic or fiber to guide light for spectroscopy on the atoms of the vapor modified by the electromagnetic wave, an optical signal conditioning circuit to modulate or filter the guided light, a detector or optical transducer to convert guided light into an electrical signal, an electrical signal conditioning circuit to mix, modulate, filter, or regulate the electrical signal derived from the light, and a processor circuit for processing the conditioned electrical signal.

In some embodiments, an atomic reference or chipspec comprises a single multi-component unit with a miniature atomic vapor cell containing an atomic gas such as alkali atoms, an integrated temperature regulator, a static or modulated electric or magnetic field, an optical component, and a photodetector. The atomic reference may be a single or monolithic unit package such as a butterfly package or similar with electrical contacts and connections to components within and an optical window or opening for light injection into the atoms and detection by the photodiode. The package may also include a light source within, such as a laser diode or narrow-linewidth laser such as a micro-integrated laser or photonically integrated laser, that is frequency-stabilized to the atomic reference and emits the stabilized light from the window of the package into free-space or coupled into an optical fiber. The laser light may be frequency-shifted or tuned by the laser current, external/grating/waveguide cavity, interference filter cats eye, and similar such as with a micro-integrated or photonic integrated circuit (PIC) Rydberg laser, or by frequency-stabilizing the laser to an atomic transition and modulating/modifying the atomic transition using electromagnetic fields or similar external parameters.

In some embodiments, an atomic reference or minisatspec comprises a chipspec, low-noise analog and/or digital electronics, and operating software.

In some embodiments an atomic sensor uses non-zero, substantially unidirectional atomic beams or atomic flow in EIT detection. Electrometry and RF sensing using non-zero velocity Rydberg EIT. Higher signal-to-noise Rydberg EIT lines (narrower linewidth, higher amplitude) for increased electric field and RF sensitivity and selectivity may be limited by interactions between atoms that cause line broadenings (many underlying mechanisms for atomic state perturbations such as atom-Rydberg, Rydberg-Rydberg, ion-Rydberg, background-Rydberg, etc.) and therewith reduced EIT signal qualities and sensitivities.

In some embodiments, a method to mitigate this (e.g., line broadenings, reduced EIT signal qualities and sensitivities) includes using non-zero, substantially single velocity atoms to avoid atom-atom interactions during EIT optical interrogation. For example, a probe (852 nm) laser is set off-resonant on the Doppler profile of the atomic vapor to select a single velocity class of atoms for the EIT. Rydberg EIT spectra may be obtained for counter-propagating two-photon EIT beams in a cesium vapor with the 852 nm and 510 nm light beams. The 852 nm light may be detuned to and from the zero-velocity atoms, with the 510 nm-laser detuning set to satisfy momentum conservation: k-vector (852 nm)+k-vector (atom velocity)-k-vector (510 nm)=0, such that EIT lines become taller and narrower away from zero-detuning. This is attributed to the fact that at the zero-detuning, zero-velocity atoms have the highest density and have no preferred direction of travel relative to one-another cause an increase in atom density and interaction-induced broadening and deterioration of the EIT line. Away from the zero-detuning point, the low-lying 6P/ground-state atom and excited Rydberg-state atom density is reduced, and the atoms/Rydberg atoms also share the same velocity vector, reducing interactions during EIT readout.

In one embodiment, an atomic sensor uses counter-propagating as well as co-propagating optical EIT beams. This also includes employing one or more standing-wave light beams (co- and counter-propagating light beams in the EIT readout from the atomic gas). The standing wave light beam can form an optical lattice. Reduced beam sizes and/or use higher velocity atoms to (A) increase transit time broadening—for, e.g., higher instantaneous bandwidth—and (B) reduce number of optical-lattice sites sampled by thermal atoms may decrease broadening and improve signal to noise (see broadening in regions 2 and 3). Interestingly, a traditional gain-bandwidth product limit no longer applies to this sensor.

In other embodiments, a micro-integrated Rydberg sensor comprises a wideband direction finding (DF) atomic antenna aperture for drone detection. Performance includes compact, sub-wavelength atomic antenna receiver elements, long-wavelength HF/VHF/UHF-band and wideband <1 MHz to 6 GHz and above detection, high resolution <10 degrees, high field of view to ±90 degrees, high intensity survivability, high long-term stability, no drift, no re-calibration.

In one embodiment, a micro-integrated Rydberg sensor comprises an HF-band atomic antenna that is compact, sub-wavelength, small RF footprint, high sensitivity/range, high intensity survivability, high long-term stability, no drift, no re-calibration.

Other embodiments include a multi-frequency/band Atomic Aperture and Receiver, wideband RF camera, whole-room millimeter-wave imager, RF source angle and velocity detector (direction finding and radar) and synthetic aperture radar.

In some embodiments, an atomic vapor cell fabrication process is one that includes a coating process in which one deposits by evaporation or other method a thin layer of borosilicate glass, such as borofloat or pyrex, or similar material that is conductive at temperature, onto a semiconductor, conductor, or insulating substrate to generate a material layer for anodically bonding the substrate part to a silicon or other other material part in, for example, the formation of a sealed gas vapor cell or vacuum compartment. The substrate could also have an antri-reflection coating that is non-conductive, or a conductive coating prior to the evaporation layer on top of the substrate. Evaporation may be done of other glass types that have not been done before such as aluminosilicate glass and ceramics such as sapphire, for decreasing helium permeability and decreasing charge build-up on dielectric and semi-conductor surfaces, respectively.

In some embodiments, the coupling between one quantum state and a second quantum Rydberg state, including for example a transition between two or more quantum Rydberg states, is used as a clock transition for the precise measurement of electromagnetic field frequency and time (e.g., a Rydberg atomic clock or frequency reference).

In some embodiments, an atom radio apparatus can include a compartment enclosing a gas of atoms in one or more excited states. In some embodiments, the gas of atoms can be configured to receive and/or transmit an electromagnetic radio signal. In some embodiments, the atom radio apparatus can further include a conduit coupled to the compartment and configured to transport electromagnetic, optical, or electronic signals to and/or from the gas of atoms. In some embodiments, the atom radio apparatus can further include a front-end coupled to the conduit and configured to generate and transmit an input electromagnetic, optical, or electronic signal to and/or receive an output electromagnetic, optical, or electronic signal from the gas of atoms. In some embodiments, the atom radio apparatus can further include a controller configured to adjust a parameter of the electromagnetic, optical, or electronic signal in the front-end sent to or received from the gas of atoms. In some embodiments, the atom radio apparatus can further include a signal processor connected to the front-end and configured to process electromagnetic, optical, or electronic input and output signals to and from the front-end. In some embodiments, the atom radio apparatus can further include a user interface and computer configured to control or monitor control signals, input signals, or output signals from the signal processor, controller, front-end, conduit, compartment, or the gas of atoms.

In some embodiments, an input electromagnetic signal can include a plurality of input electromagnetic signals.

In some embodiments, the input signal can include an electronic voltage signal, an electronic current signal, or an electromagnetic signal. In some embodiments, the electromagnetic signal can include an optical signal, a radio-frequency (RF) signal, a static field (DC) signal, a modulated signal, or a combination thereof.

In some embodiments, the conduit can include an electrical cable, a fiber optics cable, a conductor, a waveguide, a mode for free-space electromagnetic wave propagation, or a combination thereof.

In some embodiments, the front-end can include at least one of a photonic circuit, a light source, a frequency-stabilized laser, an isolator, a modulator, an amplifier, a frequency doubler, DC electronics, RF electronics, an atomic gas cell, a signal generator, a voltage-controlled oscillator, optics, a frequency comb, or a light detector. In some embodiments, the light detector can include a silicon photodetector.

In some embodiments, the input signal generated by the front-end and transmitted to the gas of atoms can include a local oscillator (LO) signal.

In some embodiments, electromagnetic, optical, or electronic signals in the conduit from the atoms can include an atomic response of the gas of atoms to one or more electromagnetic radio signals or electromagnetic waves.

In some embodiments, the input signal generated by the front-end and transmitted to the gas of atoms can be an electromagnetic, optical, or electronic signal that can include an electromagnetic radio signal.

In some embodiments, the electromagnetic radio signal received and/or transmitted by the gas of atoms has a frequency from static field (DC) to terahertz (THz).

In some embodiments, an electromagnetic radio signal is received and/or transmitted by the gas of atoms.

In some embodiments, the transmitted electromagnetic radio signal from the gas of atoms can include a tuned or modulated electromagnetic radio signal. In some embodiments, the transmitted electromagnetic radio signal from the gas of atoms can include an RF field, local oscillator (LO) reference field, and/or an optical field.

In some embodiments, the atom radio apparatus can further include an interface for input and output of signals to and from a radio operator or other system integrated with the atom radio.

In some embodiments, the atom radio apparatus can further include a system for tuning the received or transmitted signal. In some embodiments, the system for tuning can include a widely tunable laser for Rydberg spectroscopy.

In some embodiments, the widely tunable laser can include a photonic integrated circuit configured to stabilize, tune, or switch a wavelength, a phase, a frequency, an amplitude, a power, a polarization, or a combination thereof of the light beam.

In some embodiments, the widely tunable laser can include a controller configured to adjust the wavelength, the frequency, the amplitude, the power, the phase, the polarization, or a combination thereof of the light beam.

In some embodiments, the widely tunable laser can include a micro-electro-mechanical systems (MEMS) element configured to tune the wavelength, the frequency, or a combination thereof of the light in the photonic integrated circuit. In some embodiments, the MEMS element can include an integrator heator, a piezoelectric actuator, or a combination thereof.

In some embodiments, the widley tunable laser can include an atomic reference, an optical-cavity reference, or a combination thereof. In some embodiments, the atomic reference, the optical-cavity reference, or the combination thereof can be configured to stabilize or lock the widely tunable laser.

In some embodiments, the atom radio apparatus can further include an atomic reference, an optical-cavity reference, or a combination thereof. In some embodiments, the atomic reference, the optical-cavity reference, or the combination thereof is configured to stabilize or lock one or more lasers of the atom radio.

In some embodiments, the atom radio apparatus can be coupled to an antenna radio, a base station, a satellite, an airplane, a ship, a submarine, a mobile phone, a radio, a computer, an RF signal transmitter, an RF signal receiver, an RF signal transceiver, or a combination thereof.

In some embodiments, the atom radio apparatus can be configured for deployment on sea, land, air, flight missions, space platforms, or a combination thereof.

In some embodiments, a radio communication system can include a first atom radio apparatus. In some embodiments, the radio communication system can further include a second atom radio apparatus operatively coupled to the first atom radio apparatus. In some embodiments, the radio communication system can further include a first communication signal transmitted from the first atom radio apparatus and received by the second atom radio apparatus. In some embodiments, the radio communication system can further include a second communication signal transmitted from the second atom radio apparatus and received by the first atom radio apparatus. In some embodiments, the radio communication system can further include a system for synchronizing the first and second radio apparatuses.

In some embodiments, the system for synchronizing the first and second radio apparatuses can include a clock signal, an atomic clock signal, a GPS signal, or a combination thereof.

In some embodiments, the second atom radio apparatus can be coupled to an antenna radio, a base station, a satellite, an airplane, a ship, a submarine, a mobile phone, a radio, a computer, an RF signal transmitter, an RF signal receiver, or an RF signal transceiver.

In some embodiments, at least one of the first and second atom radio apparatuses can operate at below HF-band, HF-band, VHF-band, UHF-band, EHF-band, above EHF-band, or a combination thereof.

In some embodiments, an electronically-controlled frequency-agile cat-eye laser can include a laser diode configured to generate a light beam. In some embodiments, the cat-eye laser can further include a lens configured to shape and transmit the light beam. In some embodiments, the cat-eye laser can further include an interference filter configured to filter the light beam. In some embodiments, the cat-eye laser can further include a micro-electro-mechanical systems (MEMS) actuator coupled to the interference filter and configured to tune the wavelength of the light. In some embodiments, the cat-eye laser can further include a cat-eye reflector configured to feedback to the laser, stabilize and scan the laser frequency. In some embodiments, the cat-eye laser can further include a piezoelectric actuator coupled to the cat-eye reflector. In some embodiments, the cat-eye laser can further include an electronic signal to control the interference filter for wavelength tuning and piezoelectric actuator for cavity scans. In some embodiments, the cat-eye laser can further include a light conditioning element.

In some embodiments, the light conditioning element can include an isolator, an amplifier, a non-linear crystal, a modulator, an atomic reference, a cavity reference, a photonic integrated circuit, or a combination thereof.

In some embodiments, components of the cat-eye laser can be micro-integrated.

In some embodiments, the light beam of the laser diode can have a wavelength spanning from 100 nm to 10 microns. In some embodiments, the light beam of the laser diode can have an optical power spanning from 1 nW to 50 mW. In some embodiments, the wavelength of the light beam can include 852 nm, 780 nm, 510 nm, and 480 nm.

In some embodiments, the laser diode can be stabilized to a linewidth of 10 MHz or smaller.

In some embodiments, the MEMS actuator can displace or rotate the interference filter electronically based on the electronic control signal.

In some embodiments, a wavelength and a frequency of the light beam can be tuned or changed electronically using the piezoelectric actuator, a voltage or current of the laser diode, the MEMS actuator, or a combination thereof.

In some embodiments, a widely tunable laser for Rydberg spectroscopy can include a light source configured to generate a light beam. In some embodiments, the widely tunable laser can further include a photonic integrated circuit configured to stabilize, tune, or switch a wavelength, a phase, a frequency, an amplitude, a power, or a polarization of the light beam. In some embodiments, the widely tunable laser can further include a controller configured to adjust the wavelength, the frequency, the amplitude, the power, the phase, or the polarization of the light beam. In some embodiments, the widely tunable laser can further include one or more optical isolators to reduce optical feedback. In some embodiments, the widely tunable laser can further include an optical amplifier configured to amplify or generate light power. In some embodiments, the widely tunable laser can further include a non-linear crystal configured to double or change the light frequency. In some embodiments, the widely tunable laser can further include an optical modulator configured to modulate the phase, frequency, amplitude, or direction of the light. In some embodiments, the widely tunable laser can further include an atomic reference or an optical-cavity reference. In some embodiments, the widely tunable laser can further include a micro-electro-mechanical systems (MEMS) element configured to tune the wavelength or the frequency of the light in the photonic integrated circuit.

In some embodiments, a micro-integrated module for Rydberg excitation, spectroscopy, and quantum technology can include a light source configured to generate a light beam. In some embodiments, the micro-integrated module can further include a micro-electro-mechanical systems (MEMS) device or an electro-optical device configured to stabilize, tune, or switch a wavelength, a frequency, an amplitude, a power, or a polarization of the light beam. In some embodiments, the micro-integrated module can further include a controller configured to adjust the wavelength, the frequency, the amplitude, the power, or the polarization of the light beam. In some embodiments, the micro-integrated module can further include one or more optical isolators. In some embodiments, the micro-integrated module can further include an optical amplifier. In some embodiments, the micro-integrated module can further include a non-linear crystal. In some embodiments, the micro-integrated module can further include an optical modulator. In some embodiments, the micro-integrated module can further include an atomic reference or an optical-cavity reference. In some embodiments, the micro-integrated module can further include a micro-electro-mechanical systems (MEMS) tuning element.

Further features and exemplary aspects of the embodiments, as well as the structure and operation of various embodiments, are described in detail below with reference to the accompanying drawings. It is noted that the embodiments are not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the embodiments and, together with the description, further serve to explain the principles of the embodiments and to enable a person skilled in the relevant art(s) to make and use the embodiments.

FIG. 1 is a schematic illustration of an atom quantum radio apparatus, according to an exemplary embodiment.

FIG. 2 is a schematic illustration of an atom quantum radio apparatus in an example operational environment for satellite communication and with other atom radios, radio types, signals and sources, according to an exemplary embodiment.

FIG. 3 is a functional diagram and configuration of an Atomic Receiver (ARX), according to an exemplary embodiment.

FIG. 4 is a schematic illustration of an atom radio and atomic receiver (ARX) configuration, according to an exemplary embodiment.

FIG. 5 is a schematic illustration of an atom radio and atomic receiver (ARX) configuration, according to an exemplary embodiment.

FIGS. 6A and 6B are schematic illustrations of an atom radio or Rydberg sensor control unit with atom-based laser frequency-stabilization, according to exemplary embodiments.

FIGS. 7A and 7B are schematic illustrations of exemplary laser-frequency stabilization methods for micro-integrated or photonic integrated circuit (PIC) lasers for atom radios and Rydberg atom quantum technologies, according to exemplary embodiments.

FIGS. 8A and 8B are plots of wavelength tuning and frequenty operating points for an atom radio, according to exemplary embodiments.

FIG. 9A is a schematic block diagram of an absolute frequency-referenced micro-integrated monolithic cat-eye laser, according to an exemplary embodiment.

FIG. 9B is a schematic block diagram of an absolute frequency-referenced micro-integrated monolithic cat-eye laser, according to an exemplary embodiment. The TA module includes a tapered amplifier (TA) or amplifier that is current and/or temperature stabilized and the PPLN module includes a periodically-poled lithium niobate (PPLN) non-linear crystal that is temperature stabilized.

FIG. 10 is a schematic illustration of atom radio sensing and communication networks, according to an exemplary embodiment.

FIG. 11 is a schematic diagram of a Rydberg laser system with an optical frequency comb, according to an exemplary embodiment.

FIGS. 12A and 12B are schematic diagrams of a millimeter-wave atom radio receiver, subsystems, and components, according to exemplary embodiments.

FIGS. 13A-13C are plots of measurement and demonstration of an atom radio receiver responsivity to varying internal (LO power and laser frequency) and external (signal power) parameters, according to exemplary embodiments.

FIGS. 14A and 14B are plots of an atom receiver sensitivity and dynamic range measurement, according to exemplary embodiments.

FIGS. 15A and 15B are plots of a selectivity measurement of the millimeter-wave atomic receiver shown in FIGS. 12A and 12B, according to exemplary embodiments.

FIG. 16 is a plot of a filter roll-off of an atom radio receiver, according to an exemplary embodiment.

FIG. 17 is a schematic illustration of a Rydberg laser architecture for Rydberg excitation, spectroscopy, and quantum technologies, according to an exemplary embodiment.

FIG. 18 is a schematic illustration of a Rydberg laser architecture for Rydberg, excitation, spectroscopy, and quantum technologies, according to an exemplary embodiment.

FIG. 19 is a plot of an error signal of a cesium laser-frequency lock, according to an exemplary embodiment.

FIG. 20 is a schematic illustration of a Rydberg atom modulation spectroscopy vapor cell with electrodes for AC/DC field application, according to an exemplary embodiment.

FIG. 21 is a schematic illustration of a minisatspec and chipspec atom modulation spectroscopy vapor cell with electrodes for AC/DC field application, according to an exemplary embodiment.

FIG. 22 is a schematic illustration of a minisatspec and chipspec atom modulation spectroscopy vapor cell with the chipspec placed externally on the minisatspec case, according to an exemplary embodiment.

FIG. 23 is a schematic illustration of an integrated vapor cell in a chipspec package, according to an exemplary embodiment.

FIG. 24 is an illustration of an integrated vapor cell in a chipspec package, according to an exemplary embodiment.

FIG. 25 is a plot of velocity selection in a Rydberg atom sensor or spectroscopy, according to an exemplary embodiment.

FIG. 26 is a schematic illustration of a chip-scale Rydberg laser, according to an exemplary embodiment.

FIG. 27 is a schematic illustration of a two-tone testing setup for an atomic receiver, according to an exemplary embodiment.

FIGS. 28A and 28B are plots of two-tone measurements (modulation signal as a function of frequency and RF power applied) using the two-tone testing setup shown in FIG. 27, according to an exemplary embodiment.

FIG. 29 is a plot of two-tone measurement (modulation signal as a function of field intensity) using the two-tone testing setup shown in FIG. 27, according to an exemplary embodiment.

FIG. 30 is a plot of detected signal strength measured by an atomic receiver as a function of signal electric field, according to an exemplary embodiment.

FIGS. 31A and 31B are plots of detection and measurement of a HF-, VHF-, and UHF-band Rydberg Atomic Receiver (ARX), according to exemplary embodiments.

FIGS. 32A-32C are plots of RF signal electric-field sensitivities and AC polarizabilities of a Rydberg atom sensor, according to exemplary embodiments.

FIG. 33 is a plot of sensitivity of atomic and classical sensors as a function of frequency, according to an exemplary embodiment.

FIGS. 34A-34D are plots of Rydberg HF/VHF-band RF sensing with high angular momentum methods, according to exemplary embodiments.

FIG. 35 is a schematic illustration of atomic RF electric-field sensing, according to an exemplary embodiment.

FIGS. 36A and 36B are schematic illustrations of a Rydberg Atomic Aperture and Receiver (ARX), according to exemplary embodiments.

FIG. 37 is a schematic illustration of multi-band signal reception of a Rydberg atomic receiver (ARX), according to an exemplary embodiment.

FIGS. 38A-38D are plots of Rydberg EIT spectra for different atom-field interaction regimes, according to exemplary embodiments.

FIGS. 39A and 39B are schematic illustrations of a Rydberg RF electric-field probe (Rydberg Field Probe or RFP) and measurement instrument (Rydberg Field Measurement System or RFMS) for electric-field imaging, according to exemplary embodiments.

FIGS. 40A and 40B are plots of Rydberg EIT spectra from the Rydberg RF electric-field probe (RFP) shown in FIGS. 39A and 39B, according to exemplary embodiments.

FIG. 41 is a two-dimensional (2D) plot of the electric-field radiation pattern detected by the Rydberg RF electric-field probe (RFP) shown in FIGS. 39A and 39B from a Yagi-Uda antenna transmission, according to an exemplary embodiment.

FIG. 42 is a 2D image of RF signal phase detected by a Rydberg imager (atomic quantum synthetic aperture radar) based on Rydberg EIT fluorescence readout from an atomic vapor, according to an exemplary embodiment.

FIG. 43 is a schematic illustration of a high-frequency (THz) Rydberg maser with a bound-bound masing transition between a pair of Rydberg states, according to an exemplary embodiment.

FIGS. 44A and 44B are plots of Rydberg interaction potentials of a pair of Rydberg states along the internuclear axis, according to an exemplary embodiment.

FIGS. 45A and 45B are plots of absorption coefficients of Rydberg atom excitations, according to exemplary embodiments.

FIG. 46 is a schematic illustration of a matched Rydberg THz source and receiver, according to an exemplary embodiment.

FIG. 47 is a schematic illustration of a quantum-enabled RF imaging and visualization system, according to an exemplary embodiment.

FIG. 48 is a schematic illustration of stemless vapor cells, according to exemplary embodiments.

The features and exemplary aspects of the embodiments will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of this present disclosure. The disclosed embodiment(s) merely exemplify the present disclosure. The scope of the disclosure is not limited to the disclosed embodiment(s). The present disclosure is defined by the claims appended hereto.

The embodiment(s) described, and references in the specification to “one embodiment,” “an embodiment,” “an example embodiment,” “an exemplary embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; quantum storage media; flash memory devices; electrical, optical, acoustical or other forms of propagated signals (e.g., carrier waves, radio-frequency signals, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

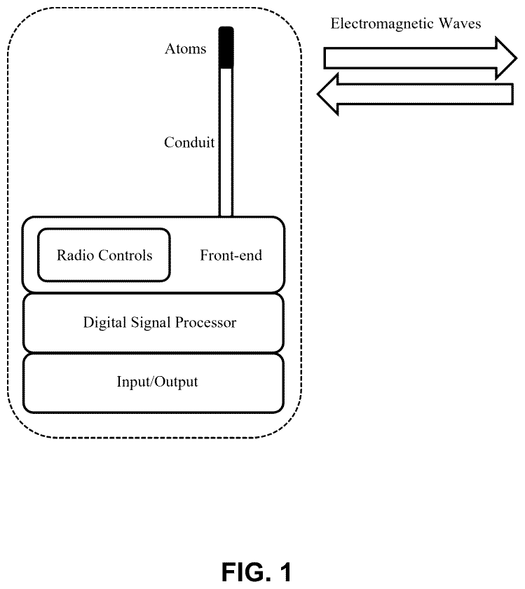

FIG. 1 illustrates an atomic radio apparatus (dashed outline) comprising atoms in one or more Rydberg states that receives and/or transmits electromagnetic radiation, a cable conduit carrying electronic and/or electromagnetic signals to and/or from the atoms, a front-end generating and/or receiving electronic and/or electromagnetic signals to and/or from the atoms, user-controls for the radio channel tuning and other controls of radio operation, a digital signal processor for processing sent and received signals from the front-end, and an interface for input and output of signals to and from a radio operator or other system integrated with the radio. Incident (received) and outgoing (transmitted) electromagnetic waves are shown.

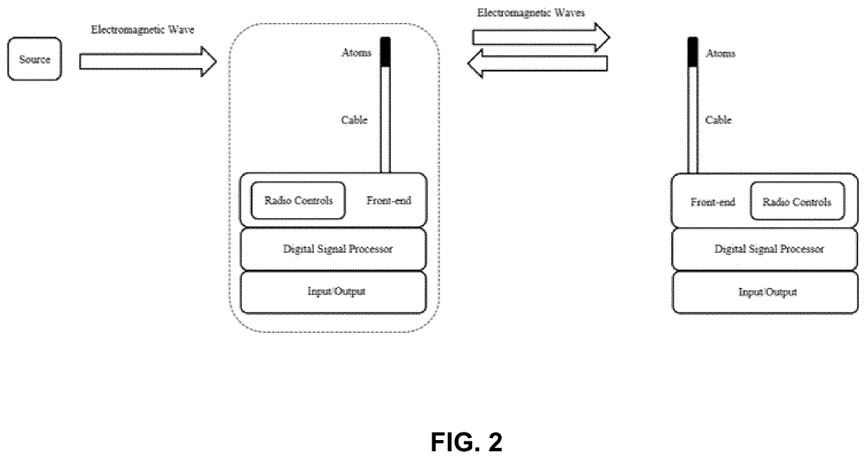

FIG. 2 illustrates an atom radio apparatus (dashed outline) with a source of electromagnetic waves and a second atom radio receiving and transmitting electromagnetic waves between radios.

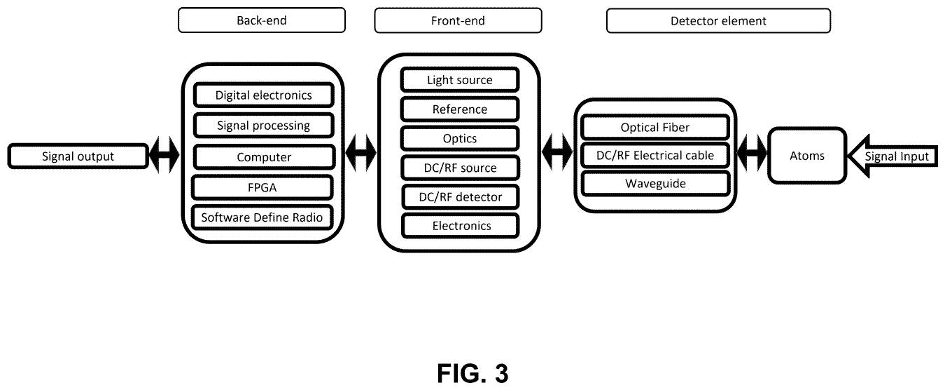

FIG. 3 illustrates an Atomic Radio and Atomic Receiver (ARX) functional diagram and configuration.

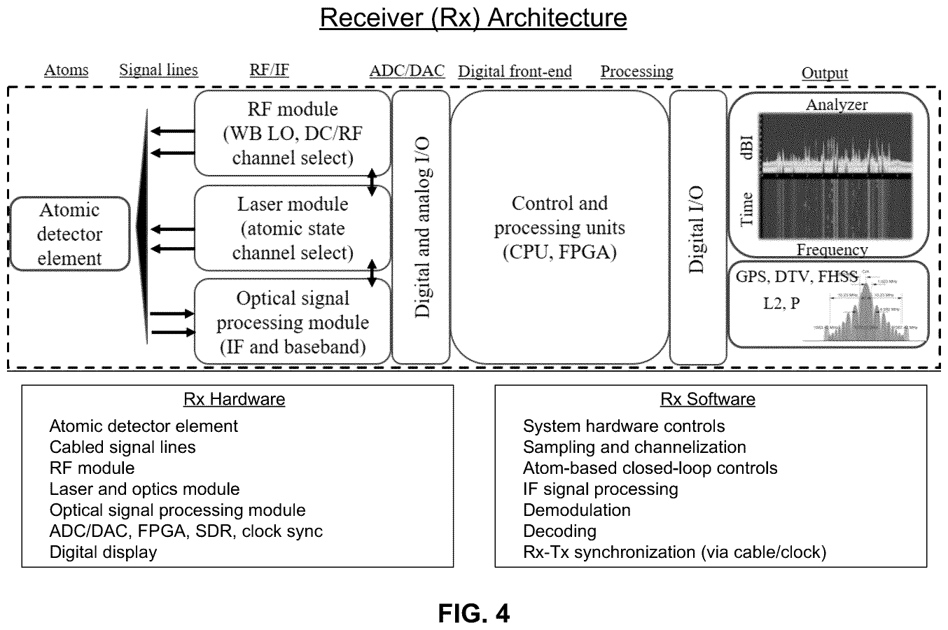

FIG. 4 illustrates an Atomic Receiver (ARX) configuration with a wideband reference local oscillator, DC/RF continuous or discrete state and RF-channel tuning, optical signal processing, and software digital signal processing for Satellite, GPS, digital television, FHSS, and other complex RF waveforms.

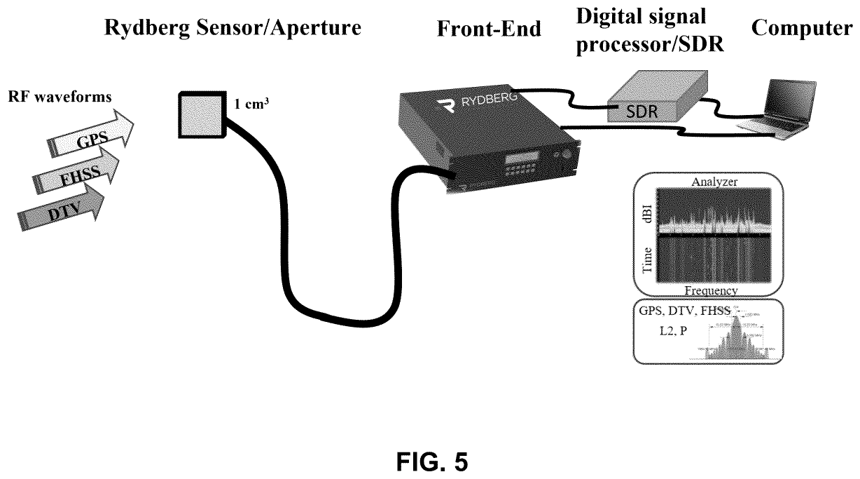

FIG. 5 illustrates an Atomic Receiver (ARX) hardware configuration with an Rydberg quantum aperture, mainframe control (front-end), software-defined-radio, and display for Satellite, GPS, digital television, and frequency-hopping spread spectrum (FHSS) signal reception.

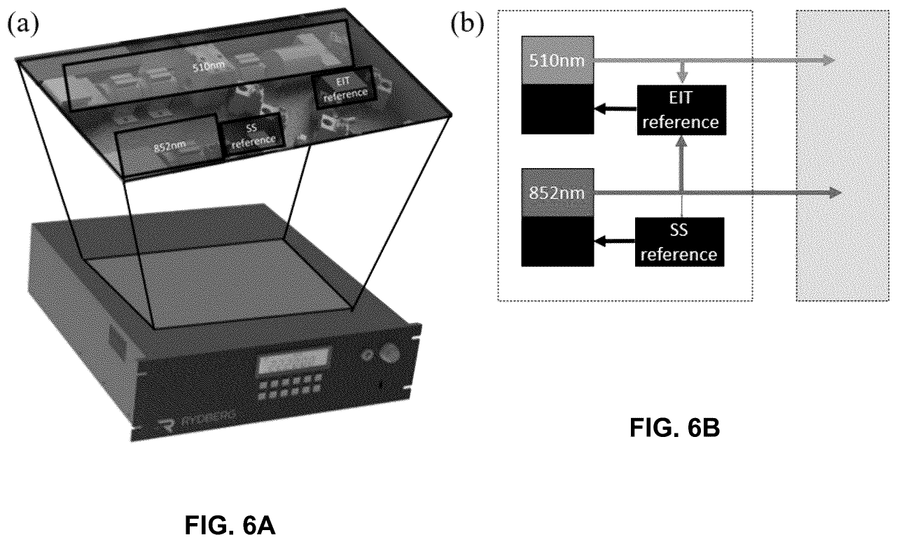

FIG. 6A illustrates a Rydberg sensor control unit with an integrated compact multi-photon Rydberg laser and frequency-stabilization subsystem for cesium two-photon Rydberg spectroscopy including a tunable 510 nm laser and 852 nm laser with EIT and SS reference modules (inset). FIG. 6B illustrates the laser stabilization subsystem that shows the 510 nm and 852 nm lasers, electronics drivers (black boxes), and optical (green and red arrows) and electronic (black arrows) signal paths.

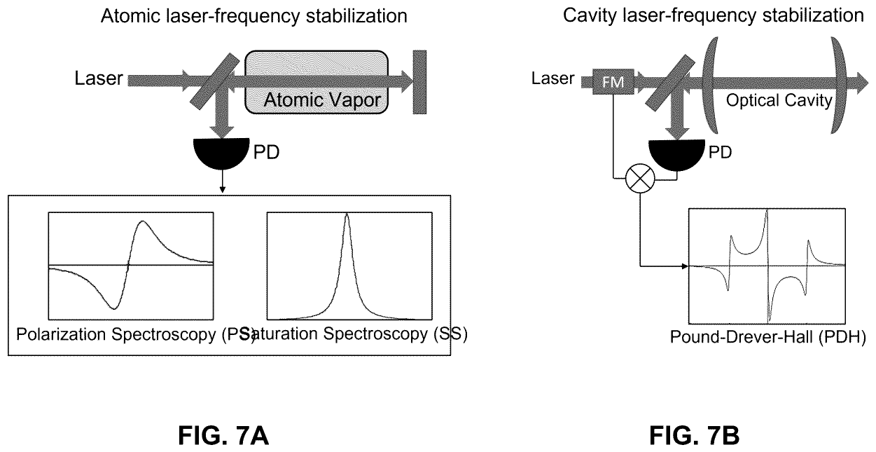

FIG. 7A illustrates a laser-frequency stabilization method using an atomic reference with polarization spectroscopy (PS) and saturation spectroscopy (SS) locks. FIG. 7B illustrates a laser-frequency stabilization method using an optical cavity reference using a Pound-Drever-Hall (PDH) lock.

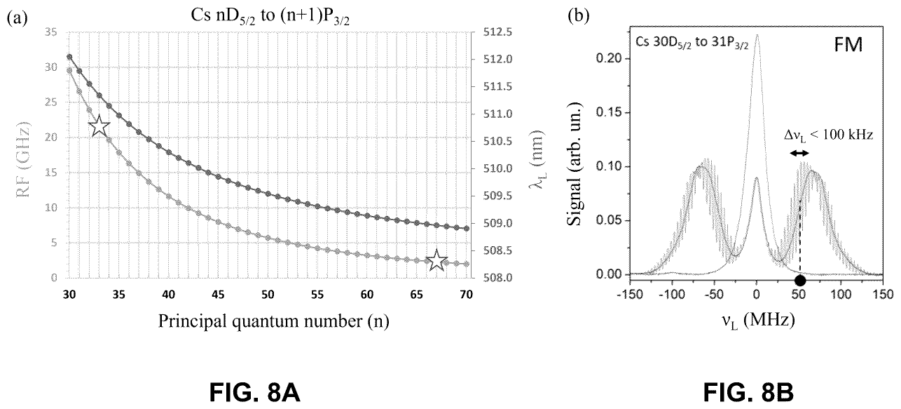

FIG. 8A illustrates a 510 nm coupler laser wavelength coupling Cs |6P_{3/2}> to |nD_{5/2}> transitions (blue, right axis) and the RF carrier frequency resonant with the connected Cs |nD_{5/2}> to |n+1P_{3/2}> Rydberg transition (orange, left axis) as a function of principal quantum number. Example transitions are marked by yellow stars. FIG. 8B illustrates a spectral readout from a Cs atomic receiver with the tunable coupler laser wavelength set to 512.048 nm centered at v_{L}=0 on the x-axis and scanned across the Cs |6P_{3/2}> to |30D_{5/2}> Rydberg transition. The three curves show the spectral readout: without an RF signal (black), with a 29.548 GHz RF carrier signal resonantly driving Autler-Townes (AT)-splitting on the Cs |30D_{5/2}> to |31P_{3/2}> Rydberg transition (blue), and with the carrier frequency modulated (FM) at 1 KHz (red). The black dot and dashed line indicate the desired coupler laser frequency operating point at which the coupler-laser detuning must be stabilized (at approximately 512.048 nm+50 MHz under these RF conditions in FIG. 8B) to achieve the highest signal-to-noise ratio (SNR) (largest 1 kHz oscillation amplitude) of the 29.548 GHz FM signal. To maximize SNR on the target Rydberg transition, the laser frequency stabilization Δv_{L} of 100 kHz or less is typically required.

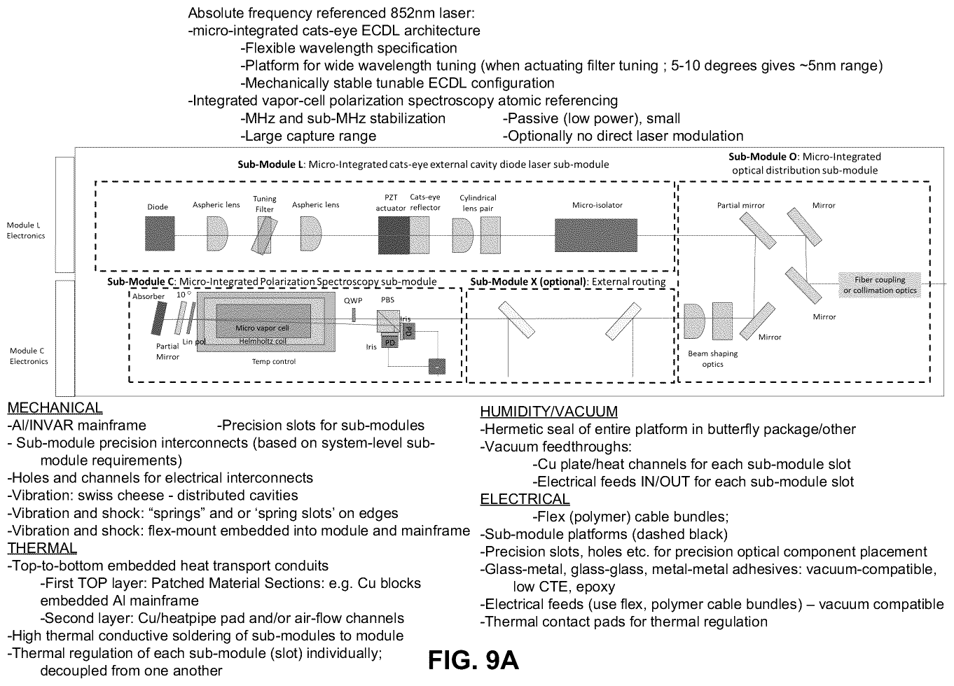

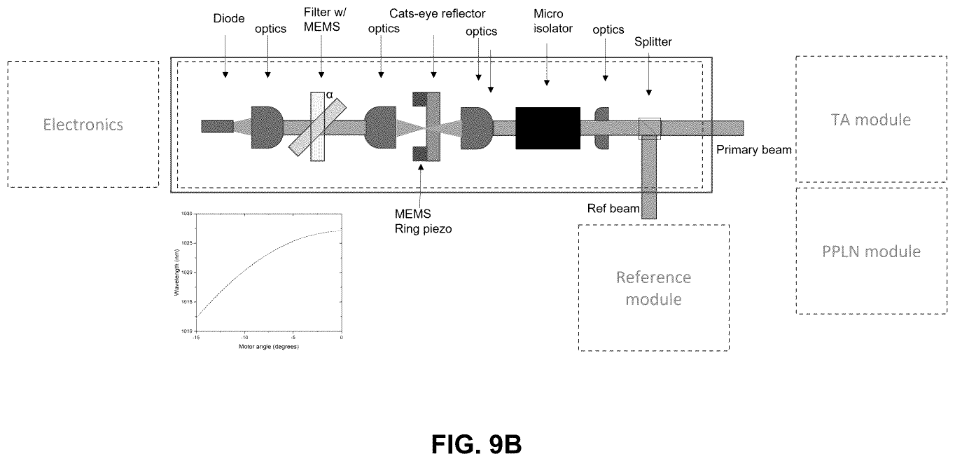

FIG. 9A illustrates a schematic block diagram of an absolute frequency-referenced micro-integrated monolithic cat-eye laser with sub-5 mm optical elements and wavelength and frequency tuning electronically-controlled by MEMS/Piezo actuating the interference filter in the cats-eye, according to an exemplary embodiment. The laser is stabilized and referenced via atomic spectroscopy, or external cavity (not shown). An amplifier and multiplier stage for higher-power and frequency doubling of the IR light are not shown. In the case of a photonic integrated circuit architecture, laser wavelength/frequency tuning and switching is electronically-controlled via selecting one or one out of a bank of resonators. Feedback and feed-forward on laser parameters such as temperature and current are also implemented.

FIG. 9B is a schematic block diagram of an absolute frequency-referenced micro-integrated monolithic cat-eye laser, according to an exemplary embodiment. The TA module includes a tapered amplifier (TA) or amplifier that is current and/or temperature stabilized and the PPLN module includes a periodically-poled lithium niobate (PPLN) non-linear crystal that is temperature stabilized.

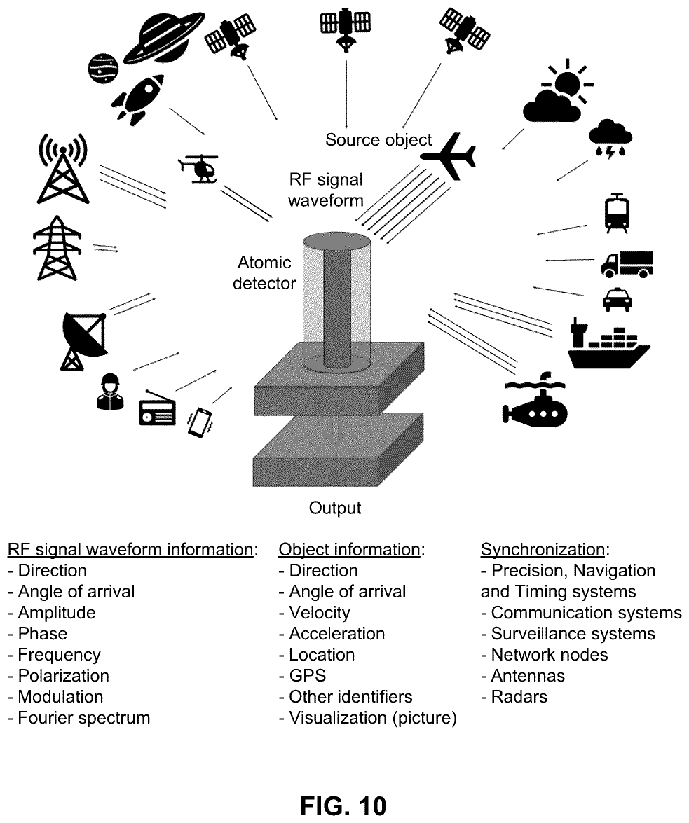

FIG. 10 illustrates atom radio sensing and communications.

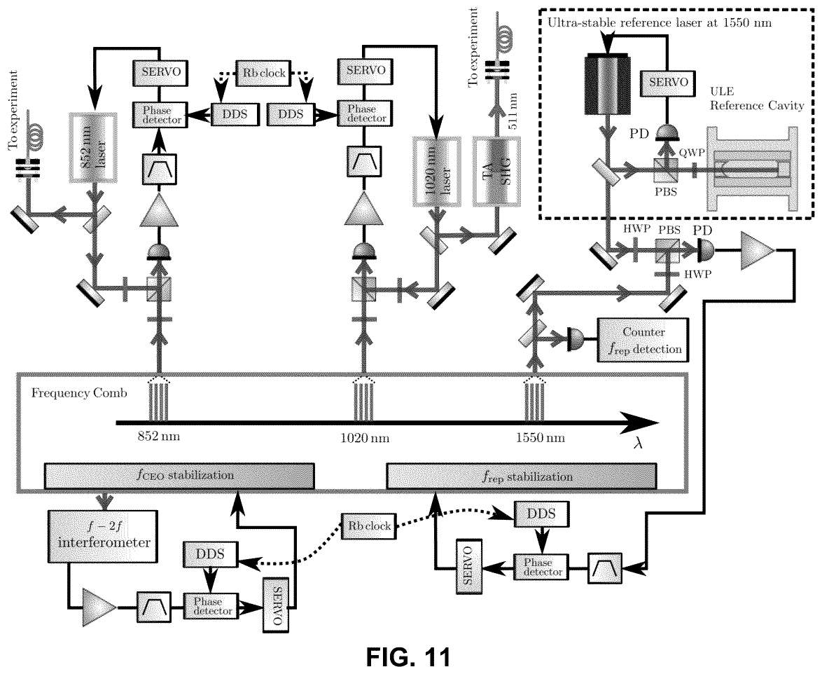

FIG. 11 illustrates the optical frequency comb (OFC) stabilization to an ultra-stable reference laser as well as 852 nm and 1020 nm lasers lock to the OFC. HWP: half-waveplate, QWP: quarter-waveplate, PD: photodiode, PBS: polarizing beam-splitter, DDS: direct digital synthesizer, Rb clock: Rubidium clock.

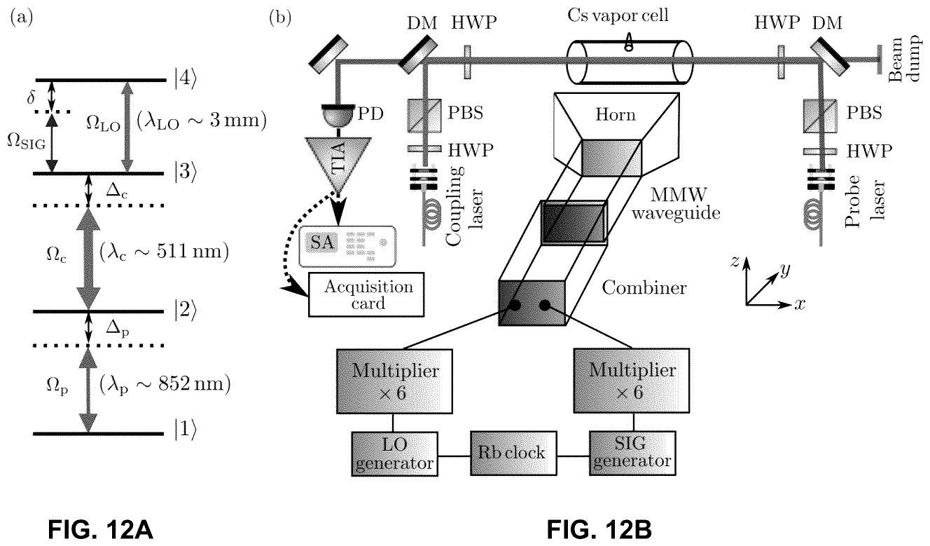

FIGS. 12A and 12B illustrate two-photon Rydberg excitation in ¹³³Cs vapor cell. FIG. 12A illustrates four-level energy diagram with ground state |1>=|6²S_{1/2}>, first excited state |2>=|6²P_{3/2}), Rydberg state |3>=|37²S_{1/2}>, and Rydberg state |1>=|36²P_{3/2}>. The corresponding Rabi frequencies and detunings of the 852 nm probe laser and 511 nm coupling laser are, respectively, Ωₚ (Ω_{c}) and Δₚ (Δ_{c}). A strong MMW (λ_{LO}˜3 mm) resonant local oscillator field (Ω_{LO}) and a weak MMW signal field (Ω_{SIG}) with RF detuning δ are coupling the two Rydberg states |3> and |4>. FIG. 12B illustrates an experimental setup for super-heterodyne measurements. HWP: half-waveplate, QWP: quarter-waveplate, DM: dichroic mirror, PD: photodiode, TIA: transimpedance amplifier, PBS: polarizing beam-splitter, SA: spectrum analyzer.

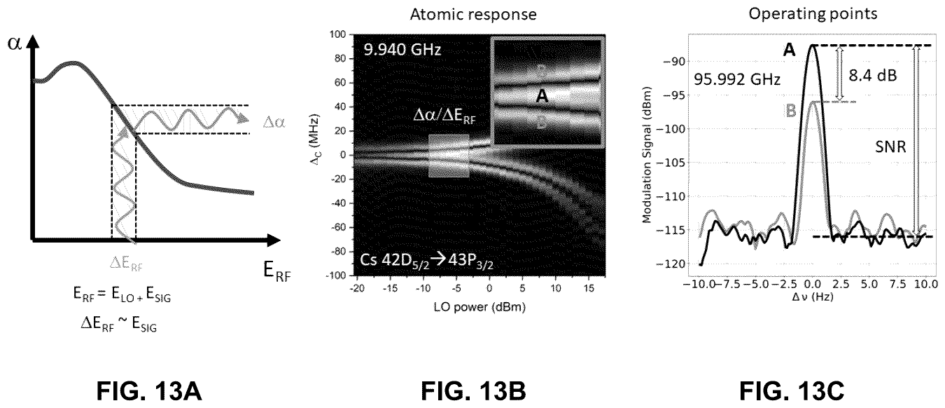

FIGS. 13A-13C illustrate responsivity of atomic receivers to microwave (MW) and millimeter-wave (MMW) signals. FIG. 13A illustrates a typical EIT probe absorption coefficient α(E_{RF}, Δ_{c}) at a fixed EIT coupling detuning, Δ_{c}=0, versus RF field, E_{RF}. Δα/ΔE_{RF} at Δ_{c} is the relevant atomic figure of merit for responsivity. FIG. 13B illustrates a measurement of Δα/ΔE_{RF}(E_{RF}, Δ_{c}) with the atomic receiver for a 9.940 GHz MW field. FIG. 13C illustrates signal-analyzer (SA) spectra of Rydberg-receiver output signals on operating points A and B for an equivalent measurement of a 95.992440 GHz MMW signal on the Cs 37S_{1/2}↔36P_{3/2} Rydberg transition with E_{LO}=0.51 V/m and E_{SIG}=513 μV/m. The SA frequency, Δv, is shown relative to the intermediate frequency (IF) beatnote frequency of 72 kHz. Operating point A has a 8.4 dB higher response than operating point B.

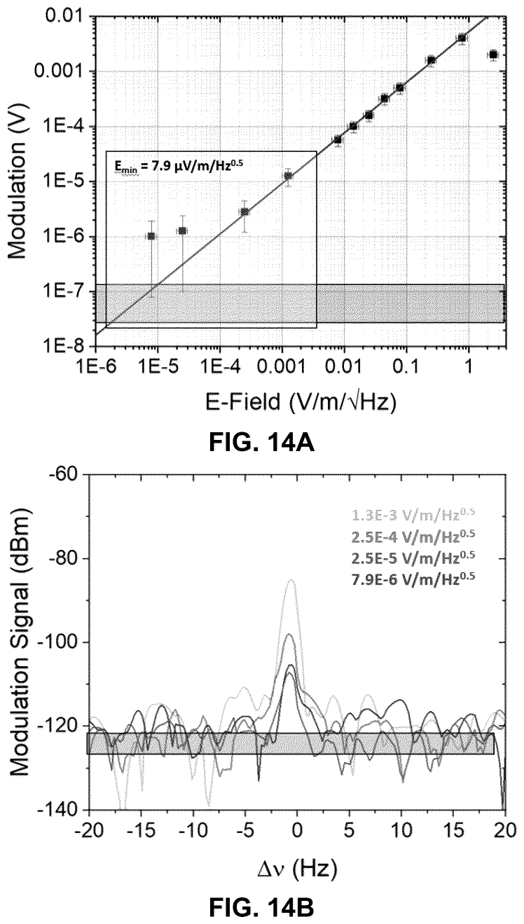

FIGS. 14A and 14B illustrate atomic receiver sensitivity and dynamic-range measurement for a 95.992440 GHz signal (SIG) field for a detuning Δf of the SIG field from the LO, equivalent to an intermediate frequency (IF) of 72 kHz (IF=SIG−LO frequency). FIG. 14A illustrates the atomic receiver's output in RMS voltage at the IF frequency versus applied MMW SIG electric field in units V/m/\sqrt{Hz}. FIG. 14B illustrates signal-analyzer (SA) spectra in dBm centered at the 72 kHz IF and measured at the four lowest SIG fields shown in FIG. 14A (values provided in the legend in units V/m/\sqrt{Hz}).

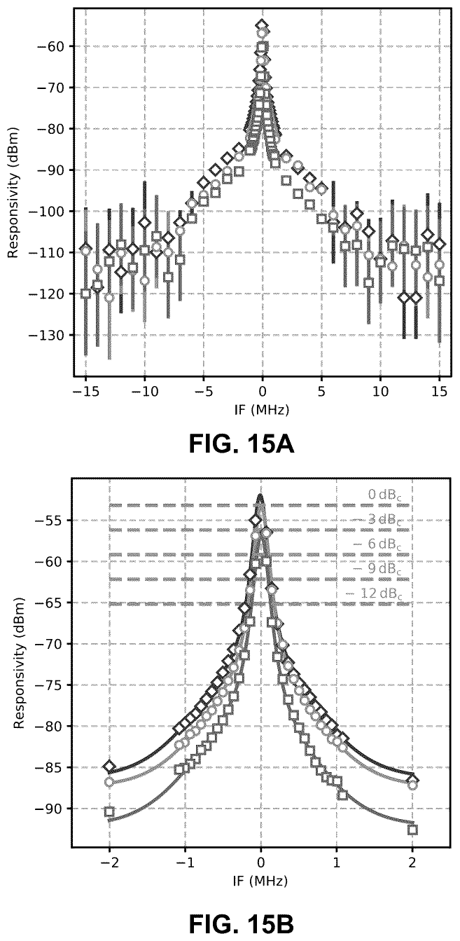

FIGS. 15A and 15B illustrate atomic receiver response (pass-band filter) to signal frequency (SIG frequency detuning Δf from SIG=LO, or IF frequency). FIG. 15A illustrates response over a Δf range from −15 MHz to +15 MHz (IF=SIG−LO frequency), for LO frequency 95.992440 GHz resonant with a Rydberg MMW transition. FIG. 15B illustrates atomic receiver responsivity over an IF range of −2 MHz to +2 MHz. Response curves are shown for coupling laser powers of 48 mW (blue diamonds), 38 mW (red circles), and 28 mW (green squares). The response (pass band filter) curves are empirically fitted to Voigt functions (solid lines) before extraction of responsivity attenuation levels. The fitted Gaussian and Lorentzian widths in the Voigt fits are Γ_{G}/2π={547, 522, 537} KHz and Γ_{L}/2π={309, 324, 337} kHz, for respective coupling laser powers listed above. The red dashed lines show the extraction of the IF bandwidth cutoff frequencies for {3, 6, 9, 12} dB attenuation levels at a coupling power of 38 mW.

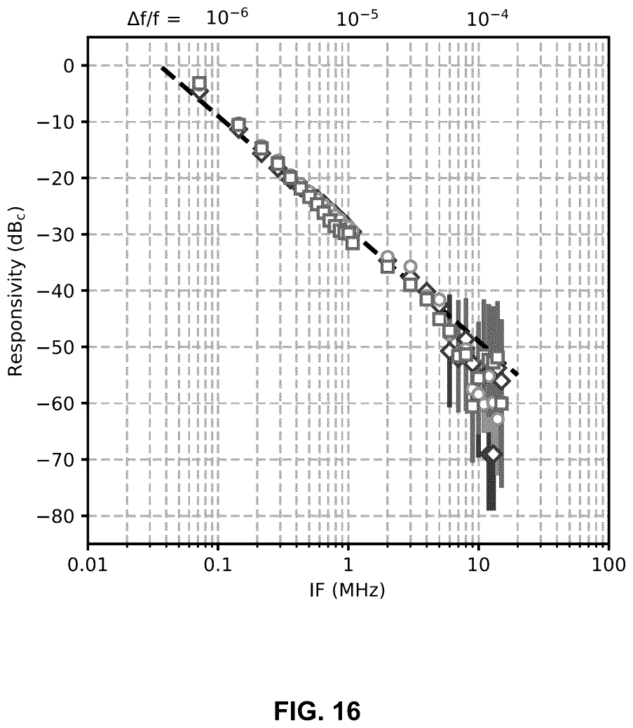

FIG. 16 illustrates atom receiver filter roll-off showing signal rejection ratio in dB_{c} versus signal frequency detuning Δf. Notably, at large |Δf| the atomic receiver filter roll-off exhibits a fixed slope of −2, as indicated by the black dashed line.

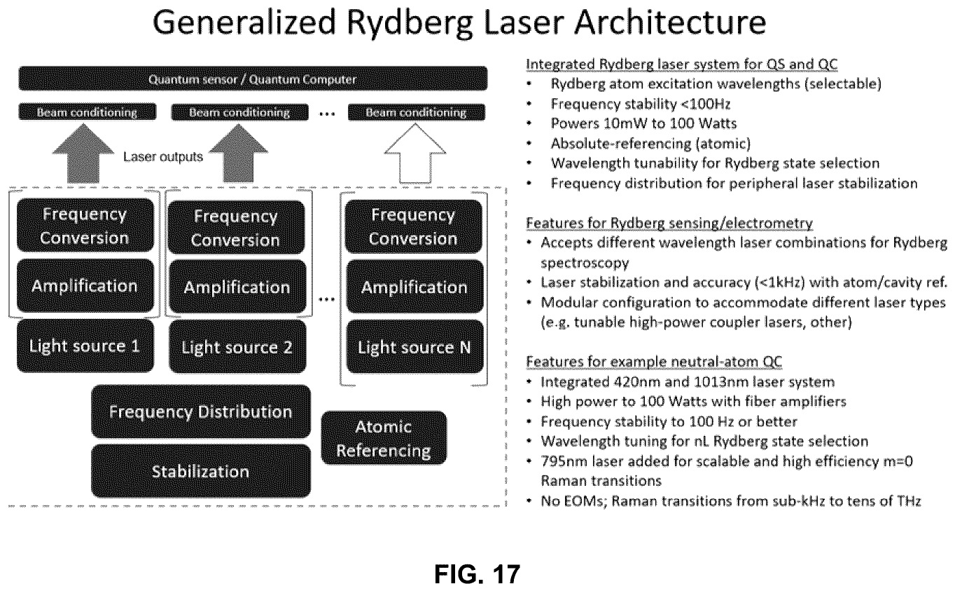

FIG. 17 illustrates an integrated Rydberg laser system for Rydberg quantum technologies including sensing and computing. Example features include Rydberg atom excitation wavelengths (selectable), frequency stability <100 Hz, powers 10 mW to 100 W, absolute-referencing (atomic), wavelength tenability for Rydberg state selection, and frequency distribution for peripheral laser stabilization. Features for Rydberg sensing/electrometry: accepts different wavelength laser combinations for Rydberg spectroscopy. Laser stabilization and accuracy (<1 kHz) with atom/cavity reference. Modular configuration to accommodate different laser types (e.g., tunable high-power coupler lasers, others). Features, for example, neutral-atom QC: integrated 420 nm and 1013 nm laser system, high power to 100 W with fiber amplifiers, frequency stability to 100 Hz or better, wavelength tuning for nL Rydberg state selection, 795 nm laser added for scalable and high efficiency m=0 Raman transitions, no EOM required (optional), Raman transitions from sub-kHz to tens of THz.

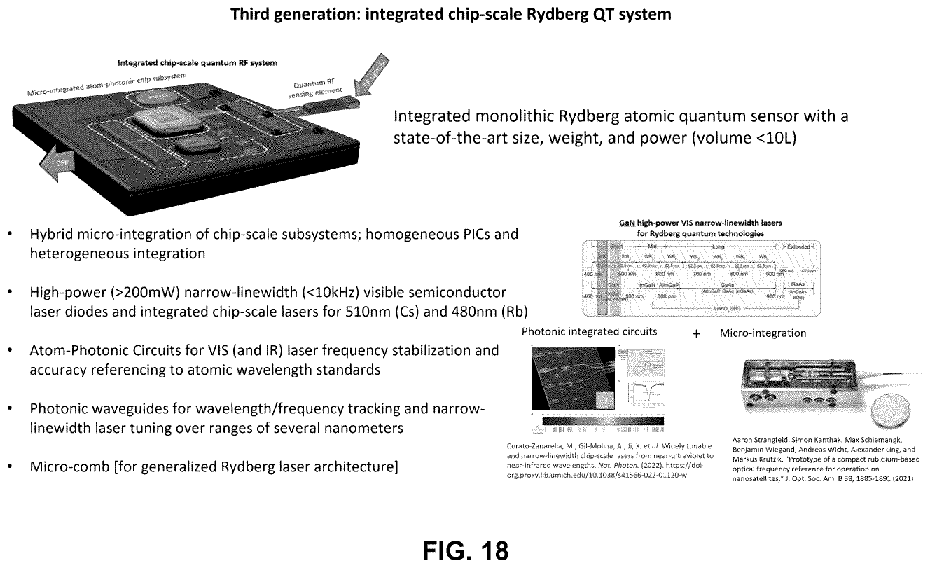

FIG. 18 illustrates a micro-integrated and chip-scale Rydberg laser system.

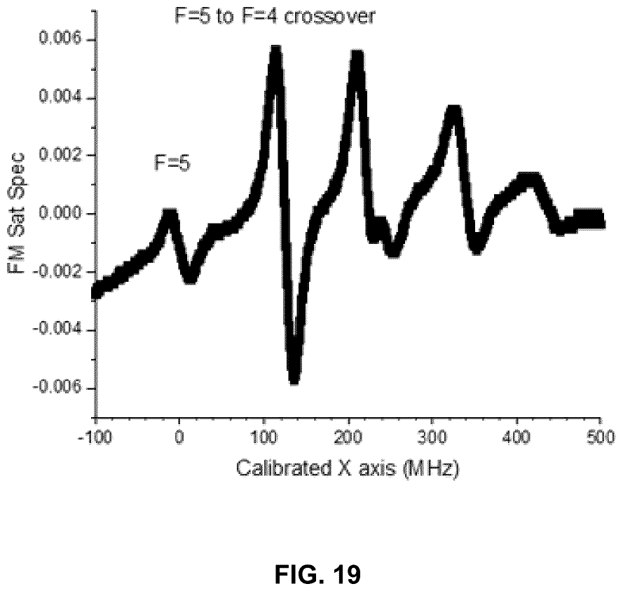

FIG. 19 illustrates FM spectroscopy error signal of cesium for 852 nm atomic frequency-stabilization from miniature saturation spectroscopy in a compact two-color laser subsystem in a Rydberg atomic aperture for RF communications. The laser stabilization subsystem provides a lock of the laser to a zero-crossing and laser-frequency stability of 20 KHz.

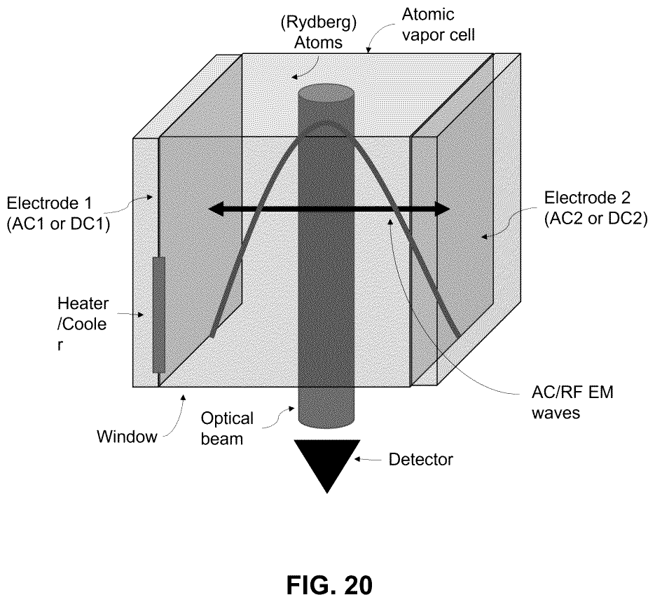

FIG. 20 illustrates a Rydberg integrated atomic gas cell with electrodes for AC/DC field application and sensing. Electronics, additional electrodes, laser beams, and packaging not shown.

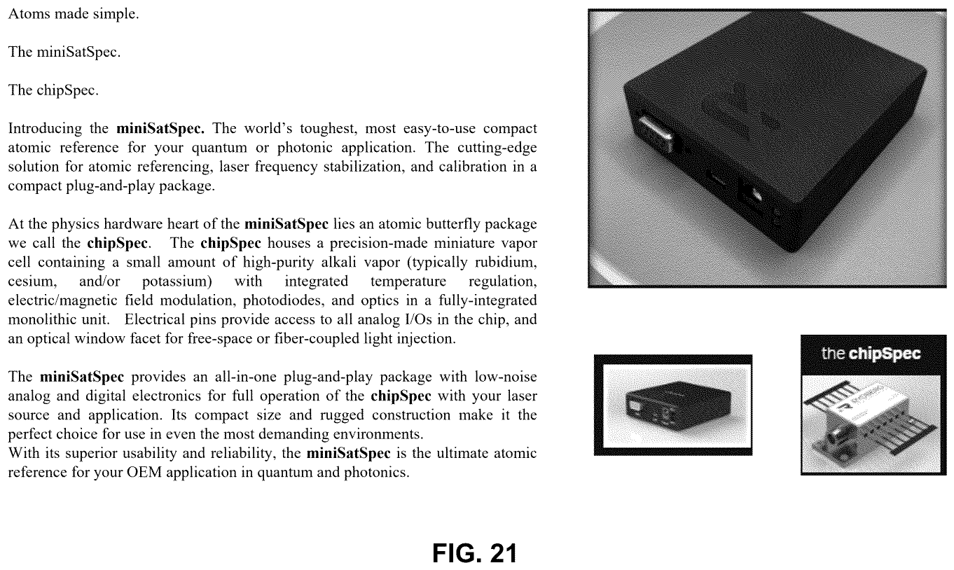

FIG. 21 illustrates a Rydberg minisatspec and chipspec.

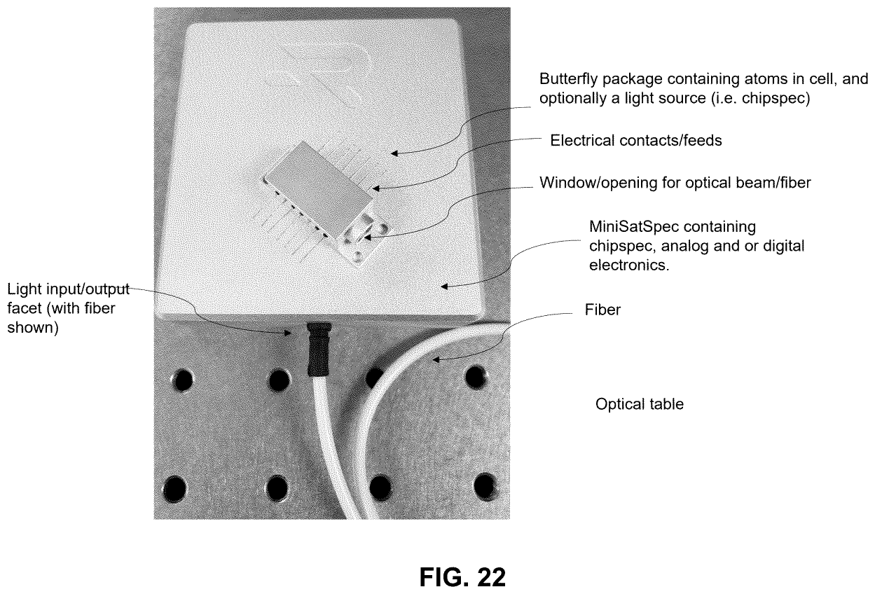

FIG. 22 illustrates a Rydberg minisatspec and chipspec (external).

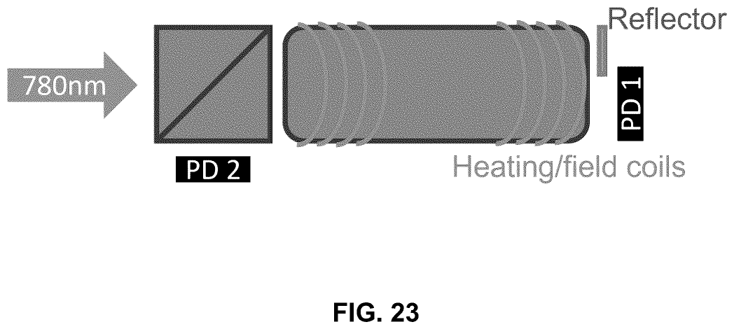

FIG. 23 illustrates a Rydberg integrated/monolithic minature vapor cell in a minisatspec and chipspec package with photodiodes, heater/field coils, and an optic for beams splitting/conditioning. Isolators, laser sources, and other elements not shown.

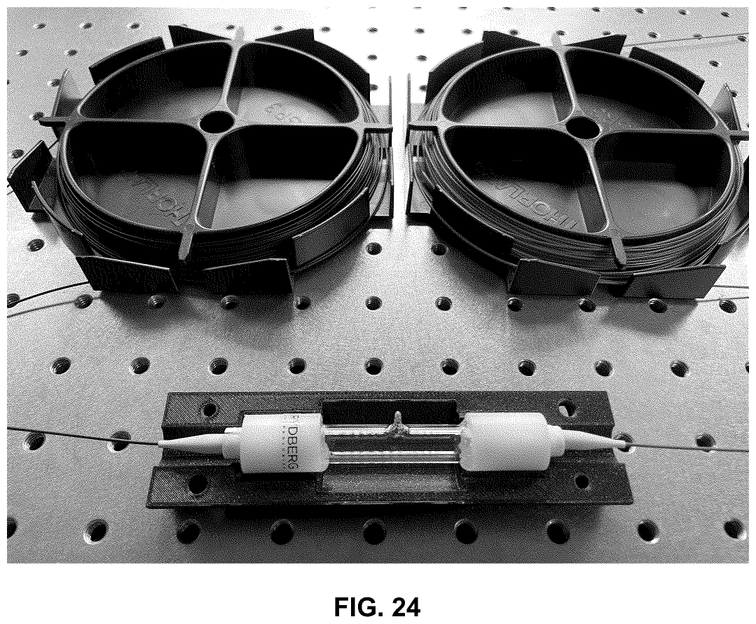

FIG. 24 illustrates a Rydberg vapor cell probe and atom radio atoms and fiber-optic conduits.

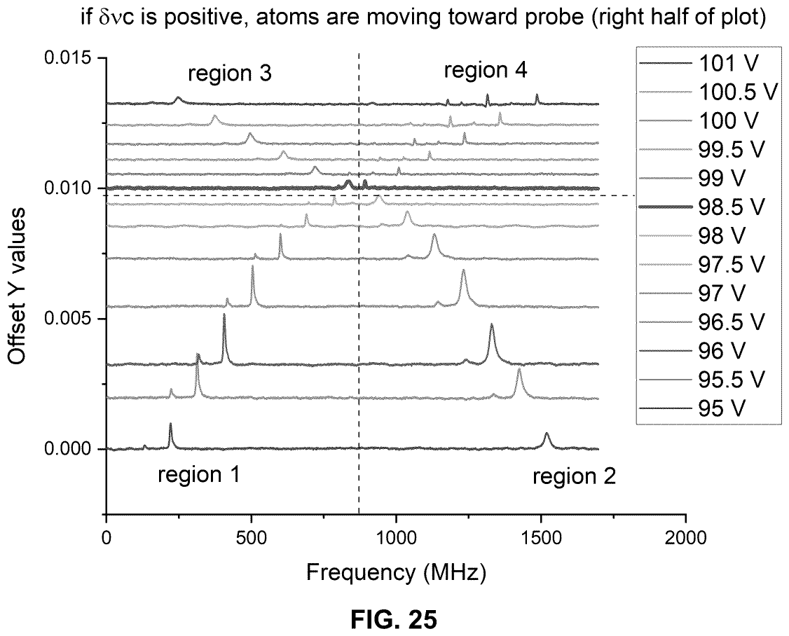

FIG. 25 illustrates spectra for two-photon Rydberg EIT in an atomic vapor with probe and coupler beam detunings from zero when the beams are set up to be overlapped and counter-propagating. Regions 1 and 4 are EIT spectra from counter-propagating EIT beams. Regions 2 and 3 are EIT spectra for an effective “co-propagating” standing wave or optical lattice or optical dipole trap EIT. Spectra would not appear in these regions of laser detunings if they were counter-propagating. Regions 1 and 4 show EIT spectra for counter-propagating two-photon EIT in cesium vapor with 852 nm and 510 nm light beams. Here the 852 nm light is detuned from blue (region 1) to red (region 4) relative to zero-velocity atoms, with the 510 nm laser detuning set to satisfy momentum conservation: k-vector (852 nm)+k-vector (atom velocity)−k-vector (510 nm)=0. As shown in FIG. 25, in regions 1 and 4, the EIT lines become taller and narrower away from zero-detuning (dashed vertical and horizontal lines in the figure). This is attributed to the fact that at the zero-detuning, zero-velocity atoms have the highest density and have no preferred direction of travel relative to one-another cause an increase in atom density and interaction-induced broadening and deterioration of the EIT line. Away from the zero-detuning point, the low-lying 6P/ground-state atom and excited Rydberg-state atom density is reduced, and the atoms/Rydberg atoms also share the same velocity vector, reducing interactions during EIT readout.

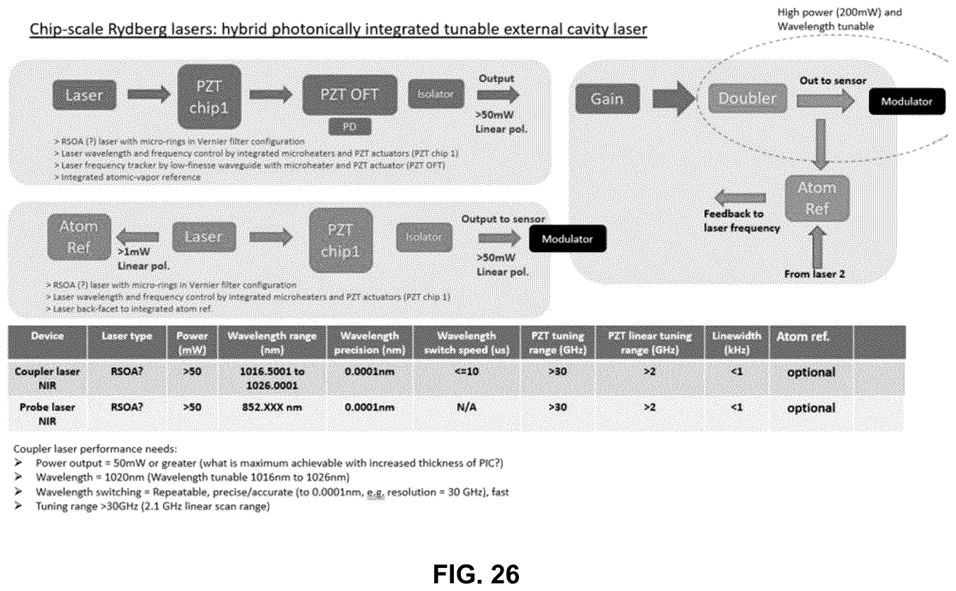

FIG. 26 illustrates a chip-scale Rydberg laser: hybrid photonically integrated lasers with micro-resonators and Rydberg atoms. The chip-scale Rydberg laser may comprise a laser such as an injection-locked distributed feedback (DFB) laser diode or reflective semiconductor optical amplifier (RSOA), one or more voltage-controlled piezo micro-resonator or Vernier filter for wide wavelength/frequency tuning and or stabilization, an optical isolator, a gain stage such as an amplifier for increased power, and a (Rydberg) atom vapor cell and atomic reference such as the miniSatSpec for stabilizing or referencing the light frequency to an (Rydberg) atomic transition; with subsystems and components heterogeneously integrated into a single or multi-chip package with optical and electrical connections. A multi-wavelength Rydberg chip-scale Rydberg laser can comprise, for example, an 852 nm laser and 1020 nm laser frequency-doubled to 510 nm for cesium, or similarly a 780 nm laser and a 960 nm laser frequency-doubler to 480 nm for rubidium. Such a chip-scale laser can also include a frequency-comb.

FIG. 26 also illustrates the architecture of a PIC-based Rydberg laser system that comprises a frequency-agile PIC laser subsystem with two or more laser frequencies, one of which is a widely wavelength-tunable and or fast switching coupler laser, and subcomponents such as waveguides, optical isolators, and modulators, and absolute atomic-vapor cell laser-frequency-referencing or stabilization for Rydberg atom excitation and spectroscopy. The PIC Rydberg laser components are small structures in materials such as silicon nitride (Si₂N₄), lithium niobate (LiNbO₃), or aluminum nitride (AlN) that exhibit low optical loss and good power handling, and robustness to shock and vibrations in harsh environments.

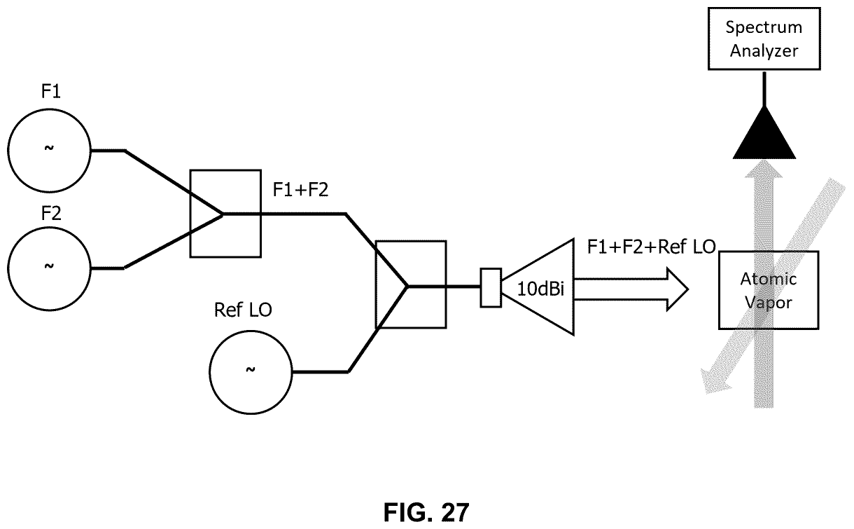

FIG. 27 illustrates an atomic receiver two-tone testing setup. Two tones F1 and F2 are generated and combined with a reference local oscillator FLO. The combined signal F1 +F2+F_{LO} is transmitted by an antenna (WR-75 horn antenna) over-the-air to the atomic receiver (atomic vapor cell). Two-photon Rydberg electromagnetically-induced-transparency (EIT) spectroscopy is performed on RF-sensitive Rydberg states and RF-induced changes (probe beam) are detected on a photo-detector for optical readout. The photo-detector signal is read by a spectrum analyzer (SA) to measure the power spectrum of the atomic receiver response.

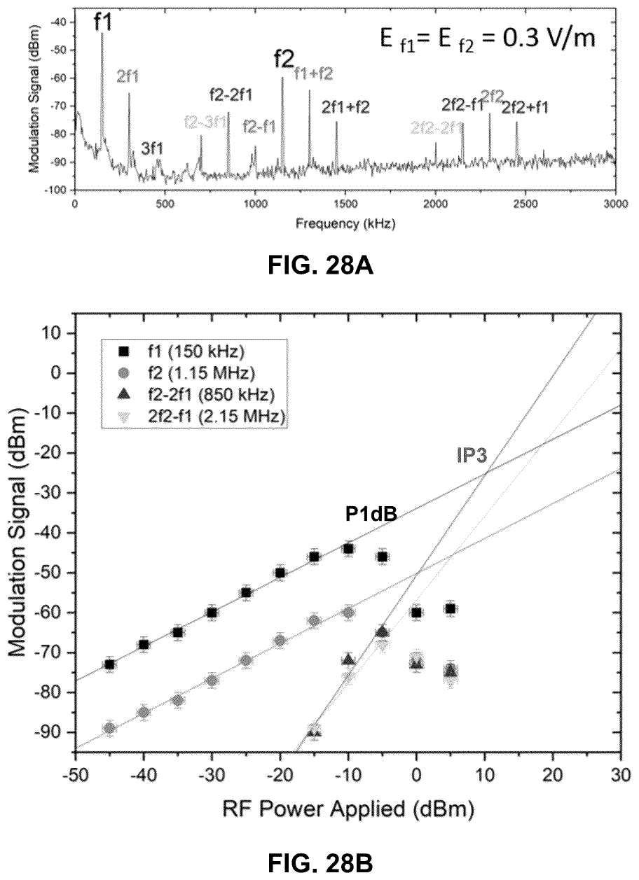

FIGS. 28A and 28B illustrate atomic receiver two-tone tests. FIG. 28A illustrates an intermediate frequency (IF) from a spectrum analyzer (SA) of the atomic receiver including fundamental (black), second-order (red), third-order (blue), and fourth-order (green) harmonic modulation and intermodulation products (labeled). FIG. 28B illustrates dependence of modulation products versus applied two-tone signal power.

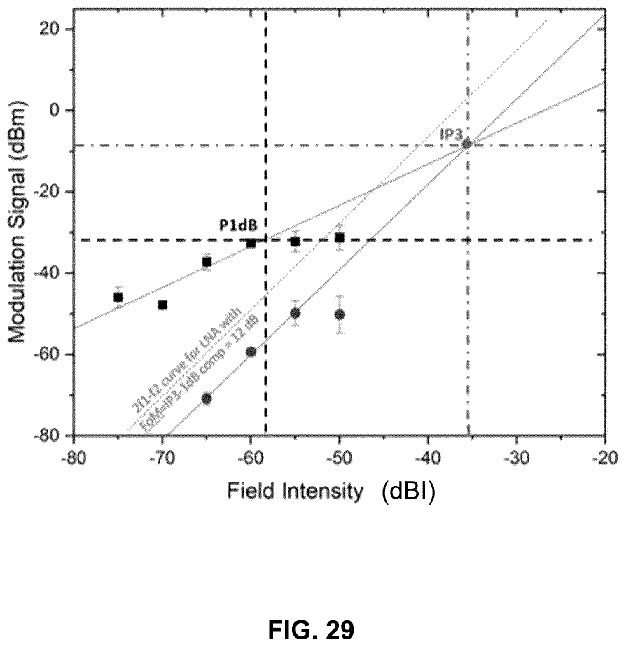

FIG. 29 illustrates atomic receiver two-tone tests including dependence of modulation products versus applied two-tone signal power for tones F1=9.940150 GHz and F2=9.940250 GHz, frequency separation ΔF=F2−F1=10 kHz, and a relative frequency separation ΔF/F_{LO}=10⁻⁶ (F_{LO}=9.940 GHz). P1dB (black dash) and IP3 (teal dash-dot) intersection points are marked. The 2f1-f2 curve for a low-noise amplifier (LNA) with a figure of merit (FoM)=IP3−P1dB=12 dB is overlaid for comparison (red).

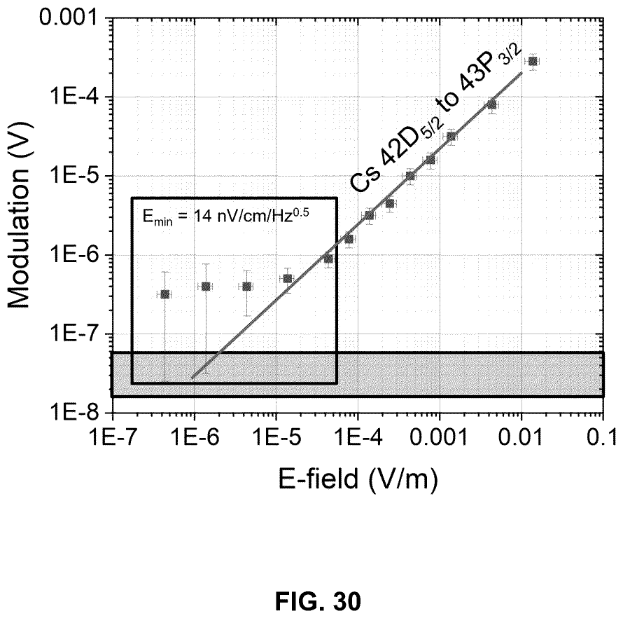

FIG. 30 illustrates atomic receiver sensitivity and dynamic range for a 9.936 GHZ signal.

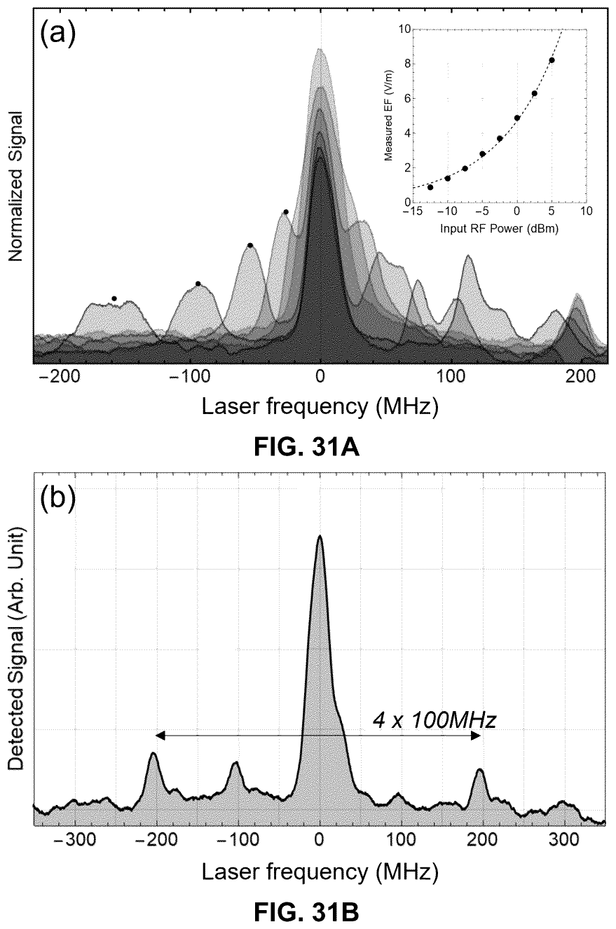

FIGS. 31A and 31B illustrate RF signal reception with the ARX. FIG. 31A illustrates a 2 GHz RF signal reception using the 70D_{5/2} to 71P_{3/2} resonant transition. Inset shows a signal electric-field to power calibration curve. FIG. 31B illustrates a 100 MHZ RF signal reception using the 50D_{5/2} atomic Rydberg state. 100 MHZ carrier-wave-generated off-resonant sidebands at ±200 MHz from the 50D_{5/2} atomic Rydberg resonance.

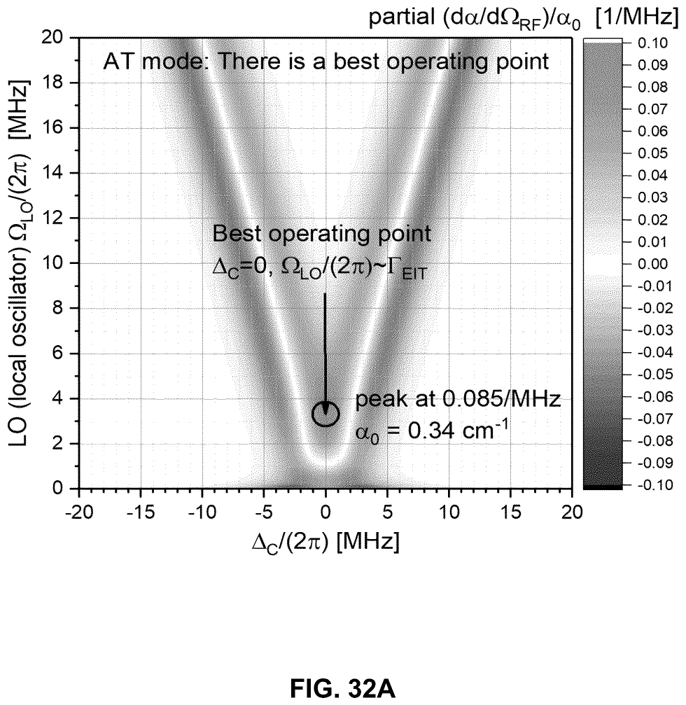

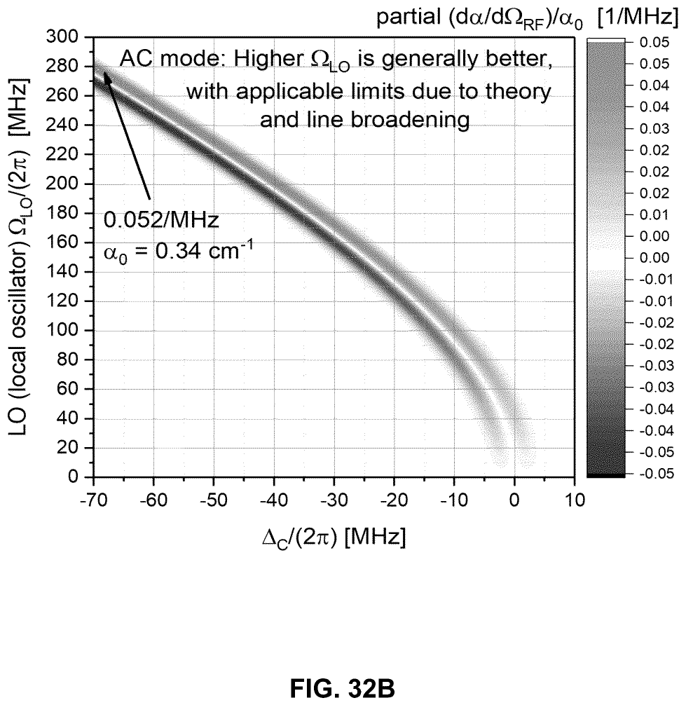

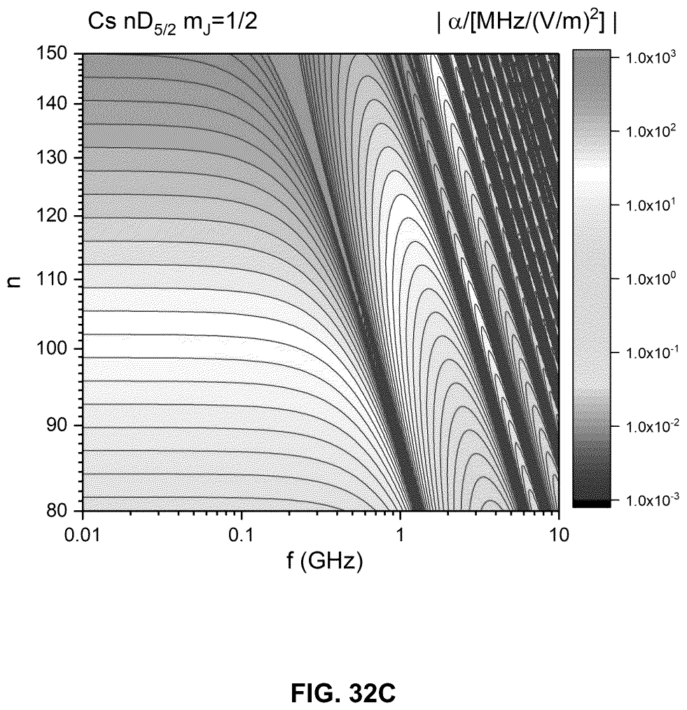

FIG. 32A illustrates RF signal electric-field sensitivity for near-resonant Autler-Townes (AT) versus coupler-laser frequency detuning (x-axis) and atomic Rabi frequency due to the E_{LO} field (y-axis), shown on the given color scale. FIG. 32B illustrates RF signal electric-field sensitivity for off-resonant AC Stark shifts. FIG. 32C illustrates AC polarizabilities for cesium in AC mode, versus quantum number n and RF frequency. Swaths of broadband AC sensitivity are separated by AT resonances that cut diagonally through the diagram as straight lines.

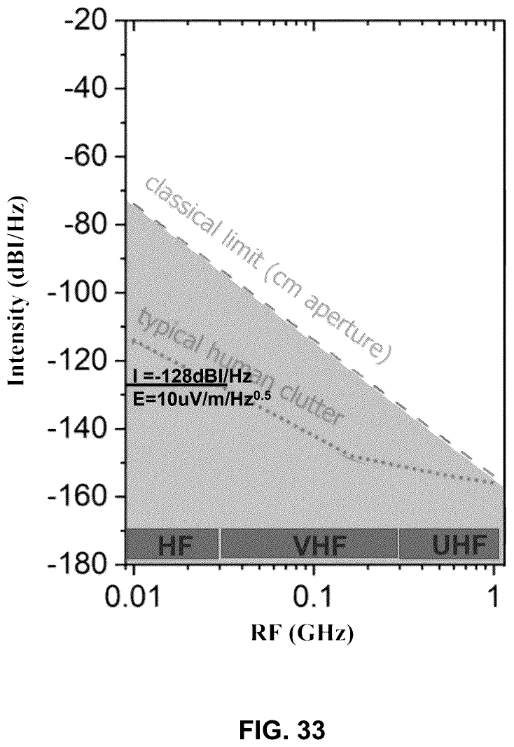

FIG. 33 illustrates sensitivity of atomic and classical sensors for RF from 10 MHZ to 1 GHz including classical limits for a cm antenna sensor (wide dash), exemplary typical human clutter (short dash), and a cm Rydberg EIT vapor-cell sensor in the HF-band from 3 MHz to 30 MHZ (black). The −128 dBI/Hz HF-band sensitivity level lies approximately 40 dB below the classical cm aperture limit, and is not a fundamental limit for Rydberg atom sensing.

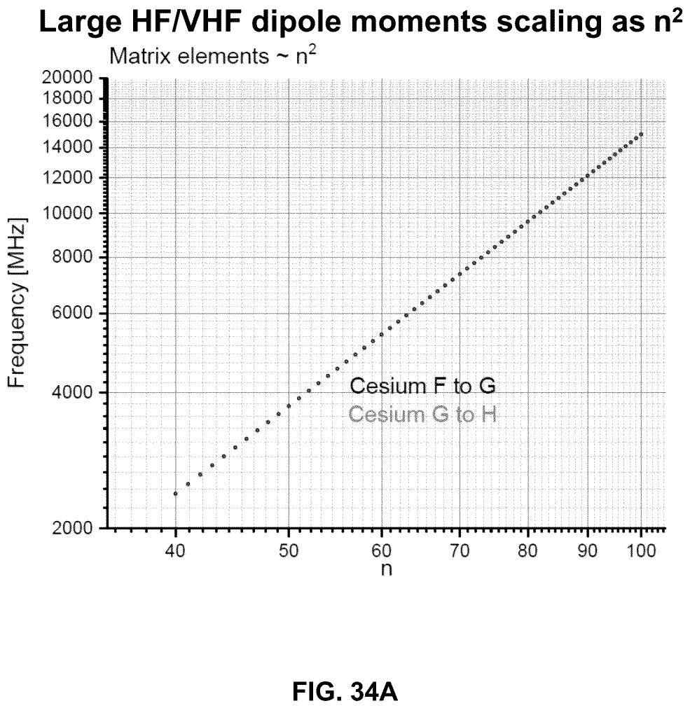

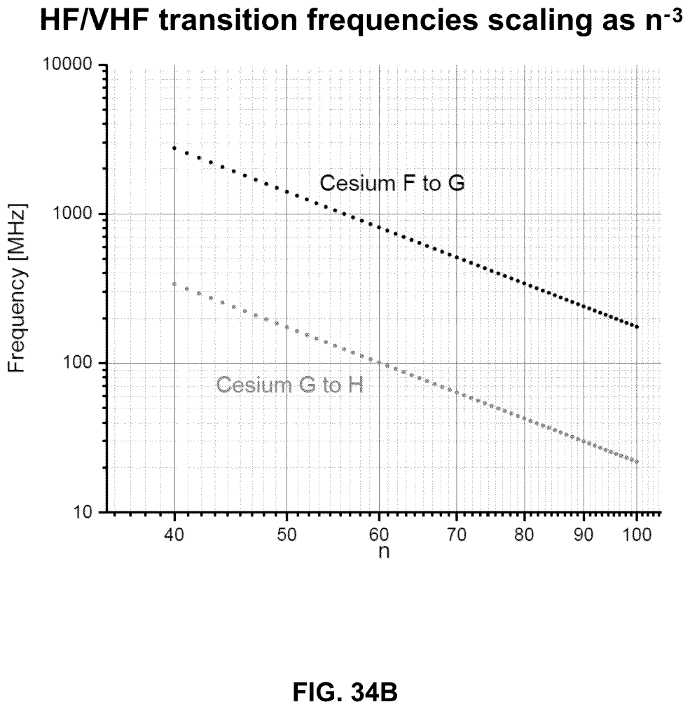

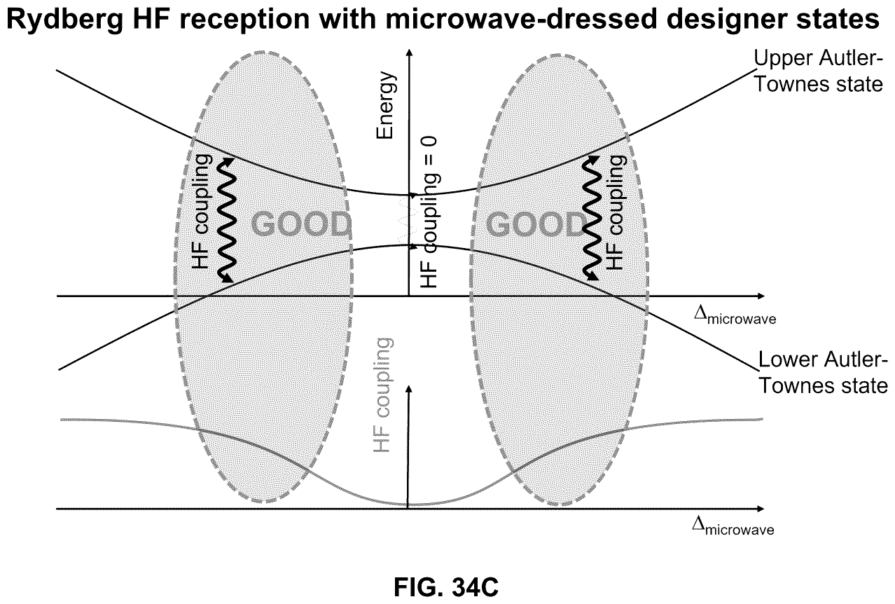

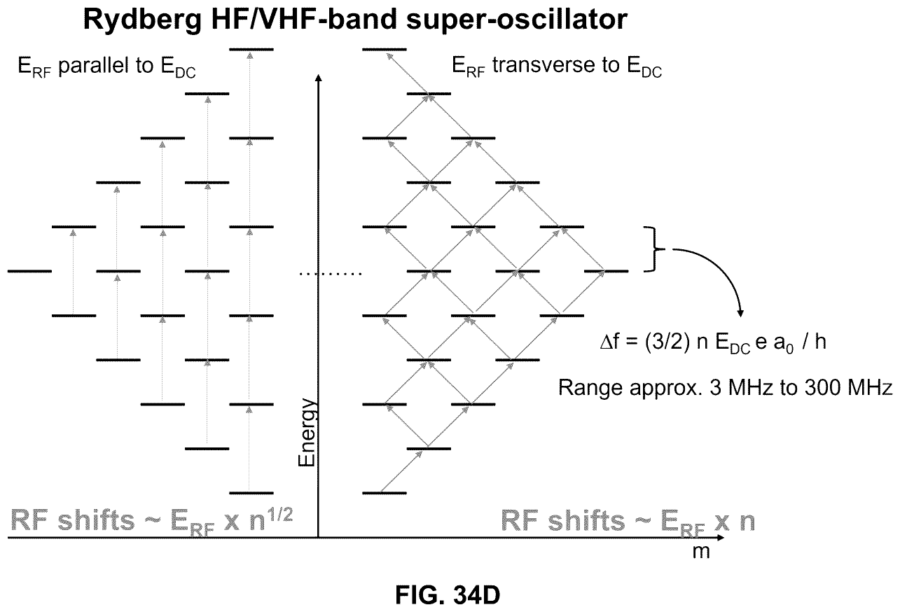

FIGS. 34A-34D illustrate Rydberg HF/VHF-band RF sensing with RF-resonant F-G and G-H high-/Rydberg states of cesium. FIG. 34A illustrates radial dipole matrix elements as a function of principal quantum number n. FIG. 34B illustrates RF frequency as a function of principal quantum number n. The matrix elements are about the same for these transition series, while the frequencies of G-H transitions are about a factor of 10 lower than those of the F-G transitions. FIG. 34C illustrates Rydberg HF sensor with MW-dressed Rydberg states. FIG. 34D illustrates Rydberg HF/VHF-band super-oscillator.

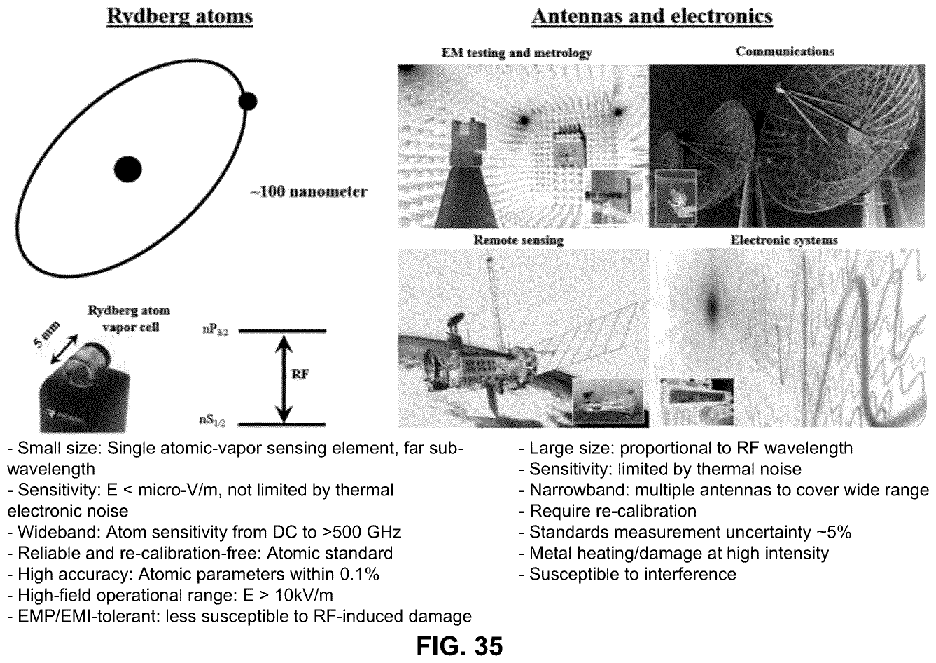

FIG. 35 illustrates Rydberg atoms, antennas, and electronic systems. Rydberg atoms (left side) have small size (single atomic-vapor sensing element, far sub-wavelength), high sensitivity (E<micro-V/m, not limited by thermal electronic noise), wideband (atom sensitivity from DC to >500 GHZ), are reliable and re-calibration-free (atomic standard), high accuracy (atomic parameters within 0.1%), high-field operational range (E>10 kV/m), and are EMP/EMI-tolerant (less susceptible to RF-induced change). Antennas and electronics (right side) have large size (proportional to RF wavelength), low sensitivity (limited by thermal noise), narrowband (multiple antennas to cover wide range), require re-calibration, standards measurement uncertainty of ˜5%, metal heating/damage at high intensity, and are susceptible to interference.

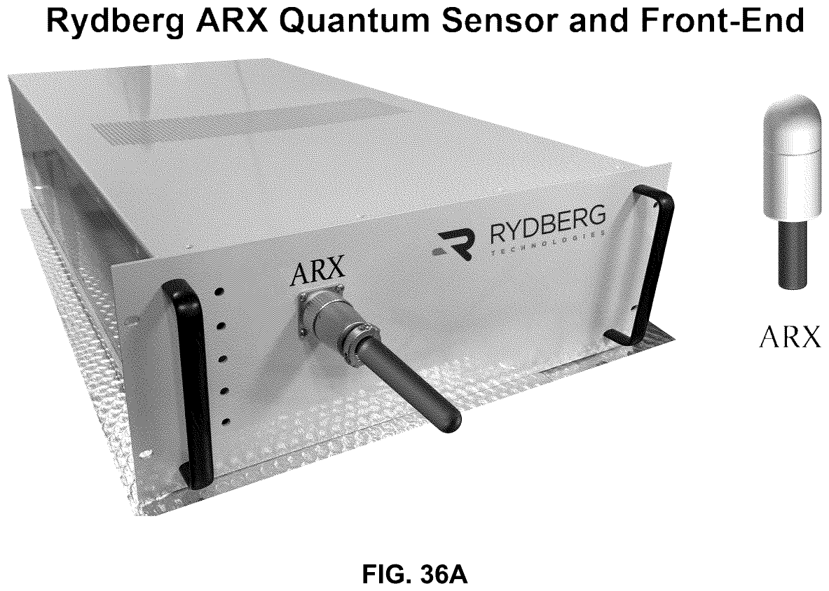

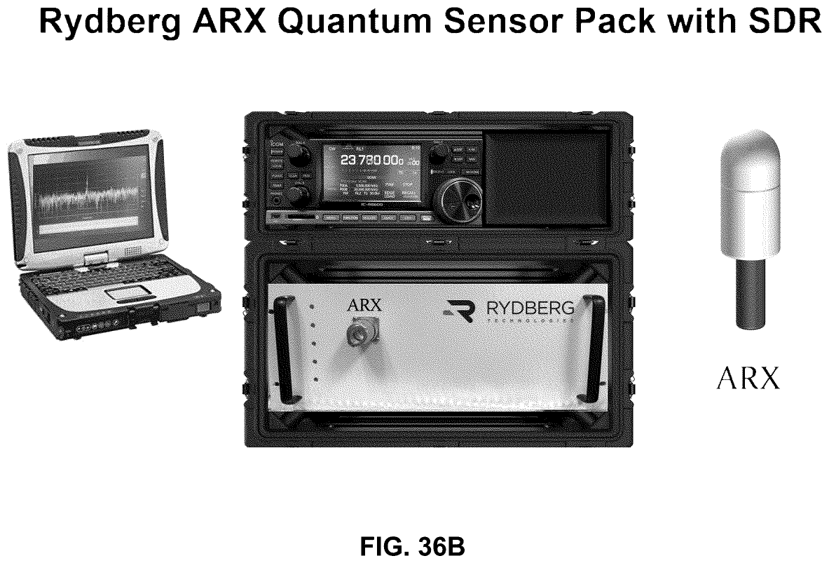

FIGS. 36A and 36B illustrate Rydberg Atomic Receiver (ARX). FIG. 36A illustrates ARX quantum sensor and front-end. FIG. 36B illustrates ARX quantum sensor pack including software defined radio module and computer interface.

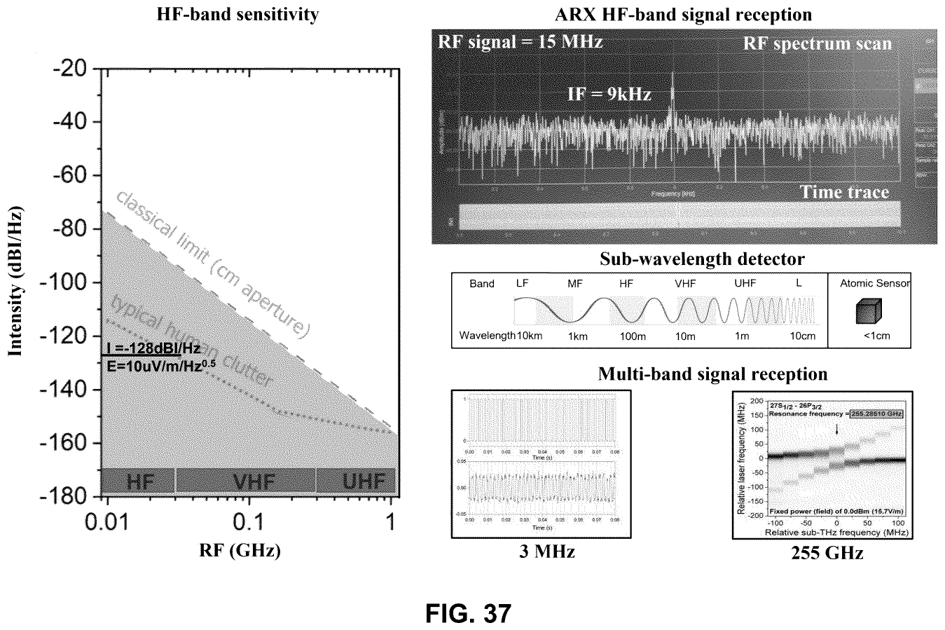

FIG. 37 illustrates ARX capabilities in quantum RF sensing. HF-band sensitivity (left side) illustrates sensitivity of apertures for RF from 10 MHz to 1 GHz including classical limits for a cm antenna aperture (wide dash), typical human clutter (short dash), and a cm ARX quantum aperture in the HF-band (black). The noted ARX HF-band sensitivity is not a fundamental limit, and lies approximately 30 dB below the classical limit. ARX HF-band signal reception (top-right side) illustrates a digitized spectrum of a 15 MHz HF carrier signal received with the ARX. The RF spectrum scan shows the modulated 15 MHz signal at an intermediate frequency of 9 kHz after demodulation by the ARX atomic heterodyne receiver. A time trace of the RF spectrum acquisition is also shown. Sub-wavelength detector (middle-right side) illustrates RF wavelength from LF to L-bands and atomic vapor-cell sensor length comparison. Multi-band signal reception (bottom-right side) illustrates multi-band signal reception by a Rydberg atom vapor-cell detector for a frequency-shift keying (FSK)-modulated 3 MHZ (HF-band) signal and continuous-wave 255 GHZ (millimeter-wave band) signal.

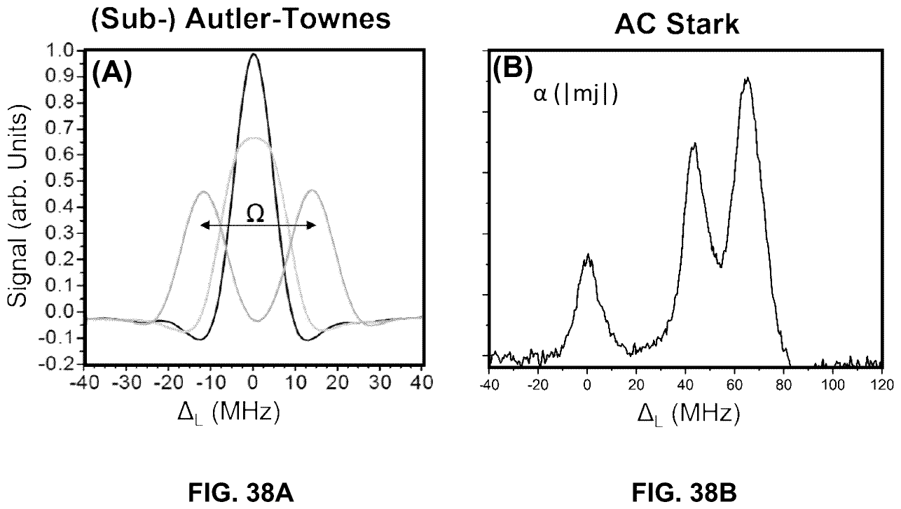

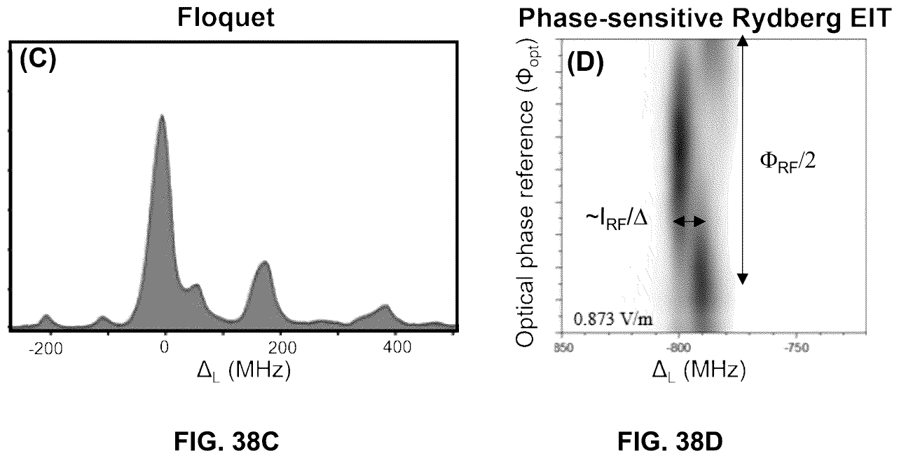

FIGS. 38A-38D illustrate regimes of Rydberg atom-field response. FIG. 38A illustrates Autler-Townes and sub-Autler-Townes splitting for resonant and near-resonant RF fields. FIG. 38B illustrates AC Stark shifts for sensing of far-off-resonant RF fields. FIG. 38C illustrates complex Floquet spectroscopy for sensing of RF fields in the strong-field regime. FIG. 38D illustrates a 5 GHz RF phase and amplitude measurement with a phase-sensitive optical Rydberg probe in the Autler-Townes atom-field regime.

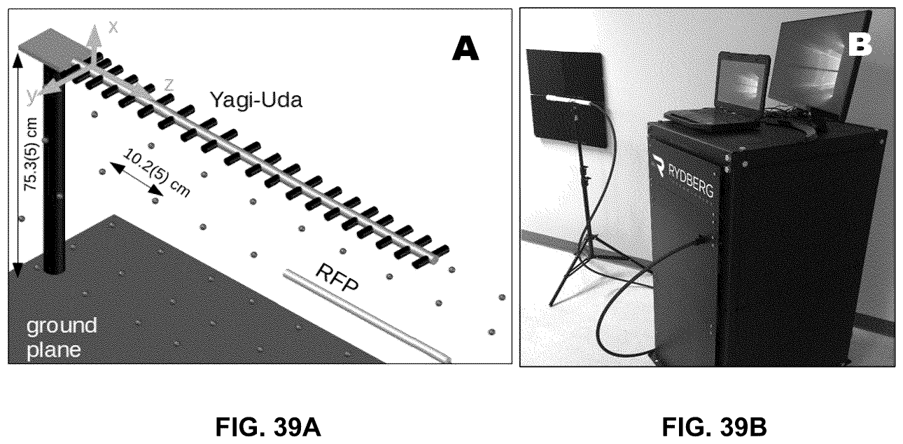

FIG. 39A illustrates a test setup orientation of the RFP with respect to the Yagi-Uda antenna as the RFP is translated over a ground plane. The red dots represent electric field measurement locations. FIG. 39B illustrates the RFP and RFMS.

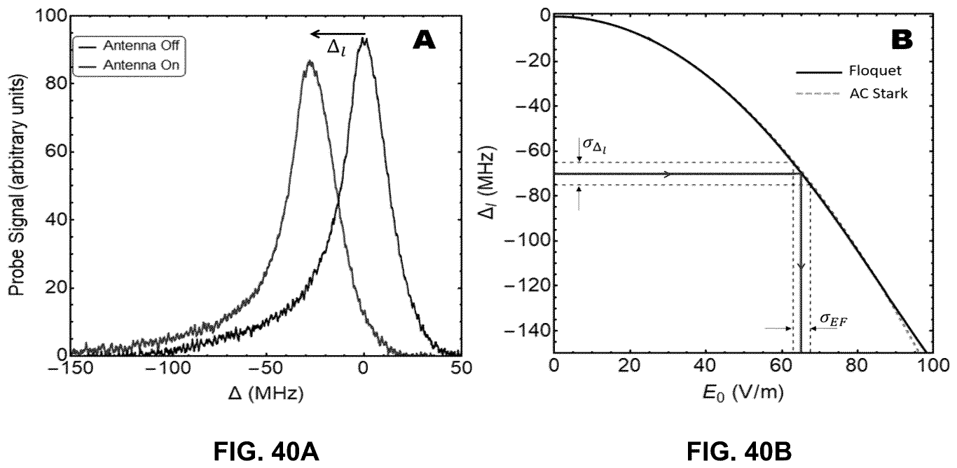

FIG. 40A illustrates sample EIT spectra of the Cs Rydberg state 70S_{1/2} acquired with the RFP located near an antenna transmitter without (black) and with (blue curve) a 2.5 GHZ RF field applied. FIG. 40B illustrates calculated AC shift AL of the same state using α₀(2π×2.5 GHZ)=0.0648 MHz/(V/m)² (dashed) and Floquet theory (solid curve) for a 2.5 GHz microwave field. E-fields are determined from measured AC shifts Δ_{L} and uncertainty σ_{ΔL} converted to RF electric-fields E₀ with uncertainties OFF, using the Floquet calculation for shift-to-field conversion (blue arrows).

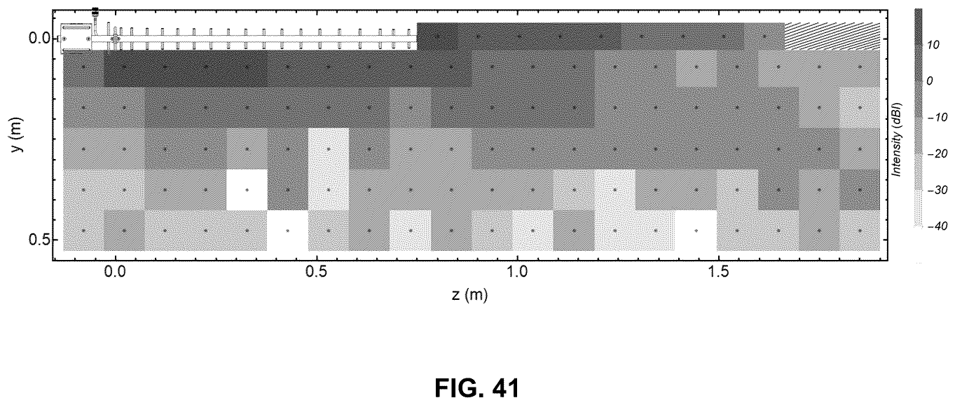

FIG. 41 illustrates a map of the electric-field radiation pattern of a Yagi-Uda antenna transmitting at 2.5 GHz. Each gray dot represents the position of the RFP during measurement, with step size Δy=Δz=0.102±0.005 m. The map includes a to-scale model of the Yagi-Uda antenna at its testing position. Local RF intensities are plotted in dBI, where dBI=10 log[½ε₀E₀²/(W/m²)].

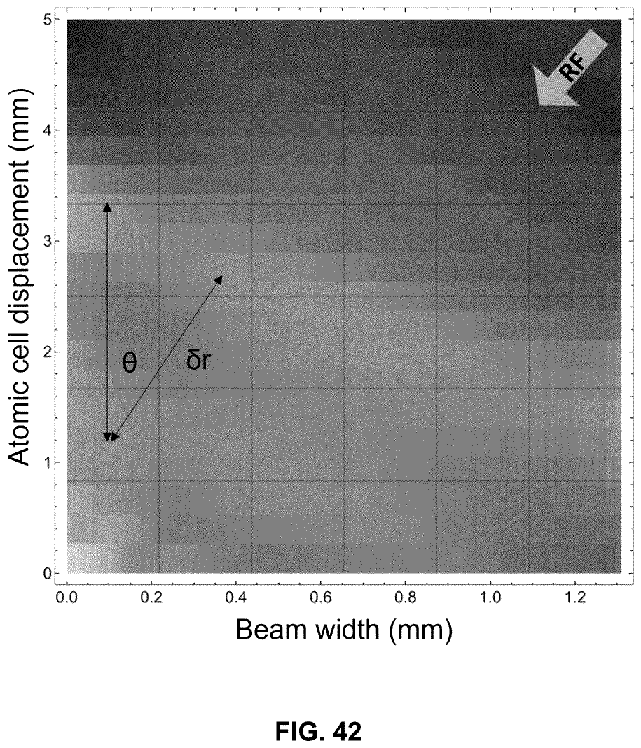

FIG. 42 illustrates a 2D image of a 100 GHz RF signal phase using a Rydberg imager probe with optical Rydberg EIT fluorescence readout and RF self-homodyning.

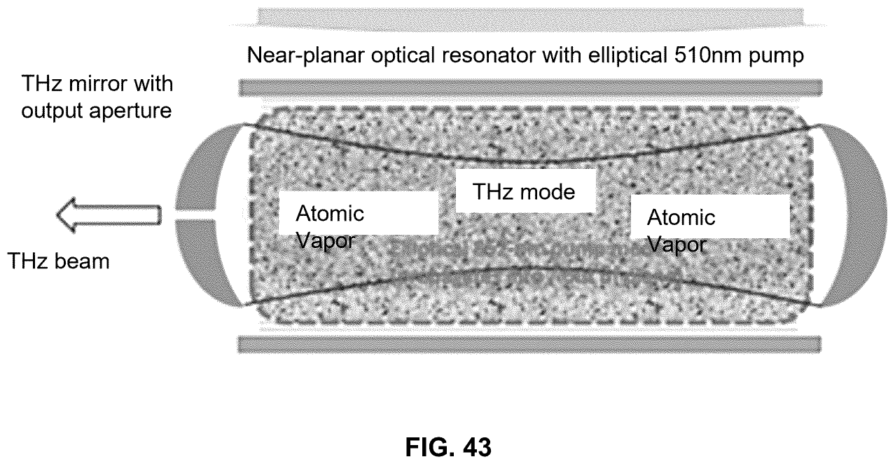

FIG. 43 illustrates a high-frequency (THz) maser concept for a cesium implementation.

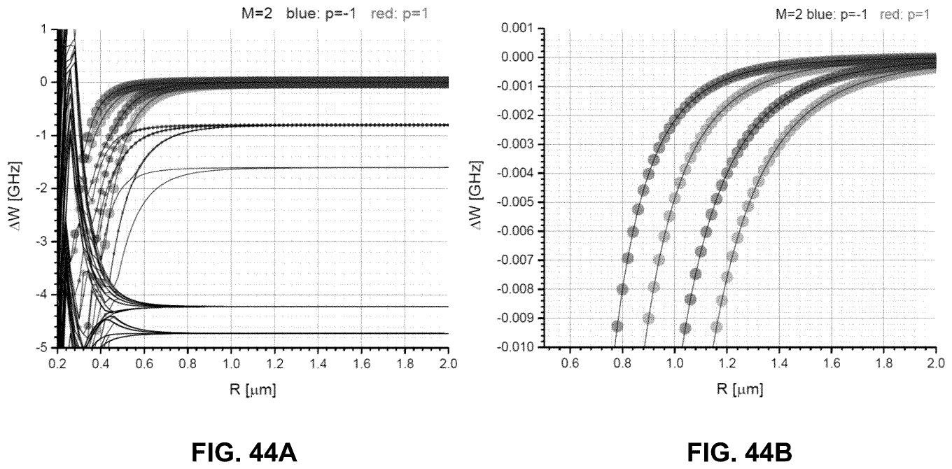

FIGS. 44A and 44B illustrate Rydberg pair potentials for (Rb 25D_{5/2})2 and total angular momentum M=2 along the internuclear axis, for both parities p of the two-body molecular states. FIG. 44A illustrates symbol areas are proportional to excitation rates from 5P_{3/2}, averaged over all alignment angles between the circularly polarized excitation-laser direction polarization and the internuclear axis. FIG. 44B illustrates a zoom-in of the plot shown in FIG. 44A, showing the long-range van-der-Waals interactions.

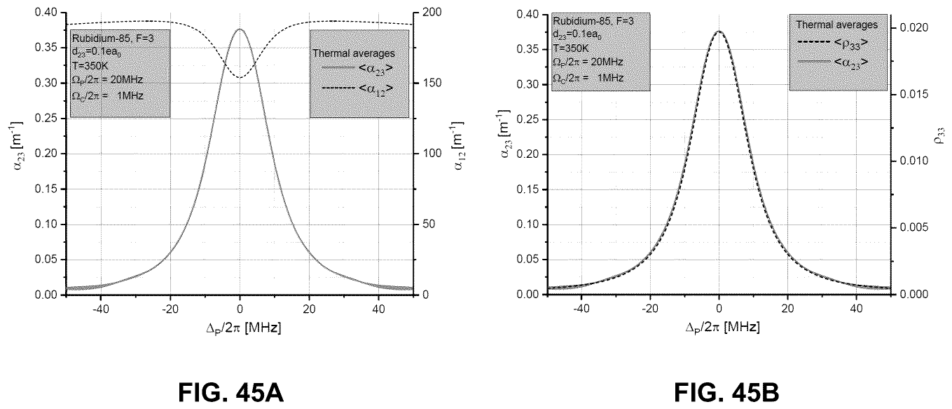

FIGS. 45A and 45B illustrate absorption coefficients on the upper (solid; Ω_{C}) and lower (dashed; Ω_{P}) transitions for the indicated Rabi frequencies vs the detuning of the lower-transition laser from resonance. The upper transition laser is on-resonance and fixed in frequency. FIG. 45A illustrates EIT (dip in dashed curve) as well as the typical absorption levels on the transitions. FIG. 45B illustrates upper-transition absorption coefficient and Rydberg-state population vs lower-transition detuning.

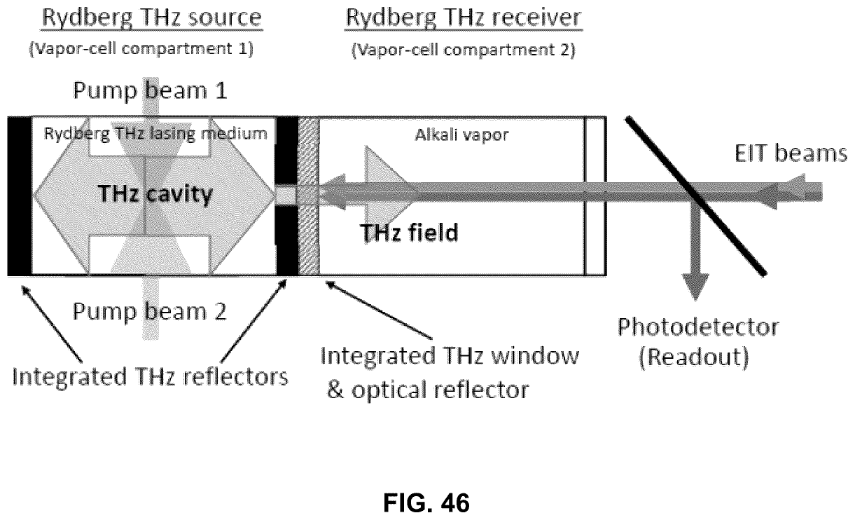

FIG. 46 illustrates a THz source and matched receiver. Note source/Tx and receiver/Rx can be joined or separated physically.

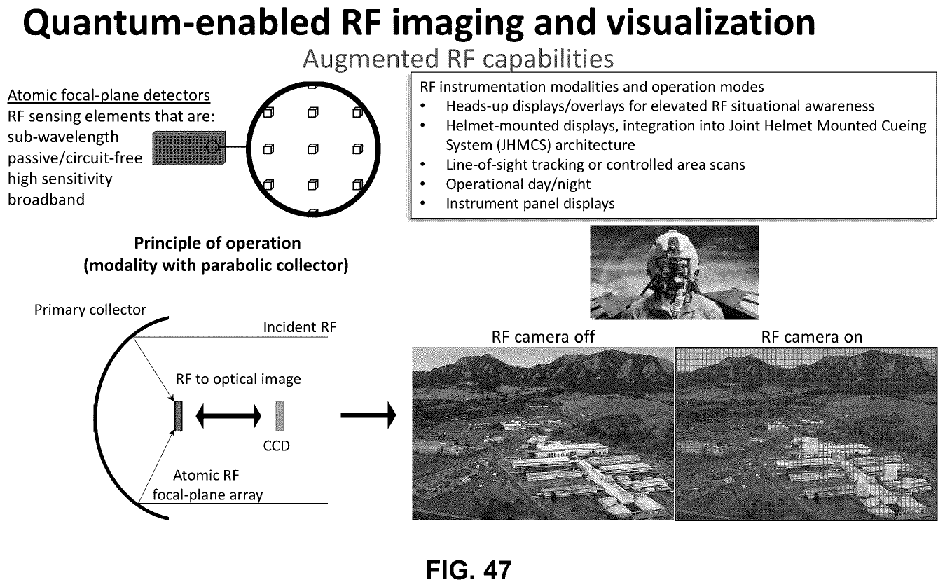

FIG. 47 illustrates an atomic focal-plane detector for augmented RF imaging and visualization capabilities. For example, the atomic focal-plane detector can include RF sensing elements that are sub-wavelength, passive/circuit-free, high sensitivity, and broadband, and can be coupled with a parabolic collector and CCD to convert incident RF signals into an optical image. Augmented RF capabilities can include heads-up displays/overlays for elevated RF situational awareness, helmet-mounted displays and integration into Joint Helment Mounted Cueing System (JHMCS) architecture, line-of-sight tracking or controlled area scans, operational day/night, instrument panel displays, or a combination thereof.

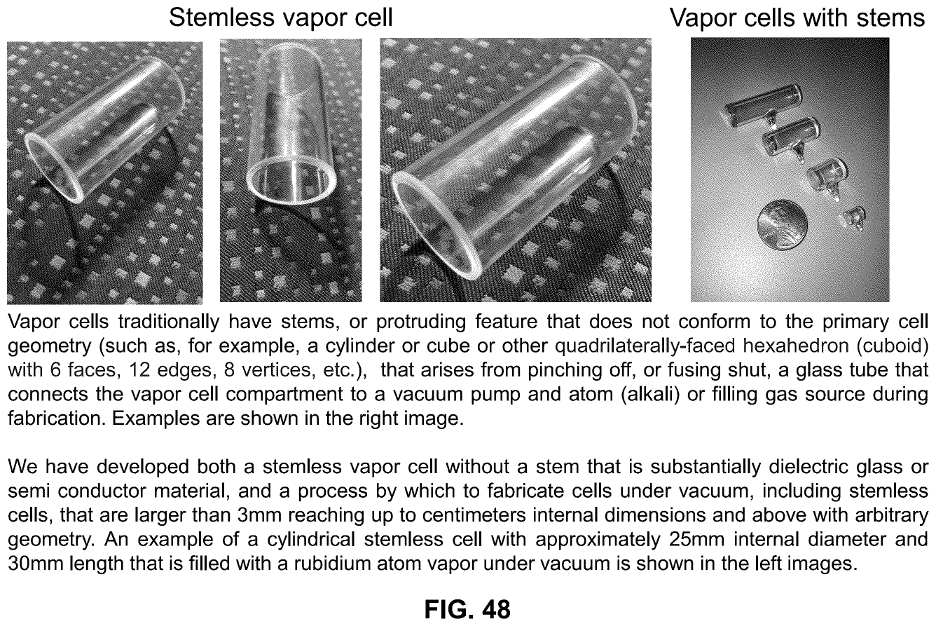

FIG. 48 illustrates a comparison of vapor cells with stems (right side) and newly developed stemless vapor cells (left side). Vapor cells traditionally have stems, or a protruding feature(s) that does not conform to the primary cell geometry (such as, for example, a cylinder or cube or other quadrilaterally-faced hexahedron (cuboid) with 6 faces, 12 edges, 8 vertices, etc.), that arises from pinching off, or fusing shut, a glass tube that connects the vapor cell compartment to a vacuum pump and atom (alkali) or filling gas source during fabrication. Examples are shown in the right image. A stemless vapor cell without a stem has been developed that is substantially dielectric glass or semiconductor material, and a process by which to fabricate cells under vacuum, including stemless cells, that are larger than 3 mm reaching up to centimeters internal dimensions and above with arbitrary geometry has been developed. An example of a cylindrical stemless cell with approximately 25 mm internal diameter and 30 mm length that is filled with a rubidium atom vapor under vacuum is shown in the left images. The stemless cell fabrication includes the fabrication of a primary cell compartment, a device for temperature regulation and the bake out of materials, evacuation of the cell compartment to generate a vacuum or desired background gas pressure in and around the cell, the insertion of the desired atomic gas using a jet of alkali metal such as by heating a getter with a nozzle akin to an inkjet printer mechanism, and the vacuum sealing of the cell compartment with the vapor inside using a window or component in a manner conforming to the primary or otherwise specific geometry desired of the cell, the sealing being done by frit bonding, fusing, anodic bonding, or similar method. The device and process also includes a light source to generate a fluorescence or absorption signal from the atomic vapor, background gas, or cell material for monitoring parameters of the fabrication process. While small millimeter-size and smaller MEMS cells and anodically bonded or optically contacted vapor cells can be fabricated without non-conforming stems in vacuum, the size and geometry of these cells are limited and have not been fabricated with internal volumes larger than approximately 3 mm. This is due to materials required, such as the etching/drilling depths through a Si wafer frames in anodically bonded MEMS cells, and the in-vacuum filling chambers and devices do not provide the means to fabricate/fill/fuse larger vapor cells, reaching up to centimeters in length and larger.

A majority of classical (non-atom) radio devices may have an architecture comprised of different sections: first, an antenna or aperture section that sends or receives/collects one or more signals of interest and guides or converts it to an electrical signal; second, a front-end circuit section that performs signal conditioning on the electrical signal such as signal amplification, mixing, filtering, and regulation; and third, a receiver section the performs processing on the signal and electrical controls on any front-end circuitry. The front-end and receiver sections employ different combinations of analog and digital conditioning and processing stages depending on the design, with modern day software defined radio (SDR) performing a substantial amount of the signal conditioning and signal processing directly in the digital domain enabled by high sample-rate analog-to-digital converters. A classical direct-conversion superheterodyne receiver, as an example of this architecture, takes the electrical signal from the antenna or aperture and mixes it with at least one local oscillator signal generated by the front-end/receiver sections, low-pass filters the output, and therewith conditions the signal to an intermediate frequency (IF) for signal processing.

An atom radio apparatus shares similar functional objectives as a classical radio architecture but requires a uniquely different architecture and incorporates different subsystems for performing atom-based radio signal transmission and reception. An atom radio is shown in FIG. 1 and described in the caption. In one embodiment, an atom radio is comprised of an atomic vapor for the transmission and or reception of an electromagnetic signal wave, a conduit such as free-space mode, optical element or fiber to guide light for spectroscopy on the atoms of the vapor modified by the electromagnetic wave, an optical signal conditioning circuit to modulate or filter the guided light, a detector or optical transducer to convert guided light into an electrical signal, an electrical signal conditioning circuit to mix, modulate, filter, or regulate the electrical signal derived from the light, and a processor circuit for processing the conditioned electrical signal.

### An Atomic Millimeter-Wave Receiver

Rydberg quantum sensors are sensitive to radio-frequency fields across an ultra-wide frequency range spanning DC to Terahertz electromagnetic waves resonant or off-resonant with Rydberg atom dipole transitions. This includes ELF, SLF, ULF, VLF, LF, MF, HF, VHF, UHF, SHF, EHF, and THE bands. This disclosure describes an atomic millimeter-wave heterodyne receiver employing lasers stabilized to an optical frequency comb. The atomic receiver is characterized in the W-band at signal frequency of f=95.992512 GHz, and demonstrates a sensitivity of 7.9 μV/m/\sqrt{Hz} and a linear dynamic range greater than 70 dB. This disclosure describes frequency selectivity metrics for atomic receivers and demonstrates their use in a millimeter-wave receiver, including signal rejection levels at signal frequency offsets Δf/f=10⁻⁴, 10⁻⁵, and 10⁻⁶, as well as 3-dB, 6-dB, 9-dB and 12-dB bandwidths, and a responsivity shape factor. This disclosure represents an important advance towards future studies and applications of atomic receiver science and technology and in weak millimeter-wave and high-frequency signal detection, as well as for new Rydberg excitation, spectroscopy, and quantum technology laser systems and hardware.

Rydberg-atom based sensors are a competitive technology platform for radio-frequency (RF) sensing and for detecting RF electric (E)-fields on-resonant and off-resonant with Rydberg-atom electric-dipole transitions over a broad field and frequency range from MHz to THz, with self-calibration and SI-traceability. Atomic field sensor devices have been developed and implemented for applications including near-field and wide-area antenna measurement and imaging and atom radio reception. The combination of electromagnetically induced transparency (EIT) and spectroscopic readout of field-induced Rydberg level changes such as Autler-Townes (AT) splittings and AC shifts for atomic electric field determination and measurement allows Rydberg-atom electrometry to outperform traditional methods of measuring RF field properties, such as amplitude, frequency, phase, polarization, and angle of arrival. The measurement of small E-field amplitudes with ultra-high sensitivity is critical in metrology and sensing applications, as well as in understanding bandwidth and selectivity performance characteristics of atomic receivers. Atomic receiver selectivity, despite being essential to establish the performance of atomic sensors, has heretofore not been explored. Further, although sensitivity measurements of microwave (MW) E-fields around 10 GHz carrier frequencies have been progressing, and V/m field measurements have been conducted using atom-based field determination method at 100 GHz with vapors in subwavelength-imaging and equipment testing, Rydberg atom sensors and heterodyne receivers at frequencies in the millimeter-wave (MMW) band reaching 100 GHz and above have not been realized, nor have atom radio receiver collective performance metrics including sensitivity, selectivity, bandwidth, and dynamic range been established. The selectivity of a traditional radio receiver is a measure of the receiver's ability to reject unwanted signals that are at frequencies near the channel in use. In radio applications receiver selectivity dictates achievable channel bandwidths and the quality of signals received based on rejection levels of signals on adjacent channels. Achieving high receiver selectivity is particularly critical when receiver operation requires mitigation of blanketing, e.g., receiver blocking by strong unwanted signals, and other intentional or unintentional electromagnetic interference. Applications of millimeter-wave atomic receivers requiring highly sensitive and selective sensors include high-frequency (>100 GHz) wideband wireless communications, next-generation mobile devices (6G), and millimeter-wave imaging devices.

In one embodiment, a MMW atomic receiver and an atom radio employ a frequency-comb and atom/optical stabilized Rydberg lasers. The atomic receiver incorporates a cesium vapor detector using two-photon Rydberg electromagnetically induced transparency (EIT) with lasers locked to an optical frequency comb (OFC) for reduced optical noise and optimized operating laser parameters. The receiver implements a MMW heterodyne (HET) architecture with a local oscillator (LO) reference field providing phase- and frequency-sensitivity and increased atomic receiver responsivity to signal fields. A minimum field sensitivity of 7.9 uV/m/\sqrt{Hz} and a linear dynamic range of >70 dB are demonstrated for a signal field freqeuency f_{SIG}=95.992512 GHZ, which is resonant with the 37²S_{1/2} to 36²P_{3/2} MMW transition of Cs. This disclosure describes the selectivity of atomic apertures for MMW sensing. Atomic aperture receiver selectivity arises from signal filtering in the analog front-end afforded by the physics principles of the atom-field interaction that occurs in the field sensing element. The filtering in the atom-optical domain occurs prior to any electronic filtering analog or digital signal processing, which may be employed in a separate stage in an atom radio. The receiver selectivity to the signal field is characterized by measurements of the atomic response to MMW signals offset by up to Δf=±15 MHz relative to the LO.

Rydberg Atom Sensor and Laser Systems with an Optical Frequency Comb

A primary design requirement for atomic sensors to perform their intended application functions, including reaching state-of-the-art sensitivity levels, is to account for and address noise sources that may limit the detection of RF E-fields with the atoms. In atomic radio receivers, the noise sources fall into two main categories, namely noise occurring in the front-end atomic vapor cell element, and noise from system hardware and electronics. The latter category includes noise from optical subsystems, excess noise from the photodiode detectors and amplifiers used to read out the EIT signal, and excess noise in the downstream electronic signal processing. The former category includes interactions of the sensor atoms in the vapor cell with incoherent electromagnetic fields, such as blackbody thermal radiation as well as radio-frequency noise, with fields present within the vapor cell, and with other atoms and background gases. Additional noise may arise from unwanted coherent electromagnetic fields entering the cell, as well as from inhomogeneities of electric fields to be measured and of tuning fields.

An orthogonal categorization of noise relates to whether a noise source is technical or fundamental in nature. The net noise level of the entire system is often set by the sum of all technical noise sources. However, there are fundamental (physical) limits that include atomic shot noise limits, optical shot noise limits for the weak EIT probe light, single-atom EIT dynamics, atom-field interaction times and Doppler shifts in the atomic vapor cell, black-body fields from sensing-element materials in the vapor cell, and electronic shot noise and Johnson noise limits.

On the laser side, the fundamental noise set by the Schawlow-Townes limit is outweighed by technical, non-fundamental noise. A critical technical limitation of hardware in atom-based quantum devices is the excess frequency jitter and amplitude noise from the lasers sources used to interrogate the quantum states of the atoms. In Rydberg sensing based on atomic vapors where multi-wavelength (e.g. two-, three-, and four-photon) Rydberg EIT approaches are typically implemented, the technical frequency and amplitude noise of each laser source can limit the achievable atomic sensor sensitivity to electromagnetic fields as well as the fidelity of radio receivers derived from such sensors.

To address this, this disclosure describes an erbium-doped fiber optical frequency comb (OFC) to transfer the linewidth and stability of a high-finesse optical cavity to continuous-wave (CW) Rydberg lasers. These are key elements to advanced metrology applications such as optical clocks, time and frequency transfer, as well as high-resolution spectroscopy. An embodiment of the Rydberg comb laser system and stabilization scheme are depicted in FIG. 11. The femtosecond frequency comb laser is a mode-locked fiber laser at a wavelength of 1550 nm. The repetition frequency (fᵣₑₚ) of this laser is 200 MHZ and can be fine-adjusted over a range of a kHz. The fᵣₑₚ-value is stabilized using a heterodyne beat-note detector for a comb line and a narrow-linewidth (<2 Hz) CW reference laser at 1550 nm, which itself is frequency-stabilized, here, to an ultra-stable high-finesse reference cavity made of ultra-low-expansion (ULE) glass. The 1550-nm/comb optical beat note is amplified, filtered, and phase-locked to a 10-MHz reference signal from a Rubidium clock via a direct digital synthesizer (DDS). The fᵣₑₚ error signal is fed back to piezo-electric tranducers (PZT) that control the laser resonator length.

The locked fᵣₑₚ-value is recorded using a frequency counter. A separate optical beat-note detector allows for carrier-envelope offset frequency (f_{CEO}) detection and stabilization via a standard f−2f interferometer. The optical beat note is amplified, filtered, and phase-locked to the Rb clock by another DDS, with the error signal fed back to the laser pump current. The locked f_{CEO} also is recorded using a frequency counter. Following the OFC stabilization, both 852-nm and 1020-nm lasers are phase-locked to the OFC using two additional heterodyne beat note detectors between the OFC and the lasers. In this way, the 10⁻¹⁴-level relative frequency stability of the 1550-nm reference laser is transferred to the frequencies of the 852-nm and 510-nm Rydberg-EIT lasers used in the atomic receiver.

An example embodiment of a general Rydberg laser architecture including a frequency-comb is shown and described in FIG. 17.

### Millimeter-Wave Atomic Super Heterodyne Receiver

The four-level cesium (¹³³Cs) atom energy-level structure relevant to this demonstration is illustrated in FIG. 12A. The four atomic energy levels |1>, |2>, |3>, and |4> correspond, respectively, to the ground state 6²S_{1/2}, excited state 6²P_{3/2}, and Rydberg states 37²S_{1/2} and 36²P_{3/2}. Rydberg EIT is obtained using a weak probe laser beam at 852 nm comb-locked on the resonant D₂ cycling transition |6²S_{1/2}, F=4)→|6²P_{3/2}, F′=5> (λₚ=852.356 nm) and a strong coupling beam resonant with the |6²P_{3/2}, F=5>→|37²S_{1/2}> (λ_{c}=510.905 nm) Rydberg transition. The 852-nm probe laser is an external cavity diode laser (ECDL), and the 511-nm coupling laser is a frequency doubled tunable 1020 nm ECDL laser. The probe beam has a power of 158 μW, a full-width at half maximum (FWHM) of 636 μm and a Rabi frequency Ωₚ/2π=16.9 MHz. The coupling beam has a power of 60 mW, a beam FWHM of 1.1 mm and a Rabi frequency Ω_{c}/2π=0.9 MHz. The optical Rabi frequencies are given for the peak power at the center of the Gaussian beams, providing an upper limit. A schematic of the experimental apparatus is shown in FIG. 12B. The probe and coupling lasers are counter-propagated, collimated, and overlapped within a cylindrical glass vapor cell of length L=30 mm containing a room-temperature vapor of Cs atoms. The power of the transmitted probe beam is recorded with a photodiode, the signal of which is amplified and recorded either by a Spectrum Analyzer (SA) for frequency analysis or digitized in real-time for time-domain signal analysis.

On-resonant Autler-Townes (AT) splitting is used to calibrate the MMW E-fields of both LO and signal fields inside the vapor cell that are generated from the MMW transmission line. The fields are calibrated by recording AT-split Rydberg EIT spectra, scanning the coupling-laser detuning Δ_{c}, while the probe laser is stabilized to the |6²S_{1/2}, F =4>→|6²P_{3/2}, F′=5> D₂-cycling transition (probe detuning Δₚ=0). The coupling-laser detuning, Δ_{c}, is scanned by tuning the DDS associated with the 1020 nm-laser (see FIG. 11).

While useful to calibrate the LO and signal (SIG) E-fields, E_{LO} and E_{SIG}, the measurement of AT splittings is not a viable approach for the sensing of weak E-fields field sensing, where the signal's atom-field interaction Rabi frequency is below the EIT linewidth, rendering field-induced spectral changes too small to accurately resolve (see e.g., FIG. 13B). For weak-field measurements, the MMW atomic receiver incorporates a compact cesium atomic vapor cell and optical readout of RF-sensitive Rydberg states using two-photon Rydberg EIT and a MMW heterodyne (HET) architecture. FIG. 12B shows the atomic MMW receiver setup. The atomic MMW HET uses an LO field E_{LO} as a frequency reference, with a frequency near-resonance with the Rydberg transition. The LO field is superimposed in the atomic vapor with a weak SIG field E_{SIG} of interest at a frequency detuning δ from the LO frequency. The atoms respond to the time-varying field superposition oscillating at the difference frequency between E_{SIG} and E_{LO}, or intermediate frequency (IF), which is detected optically.

The E_{LO} and E_{SIG} fields are generated by two independent signal generators (SG), generating \tilde{f}_{LO}=15.998740 GHz and \tilde{f}_{SIG}=15.998752 GHz, both synchronized to a common 10-MHz reference from a Rubidium clock. Each SG field is passed through a 6× multiplier to generate MMW fields at frequencies f_{LO}=95.992440 GHz and f_{SIG}=95.992512 GHz that are subsequently combined into a horn antenna and directed over-the-air to the atomic vapor. The emitted fields are linearly polarized along the z-direction. The horn antenna is placed at a distance d=100 mm from the center of the vapor cell in the antenna far-field

$$d > \frac{2 {a}^{2}}{{λ}_{R F}} = 88.5 mm ,$$

where α=11.757 mm is the diagonal of the horn antenna and λ_{RF}=3.125 mm is the MMW-field wavelength. After calibrating E_{LO} and E_{SIG}, the IF beatnote f_{IF}=δ=72 kHz is measured as described next.

### Responsivity

Understanding the responsivity of atomic receivers to signal fields is a prerequisite to a systematic characterizations of their performance and their operation in applications. FIGS. 13A-13C characterize the responsivity of the atomic receiver to weak MW (10 GHZ) and MMW (100 GHz) fields resonant with atomic Rydberg transitions. FIG. 13A illustrates the behavior of the probe absorption in the atomic EIT medium α(E_{RF}, Δ_{c}) as a function of an applied RF electric field of the form E_{RF}=E_{LO}+E_{SIG} with a laser detuning Δ_{c}=0. The highest sensitivity to a small change in the field, ΔE_{RF}, is achieved when E_{LO} is set to a value of maximum slope (e.g., an inflection point) on the curve α(E_{RF}, Δ_{c}=0). It is thus seen that the exact LO field value is critical because the LO must shift the operating point away from E_{RF}=0 to a locus where the response to small field changes, ΔE_{RF}, is maximal and linear, and where the dynamic range in ΔE_{RF} is large.

A figure of merit is established for the responsivity as Δα/ΔE_{RF} on the (Δ_{c}, E_{LO})-plane. In FIG. 13B, Δα/ΔE_{RF} is measured for the atomic receiver on the Cs 42²D_{5/2}↔43²P_{3/2} Rydberg transition for near-resonant LO and SIG MW frequencies around 9.940 GHz as a function of Δ_{c} and E_{LO} for a fixed, small E_{SIG}. This responsivity plot for resonant RF has the shape of a rotated Y; therefore referred to as a “Y-map”. For the set of atomic-receiver parameters used, the best operating point with the highest Δα/ΔE_{RF} is located where the diagonal legs of the “Y” intersect, highlighted in the red box (inset) in FIG. 13B. The highest responsivity occurs at the operating point labeled A, which resides at said intersection point of the Y-legs with the Δ_{c}=0-line. Operating point A corresponds with a well-defined E_{LO}-value that yields best signal response.

Several secondary operating points, two of which are labeled B on the Y-map that occur at the same E_{LO}-value as A, but at symmetric non-zero detunings Δ_{c} of approximately ˜10 MHz. The B-points have a responsivity of about 8.4 dB less than that of point A. This is shown in FIG. 13C for the Cs 37²S_{1/2}↔36²P_{3/2} Rydberg transition at a MMW frequency of 95.992440 GHz.

### Sensitivity and Dynamic Range

This disclosure describes an atomic sensor architecture and its characteristic responsivity to MMW fields to maximize the responsivity Δα/ΔE_{RF}, under the constraint that the signal-to-noise ratio (SNR) of its IF output, as defined in FIG. 13C, also is maximal. The sensitivity is maximized on operating point A by a parameter optimization on all optical powers, optical detunings Δ_{c} and Δₚ, MMW LO power, and RF detuning δ. This allows a minimum E-field sensitivity to be established. In addition, the linear dynamic range of the MMW atomic receiver can be established at operating point A for a 95.992440 GHz W-band SIG test field.

FIG. 14A shows the signal analyzer RMS voltage as a function of 95.992440 GHz SIG electric field for the Cs 37²S_{1/2}↔36²P_{3/2} MMW transition of Cs (dipole moment D=1150 ea₀×0.4714, where 1150 ea₀ is the radial and 0.4714 the angular matrix element). A minimum detectable MMW E-field is given by the intercept of the blue line, which extends the linear response into the low-field regime to the noise floor. The field value of the intercept at the noise floor yields a minimum detectable MMW field, which establishes the sensitivity figure of the Rydberg MMW receiver. Here, this is Eₘᵢₙ=7.9 μV/m for a 1-second integration time, limited by residual optical technical noise. FIG. 14A further shows that the receiver exhibits a linear response over a 35-dB-wide range in MMW electric field, starting at ˜0.3 mV/m/\sqrt{Hz} and beginning to saturate at ˜1 V/m/\sqrt{Hz}, where the voltage levels off as a function of field. This finding corresponds to a linear dynamic range of about 70 dB in MMW power. FIG. 14B shows signal-analyzer (SA) spectra in dBm centered at the 72 kHz IF and measured at the four lowest SIG fields shown in FIG. 14A (values provided in the legend in units V/m/\sqrt{Hz}).

### Selectivity

The selectivity of a traditional RF receiver is largely dictated by the signal response characteristics of the antenna and front-end mixer, amplifier, and filtering electronics. For the atomic receivers with external LO fields, a novel type of selectivity filter is naturally provided by the quantum-optical EIT response of the atoms to the detected fields within the receiver's atomic vapor cell, in which the SIG field first interacts and interferes with the LO field in the atomic medium. Here, the selectivity is characterized from the readout of the atomic HET comprising the Rydberg-atom EIT and LO field system, which serves as the first frequency selector for the incoming SIG wave.

To establish a selectivity metric for an atomic receiver's ability to naturally reject out-of-band interference, a SIG rejection figure can be defined as the receiver's detected SIG power level in dB relative to the detected SIG power level at near-zero IF (where SIG and LO frequencies are approximately equal) at SIG frequency offsets |Δf|/f=10⁻⁴, 10⁻⁵, and 10⁻⁶. Here, |Δf| is the detuning of the SIG field from the LO, equivalent to an intermediate frequency (IF), and f is the carrier (LO) frequency. Table I lists the measured SIG rejection values in dB at the defined |Δf|/f frequency offsets.

TABLE I
SIG rejection in dB, extracted from the Voigt fits, as a
function of |Δƒ|/ƒ

| \|Δƒ\|/ƒ | 10⁻⁶ | 10⁻⁵ | 10⁻⁴ |
|---|---|---|---|
| Rejection (dB) | 8 | 29 | 53 |

As an additional metric to characterize the atomic receiver's selectivity 3 dB, 6 dB, 9 dB, and 12 dB IF bandwidths, or |Δf| cutoff frequencies, can be defined at which the receiver's detected SIG output power relative to the detected SIG output power at near-zero IF drops by 3 dB, 6 dB, 9 dB, and 12 dB. In the following disclosure of these atomic-receiver metrics, the values of the metrics can be extracted from a measurement of the Rydberg receiver's output power as a function of IF frequency over a range of ±15 MHz, for an LO (carrier) with frequency f_{LO}=f=95.992440 GHz (which is resonant with a strong Rydberg transition).

FIG. 15A shows the spectrum-analyzer power readout from the atomic receiver (in dBm) at a signal electric field E_{SIG}=59.6 mV/m as a function of Δf over a range from −15 MHz to +15 MHz. The IF=SIG frequency−LO frequency. The LO frequency f_{LO}=95.992440 GHz is resonant with the Cs 37²S_{1/2}↔36²P_{3/2} Rydberg transition, and the LO field is E_{LO}=0.65 V/m. The measurement is performed for three different coupling powers, P_{c}={48, 38, 28} mW, and Rabi frequencies, Ω_{c}/2π={0.82, 0.73, 0.63} MHz, respectively. FIG. 15B shows a higher-resolved selectivity measurement for the IF ranging from −2 MHz to +2 MHz. A Voigt profile was empirically found to provide the best fit to the measured curves. The Gaussian and Lorentzian linewidths from fits for coupling powers P_{c}={48, 38, 28} mW are found to be Γ_{G}/2π={547, 522, 537} kHz and Γ₁/2π={309, 324, 337} kHz, respectively. The fit functions are then employed to extract the metrics defined above.

The receiver signal selectivity, defined as the ratio comparing the detected wanted signal frequency (SIG=LO) and an unwanted signal frequency (SIG−LO=Δf≠0) in dB for selected frequency offsets |Δf|/f=10⁻⁶, 10⁻⁵, and 10⁻⁴ are shown in Table I. The effect of coupler-power change in FIGS. 15A and 15B largely amounts to a global vertical shift by fixed and small dB-values, and the results in Table I do not depend on coupler-laser power. The signal rejection improves from about 8 dB at |Δf|/f=10⁻⁶ (corresponding to a full IF width of 200 kHz) to as much as 53 dB |Δf|/f=10⁻⁴ (corresponding to a full IF width of 20 MHz). These results highlight the potential for high frequency selectivity and filtering naturally afforded by atomic receivers, prior to any electronic analog or digital signal processing. Further, the atom sensor or radio selectivity can be tuned and engineered for atom radio receivers using control parameters such as laser frequency, power, LO field frequency and power, and more.

IF bandwidths at {3, 6, 9, 12} dB attenuation levels are tabulated in Table II. Over the coupler-power range investigated, little change is observed in the lineshape of the IF response curve in FIGS. 15A and 15B. As such, the data in Table II do not exhibit a significant dependence on coupler power. The results in Table II show that the presently configured millimeter-wave atomic receiver provides high selectivity and narrow bandwidth. Further, the bandwidth can be tuned or engineered for atom radio receivers using control parameters such as laser frequency, power, LO field frequency and power, and more, as well as multiplexing methods and others (see, for example, U.S. application Ser. No. 17/333,503, filed May 28, 2021, now U.S. Pat. No. 11,592,469, which is hereby incorporated herein in its entirety by reference).

TABLE II
IF Bandwidth cutoff frequencies in kHz, extracted from the Voigt fits,
versus compression in dB and coupling-laser power in mW. The results
have only a minor dependence on coupling-laser power.

| Power (mW) | 3-dB (kHz) | 6-dB (kHz) | 9-dB (kHz) | 12-dB (kHz) |
|---|---|---|---|---|
| 28 | 129.8 | 198.6 | 266.8 | 344.7 |
| 38 | 127.4 | 195.6 | 263.9 | 343.2 |
| 48 | 123.3 | 189.8 | 257.2 | 336.6 |

Another useful performance metric is the shape factor of the atom radio receiver filter, defined as the ratio of bandwidths BW_{60 dB}/BW_{3 dB}, e.g. the IF bandwidth (BW) of the response curve at 60 dB signal rejection divided by the BW at 3-dB (or 3-dB BW). In the present case the shape factor is about 100:1, and reduces at BW_{60 dB}/BW_{3 dB} and lower. The shape factor of the atom radio filter may be reduced or changed by tuning or varying other parameters to make appropriate use of the overall available RF signal spectrum in the presence of unwanted signals that must be blocked out.

FIG. 16 shows the receiver's filter roll-off in dB_{c} as a function of Δf, on a log scale. The data points are equivalent with those in FIG. 15A, minus the response at zero IF, Δf=0, taken from the Voigt profile fit. FIG. 16 emphasizes the signal rejection scaling behavior at IF larger than about 100 kHz. The data in FIG. 16 follow a linear trend with a slope of about −2, showing that the rejection scales as |Δf|⁻². This accords with the finding that Voigt profiles deliver good empirical fits to the selectivity spectra. At large argument, the decay of a Voigt profile comes from the wide Lorentzian wings of the profile, which drop off as |Δf|⁻² at large |Δf|.

The present disclosure describes and demonstrates an atomic receiver for millimeter-wave signal detection. This disclosure describes a comb-stabilized Rydberg atomic heterodyne receiver architecture, and the receiver responsivity to microwave and millimeter-wave signal fields has been investigated as a function of receiver reference LO field and coupler laser detuning parameter. An optimal operating point has been identified within this receiver parameter space; several secondary operating points are down in responsivity by 8 dB. This disclosure includes a detailed characterization of the atomic millimeter-wave receiver, achieving 7.9 μV/m/\sqrt{Hz} minimum field sensitivities and a >70 dB linear dynamic range, limited by technical noise and non-linear atomic response in the strong atom-field interaction regime, respectively. This disclosure also establishes a metric for selectivity in atomic receivers as well as a measurement protocol, which has been employed to characterize the selectivity for the atomic millimeter-wave receiver. Selectivity, rejection figures, IF bandwidths, cutoff frequencies, filter roll-off, and shape factors have been quantified. This disclosure describes advances in future studies and applications of atomic receiver science and technology, establishes a new state of the art in millimeter-wave sensitivity and performance metrics with Rydberg atomic receivers, and in weak millimeter-wave and high-frequency signal detection.

### Metrics for Non-Linear Response in Rydberg Quantum RF Receivers: Two-Tone Testing and Intermodulation Distortion

Non-linear responses and intermodulation distortion behavior of an RF receiver system are of critical importance to the receiver's spur-free dynamic range and tolerance to unwanted interfering signals. This disclosure describes the measurement and characterization of non-linear behavior and spurious response of an atom aperture front-end receiver based on Rydberg atoms. Single-tone and two-tone testing procedures are developed for Rydberg atomic heterodyne sensors and receivers based upon multi-photon laser-spectroscopic RF signal pickup in a room-temperature cesium atomic vapor. For a predetermined set of atomic receiver parameters and using near-resonant Autler-Townes transitions at RF carriers in the SHF band, a spur-free dynamic range, 1-dB compression, and third-order (IP3) intercept can be measured. Under suitable operating conditions (atom radio parameter changing/tuning) atomic receivers can exhibit a change and suppression of harmonic and inter-modulation distortion compared with that of classical receiver mixers, and can be characterized by unique RF signatures in the atomic receiver non-linear response that may be exploited in applications. This disclosure describes a compact portable Rydberg atom radio sensor front-end and receiver, or atomic receiver (ARX), and shows VHF and UHF band signal reception with the atomic sensor.

### Atom Radio Receiver Tolerance to Unwanted Interfering Signals and Anti-Jamming

Two-tone and spurious response receiver testing are commonly performed on classical receiver systems to evaluate their spur-free dynamic range and tolerance to unwanted interfering signals. Receiver performance considerations include protection against RF-induced damage to the receiver electronics, the degree of degradation allowed in receiver performance in the presence of strong interfering signals, and overall system performance in the presence of strong RF signals and interference. Here this disclosure translates these concepts from RF engineering to develop analogous testing procedures and to investigate non-linear effects in the quantum-optical Rydberg atom response to RF fields in an atomic receiver. Because the physics principles underlying atom-based RF receivers are very different from those underlying traditional RF electronics, a detailed study of nonlinear behavior in atom-based RF receivers is required for performance and capability comparisons to classical technologies.

### Atomic Receiver Two-Tone Testing

FIG. 27 shows the two-tone testing setup for the atomic receiver. Two tones F₁ and F₂ are generated and combined with a reference local oscillator F_{LO}. The three frequencies are generated using three independent signal generators that are all synchronized to a master atomic clock (not shown). The combined signal F₁+F₂+F_{LO} is coupled into a WR-75 horn antenna (G=10 dBi), which transmits the combined waveform over-the-air to the atomic vapor cell located in the horn far-field. The atomic vapor is a room-temperature cesium vapor in a dielectric cell, this may be made out of pyrex or borosilicate glass and have internal sapphire or similar coatings to avoid charge build up or to modify optical or RF electromagnetic transmission. Two-photon Rydberg electromagnetically-induced-transparency (EIT) spectroscopy is performed on RF-field sensitive Rydberg states excited in the cell using two counter-propagating laser beams at 852 nm (probe beam) and 510 nm (coupler beam). During receiver operation, the coupler laser frequency is stabilized to a target Rydberg resonance (6P3/2 to nD or nS Rydberg state), and the probe laser frequency is stabilized to a hyperfine transition within the Cs D2 absorption line. The probe beam transmission through the atomic vapor is detected on a photo-detector for optical readout of RF-induced changes of the Rydberg atom vapor. The photo-detector signal is read by a Spectrum Analyzer (SA) to measure the power spectrum of the atomic-receiver response.

### Non-Linearity and IMD

Two-tone testing on the atomic receiver is performed to investigate its non-linear response and intermodulation distortion (IMD) characteristics. FIGS. 28A and 28B show measurements using the setup in FIG. 27. The reference local oscillator (REF-LO) of the receiver is supplied by the transmission line and set to a frequency F_{LO}=9.940 GHZ resonant with the Cs 42D_{5/2} to 43P_{3/2} Rydberg transition. Two tones in the SHF band, F1=9.940150 GHz and F2=9.941150 GHz, are simultaneously applied, amounting to an absolute frequency separation of ΔF=F2−F1=1 MHz and a relative frequency separation of ΔF/F_{LO}=10⁻⁴ (F_{LO}=9.940 GHZ). Both F1- and F2-tones are on the high side of the resonant Rydberg transition and have equal atom-calibrated electric-field strengths which can be varied in tandem. The atomic receiver mixes down the applied SHF-band RF carrier waves to intermediate frequencies (IF) at the difference frequencies of the applied carrier waves (two tones and reference LO). The sum frequencies are in the GHz range, which exceeds the atomic-receiver single-channel (F_{LO}=constant) bandwidth of approximately MHz by several orders of magnitude. As a result, sum frequencies are inherently filtered out by the atomic receiver.

FIG. 28A shows an exemplary power spectrum on the SA from the atomic receiver readout for the presented test conditions, with E_{F1}=E_{F2}=0.3 V/m, showing harmonic and non-linear modulation products at an intermediate frequency (IF). Here, the atomic vapor mixes down the applied F1 and F2 tones to an IF. While the electric fields of the two tones at the location of the receiver atoms are set to be the same, the first-order tones in the IF received by the SA at f1=F1−F_{LO}=150 kHz and f2=F2−F_{LO}=1.15 MHz differ in signal strength, with f2˜15 dB lower than f1, attributed to the finite Rydberg EIT linewidth and reduced atomic response at 1 MHz from resonance. Harmonic and inter-modulation products appear up to fourth-order. FIG. 28B shows the dependence of the peak signal strengths of the harmonic and intermodulation products on applied RF power for the two tones into the first combiner, with E_{F}_{_{LO}} held constant. FIG. 28B summarizes some of the aspects of the present disclosure.

For the fundamental response at f1 and f2, a near-linear behavior is observed with slopes of 0.86±0.03 and a P1dB compression point at −10 dBm. The P1dB compression points correspond to RF electric fields of the two tones equal to 0.3 V/m. The observed slopes are slightly below a slope of 1 that would be expected for fundamental tones in classical receivers.

A more complex behavior is observed above the P1dB compression point, where signal field strengths approach that of the local oscillator field. Third-order intermodulation products exhibit a slope of 2.5±0.6, which is similarly slightly suppressed relative to the slope of 3 that would be expected for classical RF systems. These differences in the atomic heterodyne receiver are attributed to the non-linear responses and multi-wave mixing effects present in the quantum Rydberg EIT system, which are anticipated to exhibit a slight divergence from classical RF electronics.

The power ratio between the fundamental and third-order distortion product (or IMD ratio) quantifies intermodulation distortion in the system. From FIG. 28B a third-order intercept (TOI) IP3 point can be obtained, where the first fundamental (f1) and third-order distortion product theoretically become equal at a 10 dBm applied power level, or approximately 20 dB above the measured P1dB compression point of f1. From this measurement a spur-free dynamic range (SFDR) for the atomic receiver can be determined given by ⅔(IP3-N₀), where N₀ is the noise floor of the non-linear or harmonic component. From FIGS. 28A and 28B, the measured modulation signal of OIP3=−25 dB and noise floor N₀=−95 dB at a 10 Hz residual bandwidth (RBW) on the SA reading can be used, to obtain a spurious-free dynamic range (SFDR)=46.7 dB at 10 Hz RBW. Noting that at a 1 Hz RBW SA measurement the noise floor would lower, the atomic quantum receiver can exhibit even higher SFDR.

To further investigate the non-linear behavior with interference signal frequencies even closer to resonance with the atomic transition and the LO frequency, the same two-tone measurement can be performed for two signal tones at F1=9.940150 GHz and F2=9.940250 GHz, equivalent to a frequency difference ΔF=F2−F1=10 KHz and a relative frequency separation of ΔF/F_{LO}=10⁻⁶ (F_{LO}=9.940 GHz). FIG. 29 shows this two-tone measurement with the RF signal strength (X-axis) converted to absolute RF intensity units (I=I₀×10^{dBI/10}, I₀=1 Watt/m², and I=½ε₀cE²) at the atomic receiver and extrapolated P1dB and IP3 points indicated. Here, an IP3 point ˜20 dB above the measured P1dB compression point of f1 can be similarly obtained.

To benchmark the IMD performance of the atomic quantum receiver to that of a typical classical receiver, a figure of merit can be defined for distortion to be the difference between the third-order intercept and P1dB compression point as FoM=IP3−P1dB. This metric serves to quantify the amount of additional signal strength one can apply to the input of the receiver (classical or quantum) until a third-order non-linear response becomes significant relative to the receiver's compression point. From both FIG. 28B and FIG. 29, an FoM can be measured for the atomic receiver of approximately 20 dB (notably independent of the two ΔF≤1 MHz values tested at F_{LO}=9.940 GHz). This compares favorably to many classical low-noise amplifiers (LNA) at 10 GHz, which typically exhibit a distortion FoM of 12 dB or less (see for example commercial devices from Mini-Circuits part No. ZX60-06183LN+ or Pasternack part No. PE15A1032). An illustrative 2f1-f2 curve for an LNA with a FoM=12 dB is overlaid in FIG. 29.

There are two important distinctions to keep in mind in the above comparison. First, the atomic receiver measures over-the-air free-space RF signal waves while LNAs measure electronic RF signals. Second, not unrelated to the first, the FoM comparison uses a relative metric and does not provide an absolute RF signal metric measurable as an FoM for distortion by both receiver types. Obtaining an absolute signal RF field metric that can be compared to both receiver types would require specific assumptions about the antenna aperture or similar transducer used to convert a free-space RF signal field to the RF electric signal input into the LNA. Since the antenna transducer details vary substantially for different antenna types and applications of interest, it is not incorporated in the comparison here. Generally, and independent of front-end antenna, the atomic quantum receivers can exhibit a greater tolerance to nearby interference signals compared to classical LNAs within their respective dynamic ranges.

### Sensitivity and Dynamic Range

Atomic quantum receivers based on Rydberg atoms exhibit minimum field sensitivities that can achieve levels below 1 μV/m. FIG. 30 shows the detected signal strength of a 9.936 GHz RF signal measured by the atomic receiver as a function of signal electric field to the receiver's minimum detectable signal level, limited by technical noise sources.

Taking the P1dB compression point from the measurement in FIG. 29 at approximately −60 dBI or electric field level E_{P1dB}=27 mV/m, and the minimum detectable electric field sensitivity Eₘᵢₙ=1.4 μV/m from FIG. 30, a linear dynamic range can be obtained for the atomic quantum receiver of 43 dB in RF signal electric field, or equivalently 86 dB in RF signal power. Noting that the minimum detectable signal and dynamic range in the presented measurements are both limited by technical noise sources, further increases to both signal sensitivity and linear dynamic range of atomic receivers are expected.

Secure Communication with Atom Radios

The non-linear behaviors of atomic receivers described in this disclosure are notably unlike those of classical LNAs and electronic systems in that they incorporate an atom-field interaction that is ultimately tied to the invariable atomic structure and fundamental physical constants. Moreover, the types of EIT schemes, the intensities of the optical EIT-readout beams, and the atomic vapor-cell conditions play a role. As such, unlike their classical counterparts, the non-linear behaviors of atomic receivers are reproducible under user-determined conditions and can provide unique, controllable RF signatures on the receive-side for predetermined signal sources. This can be exploited to realize transmit-receive communications modalities for secure communications, RF fingerprinting, and other applications. As a basic example implementation, a physical encryption scheme may be employed using an atomic receiver in which the non-linear response of a two-tone local oscillator (e.g. output shown in FIG. 28A) can be switched between discrete spectra of higher-order products (e.g. by switching LO amplitudes and frequencies). The switching between spectra can serve as a coding algorithm to, for example, provide a physical frequency hop table selector in the receiver for an incident RF waveform with frequency-hopping spread spectrum (FHSS) modulation.

### HF-, VHF-, and UHF-Band Atom Radio Receiver

FIGS. 31A and 31B show detection and measurement of a 2 GHz (UHF-band) and a 100 MHZ (VHF-band) carrier wave with the atomic sensor. The 2 GHZ RF carrier is detected using the RF-resonant 70D_{5/2} to 71P_{3/2} transition in the ARX cesium vapor cell. The electric field E of the 2 GHz electromagnetic wave detected by the sensor atoms is determined using measured Autler-Townes splittings and the relation E=h×v/d, where v is the optical frequency splitting in Hz, d is the dipole moment of the atomic Rydberg transition, and h is Planck's constant. An atomic calibration for the detected 2 GHz carrier-wave electric field E_{F}(V/m) as a function of injection RF power (dBm) is shown in the inset of FIG. 31A. A 100 MHz signal is transmitted and detected with the ARX sensor using an off-resonant 50D_{5/2} Rydberg state. In this detection mode, the strong RF signal manifests as sidebands of the target 50D_{5/2} Rydberg state, shown in FIG. 31B. Here, the 100 MHz RF signal modulates the Rydberg atomic state generating symmetric sidebands at ±2× FRF, where FRE is the RF carrier frequency; a method developed for strong RF signal detection using off-resonant atomic states on table-top experiments.

The harmonic and inter-modulation distortion behavior of atom radio receivers have been described. Two-tone testing is experimentally performed in the SHF band for tones near-resonant to an Autler-Townes transition. P1dB and IP3 points are obtained, and dynamic range and spur-free dynamic range are characterized. The atom radio receiver can exhibit suppressed harmonic and intermodulation distortion under certain operating conditions, deviating from the expected behavior of classical antenna receivers. The absolute nature of non-linear behaviors of atomic receivers is described along with their implementation for secure communications, encryption, and other communications schemes. Finally, signal reception in long-wavelength bands including VHF and UHF bands has been demonstrated with the atom radio receiver (ARX) and front-end.

Sensitivity Limits of Electric Field Sensing with Rydberg Atoms in the High-Frequency (HF) Regime and Below

Sensors that operate in the high-frequency (HF) band and below play strategic roles in over-the-horizon communications, remote sensing, and radar applications on platforms critical to the current and future U.S. Department of Defense (DoD) signal intelligence (SIGINT), surveillance, and reconnaissance (ISR) capabilities, as well as in non-defense commercial applications. Rydberg atom sensing methods and systems for RF fields in the high-frequency (HF) band to ELF band and below (as well as VHF, UHF, and above) have not reached fundamental performance limits. Atomic RF sensing using Rydberg atom vapors has been the subject of growing interest in national security and defense around the world, motivated early-on by a need at U.S. National Institute of Standards and Technologies (NIST) and other National Metrology Institutes to replace existing antenna standards with absolute (atomic) standards for RF electric fields. In this disclosure Rydberg electromagnetic field sensing has matured into a novel quantum technology platform with the realization of the first portable Rydberg-based RF field sensor instrument for self-calibrated SI-traceable broadband RF measurement and imaging of continuous, pulsed, or modulated fields, atomic RF antenna front-end receivers, and many more developments. Atomic electric field sensors exploit well-known properties of Rydberg atoms in innovative ways, driving disruptive advances in RF sensing and reception. Rydberg atoms are atoms in highly-excited electronic states at high principal quantum number n that offer a unique set of advantages including small sizes, high sensitivity, and wide-band response to radio-frequency (RF) electric fields across swaths of the electromagnetic spectrum from DC and quasi-static fields to VHF-band and above into the millimeter-wave bands and THz. Rydberg atomic RF sensors afford novel performance capabilities including self-calibrated and drift-free sensing, EMI/EMP tolerance, and operational reliability in congested electromagnetic environments. As a result, atomic sensors provide new capabilities in RF impacting industries from aerospace and defense to telecommunications and medical with applications in electromagnetic testing, metrology, remote sensing, electromagnetic warfare, security, and surveillance.

### Fundamental Sensitivity and Bandwidth Limits of Rydberg Atom Electromagnetic Sensors—Sensor Modalities

Rydberg sensors operate based on Rydberg electromagnetically-induced transparency (EIT) in atomic vapors employing multi-photon Rydberg EIT spectroscopy approaches to probe field-sensitive Rydberg atom energy levels. External electric fields are sensed or measured based on field-induced changes to the Rydberg line intensity or frequency-space offset, with values and uncertainties given by atomic physics theory. Hybrid Rydberg sensor modalities that combine Rydberg EIT and traditional RF resonators and waveguides to condition incident RF signal fields for atomic detection are also discussed.

### Rydberg Atom Sensitivity

Rydberg atoms have strong transitions for RF field sensing based on the Autler Townes (AT) effect; see FIG. 32A. The high-Q AT response to the RF field is maximally strong among the sensing modes discussed in this response, linear and narrow-band (˜EIT linewidth). Combined with RF heterodyne techniques using RF reference local oscillator (LO) fields, RF field sensitivity reaching the 1 μV/m level and pushing lower is described in this disclosure for RF resonant AT cases, with linear dynamic ranges up to about 80 dB. These figures are continually improving towards fundamental limits. In AT mode, RF resonant transitions larger than about 200 MHz are accessed, where the sensor is tuned into exact resonance using a suitable optically-coupled Rydberg state and additional external fields to tune selected AT transitions into exact resonance with the RF signal of interest.

In-between the high-Q AT resonances, the response is characterized by a quadratic, broadband AC Stark effect (see FIG. 32B). AC mode is generally targeted for frequencies below 200 MHz, where no convenient AT resonances at low-enough quantum number n have been tested so far. Tuning and switching in AC mode is similar as in AT mode, using auxiliary fields, but differs due to the quadratic response, which in principle allows high LO gain at high LO fields. In addition, the AC Stark effect is broadband, with regions in parameter space affording polarizability enhancements (see FIG. 32B).

Considering an RF signal field E_{S} and an RF reference local oscillator field E_{LO} in an atomic vapor, for RF near-resonant to a Rydberg-Rydberg transition (Autler-Townes splitting regime for E_{S}˜1 μV/m field levels and above) the derivative of the detected absorption coefficient, α_{abs}, over the signal RF electric field, Δα_{abs}/ΔE_{S}, has a maximum at Δα_{abs}/ΔE_{S}≈α₀dlhΓ_{ETT}, where α₀ is the depth of the EIT line in cm⁻¹, Γ_{EIT} the EIT linewidth in units Hz, d the atomic dipole moment in units Coulomb-meters, and h Planck's constant in units Joule-seconds. As shown in FIG. 32A, peak sensitivity occurs at zero coupler detuning, Δ_{c}=0 from resonance, for a local oscillator field amplitude where the AT line pair just begins to split (e.g. Ω_{RF}˜Γ_{EIT}). The local oscillator field at the best operating point is fairly small; it approximately equals E_{LO}=hΓ_{EIT}/d.

For the AC mode, an analytical analysis shows that Δα_{abs}/ΔE_{S}=0.714α₀αE_{LO}Γ_{EIT}, where α is the AC polarizability (see FIG. 32C). The AC responsivity to the RF signal field E_{S} increases linearly with E_{LO} (see FIG. 32B), with a fundamental limit set by the atoms (the field amplitude beyond which Floquet theory must be used), and a practical limit set by inhomogeneous line broadening of Γ_{EIT} in the atomic vapor cell. In the case of a fixed Γ_{EIT}, AT and AC sensitivities ideally break even at a local oscillator field E_{LO}=1.40d/(hα), with d the dipole moment in AT cases and a the polarizability in AC cases.

### Fundamental Rydberg Atom Sensitivity Estimates

The present disclosure describes an AT case of Cs 90D_{5/2} to 91P_{3/2} at m=½, which has a frequency of 912 MHz and d=5577eα₀ (angular matrix element included), and compares it with an AC case of Cs 90D_{5/2} at m=½ at 500 MHz, where MHz/(V/m)². This disclosure assumes a fixed Γ_{EIT}=5 MHz (common performance in two-photon Rydberg EIT spectroscopy). For the AT case, Δα/ΔE_{S}/α₀=14/(V/m) can be calculated, with an optimal E_{LO}=0.07 V/m. Break-even sensitivity in AC mode occurs at E_{LO}=6.7 V/m, where the AC shift is 166 MHz, which is less than 2% of the Kepler frequency (meaning the off-resonant AC model is still approximately valid). However, inhomogeneous line broadening at the comparably higher E_{LO}=6.7 V/m field may make AC sensitivity work less well than AT sensitivity. This, however, is alleviated at longer wavelength in HF-band and below, where RF wavelengths typically substantially exceed atomic sensing volumes by orders of magnitude. With a δα/α₀ resolution in the range from 10⁻⁴ to 10⁻⁵, RF signal-field sensitivities can range between δE_{S}=7 μV/m and 0.7 μV/m, with the lower value corresponding to an intensity of −152 dBI (dBI=10 log₁₀[I/(1 W/m²)] with intensity I). The present disclosure experimentally validated these resolutions and corresponding minimum detectable field levels δE at measurement times T of 1 second, for sensitivities of ε=δE\sqrt{T} in the range of ≈(1−50 μV/m)×\sqrt{Hz} at various RF frequencies in HF-band and above using both AT and AC readout modes with two-photon Rydberg EIT in atomic cesium or rubidium vapors. FIG. 33 shows a HF/VHF-band electric-field sensitivity measurement using a cm-sized Rydberg vapor aperture of the present disclosure relative to the classical sensitivity limit of a centimeter-sized classical antenna aperture in the HF-, VHF-, and UHF-bands.

Further improvements to sensitivity in the HF-band can be achieved by utilizing high-n resonant Rydberg AT transitions in the 3 MHz to 30 MHz range as well as AC readouts. In the present disclosure, orders of magnitude improvements in sensitivity from current state of the art are possible and described. Limitations to improving δE in HF-band at higher-n include a general increase of Rydberg-EIT linewidths with increasing n, large atom-atom interactions, as well as reduced intermediate-to-Rydberg state dipole matrix elements requiring larger coupler-laser powers. These make accessing higher-n Rydberg states with larger electric dipole moments (AT) and polarizabilities (AC) at HF-band frequencies and below a challenge. A variety of off-resonant AC methods with conditioning external fields can be employed to increase sensitivity compared to current state of the art; several AC methods are described in the present disclosure. Alternative Rydberg EIT spectroscopy and excitation pathways using different three- and four-photon Rydberg EIT configurations such that all-infrared photons and others can be employed to reach narrower Rydberg EIT linewidths and to excite Rydberg states with higher/(orbital angular momentum quantum number), which have energy gaps that are lower in frequency than those between lower-l states of the same n. This disclosure describes novel approaches to long-wavelength HF-band sensing using high-n, l Rydberg states. Hybrid sensor modalities using wavelength-scale engineered structures such as split ring resonators can also provide enhancement to the local field amplitude by a factor of 100 and possibility 1000 and higher, while selecting polarization and a narrow frequency range by design. This disclosure describes hybrid Rydberg sensors for HF-band and below.

A careful noise analysis is critical to push the sensitivity in δα/α₀, which directly maps onto a δE, to its limits. Using a suitable IF frequency (IF=signal minus LO frequency), technical noise can be fairly efficiently minimized, leaving quantum-optical shot noise of the detected probe light as fundamental limit. Shot-noise may become enhanced due to possible instability caused by slow Rydberg polariton propagation in the EIT medium. Thermal noise, k_{B}T RBW, where RBW is the resolution bandwidth of the signal analyzer, typically is not important at HF. In view of these facts, using large beam diameters as well as moderate probe and coupler-beam Rabi frequencies, Ω_{P} and Ω_{C}, clearly is a first-order measure to improve the RF sensitivity limit, δE. Quantitatively, an optimum is expected for Ω_{P}≈Ω_{C}, and for (Ω_{P}²+Ω_{C}²)/Γ (Γ is the intermediate-state decay rate) on the order of the residual EIT linewidth in the vapor cell, which is governed largely by residual Doppler mismatch. This points at beam-diameter increase and multi-photon EIT schemes to reduce Doppler effects as promising candidates to reduce relative effect of shot noise.

### Methods and Paths to Fundamental Sensitivity Improvements

Off-resonant AC studies for HF-band and below: There are many ways to measure HF fields off-resonantly using Rydberg states, with different trade-offs between sensitivity, frequency filtering, and power requirements. In this disclosure several experimental methods are examined to receive HF carriers as far off-resonance signals, typically using additional controlled external RF waves.

### Off-Resonant AT and AC

Off-resonant AT splitting or AC Stark shifts are possible using nearby existing resonances, or farther away with strong LO fields. Power- and frequency-tuning methods exist for shifting resonances to meet an arbitrary field, but these still work best near existing resonances. Intensity measurements can be made using AC Stark shift measurements, with polarization enhancements and sensitivities gained with strong external fields biasing the quadratic Stark shift (see, for example, FIG. 32B and discussion).

### Strong-Field AC Modulation

Another approach for detecting arbitrary HF and VHF band electric fields utilizes the Townes-Merritt (TM) effect, (or the AC Stark effect, although this disclosure disambiguates from AT splitting, which shares the name), which has been observed and used in Rydberg atoms for RF field sensing. In brief, cyclic Stark modulation of the state's energy faster than its linewidth will produce quasi-energy sidebands on the observed EIT line, an effect which is also predicted in other quantum systems, and is typically analyzed in the Floquet picture. The field's energy ‘modulation’ generates sidebands, which are spaced by multiples of the modulating frequency, with varying population and phase of each sideband. In some cases, sidebands can be calculated in closed form to leading order as Bessel functions of the amplitude of the energy modulation, divided by the rate: J_{N} (αE_{HF}²/4ω_{HF}) for state polarizability −α, field E_{HF} at angular frequency ω_{HF}. Notably, a pure AC field contributes to only even-order sidebands, while a DC field breaks this symmetry, causing odd-order sidebands, enabling measurement of both components. Observation of TM sidebands for a 100 MHz modulation requires at least moderate fields (>0.1 to 1 V/cm) to observe significant population in the quasi-energy sidebands. This disclosure describes the addition of an HF-band LO field can enable beat-note detection of TM sidebands for more sensitive measurements of a signal field and at HF-band frequency and below.

Strong-Field AC Modulation with Weak Signal AT

Another method for HF detection combines resonant AT splitting of an arbitrary Rydberg state with the sideband generation method. This combination of fields transforms measurements of electric field intensity from relative population measurements in TM sidebands into frequency-space splittings, measuring MHz-range electric field intensities spectrally, using an arbitrary Rydberg state. To probe the TM sidebands generated by an HF field, the center EIT peak and the TM sidebands are each subject to AT splitting. If these splitting EIT-AT states come near degeneracy with other splitting sidebands, a quantum avoided level crossing occurs, with non-linear splitting determined by HF frequency and intensity, or the HF field and applied DC field, depending on the crossing measured. When an AT field's Rabi frequency is nearly ‘matched’ to the applied HF rate, or its second harmonic, a second avoided level crossing is observed in the energy spectrum, whose gap grows non-linearly with HF field strength. This Rabi matching method acts as an AM receiver, and notably applies an effective bandpass to the observed HF signal, where the spectral detuning location of AT split EIT peaks determines the HF range that those atoms are receptive to. This method can be used to measure one or multiple arbitrary HF fields that have sufficient strength, yielding both AC and DC components, as well as frequency measurements, from a single laser detuning sweep, although additional detail is gained from also sweeping Rabi frequency near the HF signal frequency and its second harmonic.

HF Sensitivity with High Angular Momentum Methods

Several alternate schemes are shown in FIGS. 34A-34D. Since quantum defects rapidly approach zero with l exceeding a value of 2 (F-states, G-states, and higher), the frequencies between such states drop into the HF and VHF range at manageable n-values (e.g., low enough n-values to avoid atom interactions), while the transition matrix elements are near-maximal due to a good match between the radial wave-functions. These features are visualized in FIGS. 34A and 34B. F- and G-states for RF sensing are accessible via 3-optical-photon and 4-optical-photon Rydberg-EIT schemes. FIG. 34C shows the splitting of an AT pair of Rydberg levels dressed by a strong microwave RF field vs detuning of the microwave from the center of the AT resonance. The microwave Rabi frequency is in the HF range. The HF transition dipole moment between the AT states increases with increasing microwave detuning. There is an optimal range where the microwave AT resonance is still fairly close, guaranteeing strong microwave coupling, while the off-resonant AT splitting still remains in the HF band (green areas in FIG. 34C). In this range, efficient HF detection between off-resonant AT-split “designer levels” is possible.

In another embodiment, a weak DC electric field E_{DC} can be applied to a manifold of high-angular-momentum Rydberg states, setting up the linear Stark splitting pattern seen in FIG. 34D. The Stark frequency, (3/2)neα₀E_{DC}, can be easily brought into the HF or VHF regime using suitable n and E_{DC}-values. HF/VHF transitions between linear Stark states (red arrows in FIG. 34D) are strong and vary fairly little across the Stark map. Hence, a super-resonance structure involving about n states (left half of the plot; π-type HF/VHF couplings) or n²/2 (right half of the plot; transverse HF/VHF couplings) occurs when the HF/VHF frequency matches the Stark frequency. The outer Stark states then exhibit a greatly enhanced HF/VHF shift, which can be read out via Rydberg-EIT via coupling of nearby F-lines into the manifold. In effect, an HF/VHF receiver with improved sensitivity δE results.

### Noise Contributions

To achieve fundamental sensitivity improvements, technical noise from sources contributing to the electric field detection with Rydberg atoms must be accounted for. In Rydberg sensors, this includes contributions from electronic and optical subsystems in the readout and detection from sensor atoms, coherent and incoherent electromagnetic field sources such as blackbody radiation from the sensor vapor cell and materials to which the sensor atoms are exposed, field inhomogeneities and surface interactions with the atoms, as well as interactions of the sensor atoms with other atoms and background gases. Theoretical limits to these sources include electronic shot noise and Johnson-noise limits, optical shot noise limit for weak probe light, laser-optical frequency (FM) and amplitude (AM) Schawlow-Townes limits, as well as single-atom and atomic-ensemble Rydberg EIT dynamics, interaction times, and Doppler shifts. Additional engineering challenges with HF-band carriers and below include efficient coupling of long wavelength signals into sensor packages and tailoring control fields to be homogeneous in the atomic sensing volume.

### Hybrid Rydberg Sensors

Hybrid atomic RF sensors are another class and modality of atomic electromagnetic sensor that combines Rydberg atom-based sensing with traditional solid-state RF circuitry and resonators. Hybrid sensors can provide augmented performance capabilities such as resonator-enhanced field sensitivity and polarization-selective detectors for over-the-air (OTA) RF signals, as well as waveguide-embedded atomic RF E-field measurement for SI-traceable RF power standards, and atom-mediated optical RF-power/voltage transducers and receivers. Hybrid sensors implementing strip-line wave guides to feed cabled RF signals of interest into the vicinity of a Rydberg EIT atomic vapor can be used for RF spectrum analysis from DC to 20 GHz. Hybrid sensors can be sub-categorized into types: (1) OTA RF sensor types, where the free-space RF wave of interest is directly measured by the Rydberg atoms, and (2) voltage sensor types, where a separate front-end transducer (such as an antenna) converts the free-space RF signal to a voltage signal which is in turn applied to conductors to generate an electric field detected by the Rydberg atoms. Type (1) hybrid sensors using resonant wave-guide engineered structures such as split-ring resonators can provide local RF field amplitude enhancements of up to a factor of 100, as well as factors of 1000 and above. In principle, these deliver proportionally higher RF sensitivities than the bare Rydberg atom sensor alone, but are limited by resonator-induced field inhomogeneities in the atomic sensing volume and fundamental gain-bandwidth limits imposed by electromagnetic boundary conditions. Type (2) sensors can also provide signal gains with enhancement structures similar to Type (1), but serve to condition RF voltage signals using features of Rydberg EIT spectroscopy. These are also generally limited by field inhomogeneities and electromagnetic boundary conditions of waveguide and conductive structures surrounding the atomic vapor.

Signal Processing Approaches and/or Decluttering Algorithms to Overcome Noisy Environments with Rydberg Sensors

Unlike RF antenna sensor systems at higher frequency that may be thermal noise limited, HF 3-30 MHz sensors must typically operate in the presence of substantial noise. At 10 MHz, for instance, 30 dB of RF noise over thermal can be expected. Galactic noise is 20 to 30 dB above thermal across most of the band. Atmospheric noise from lightning discharges reverberating within the Earth-ionosphere waveguide and other sources further complicate reception. Performance of HF antenna radars can be severely degraded by ionospheric propagation effects that cause various forms of clutter, such as spread-Doppler clutter and blanketing sporadic layers, imposing reductions and ambiguities in the surveillance area coverage. FIG. 33 shows atmospheric noise levels and man-made noise at a quiet location from ITU data. In urban areas, man-made RF noise may be even higher.

Rydberg atom sensors are sensitive to both RF electric fields of interest and to any external RF noise sources within the bandwidth of the detector. Rydberg sensors are also sensitive to noise generated internally to the sensor, for example from atom-atom collisions and stray fields that may be present within atomic vapor cells, which can limit sensitivity. Furthermore, the embodiments described in the present disclosure to improve fundamental sensitivities of Rydberg atom sensors in HF-band and below may yield different spectral readouts from which RF signals need to be retrieved, that may complicate the detailed atomic response to noise sources. In all cases, single-atom multi-level Lindblad master equation models of light-atom interactions in Rydberg vapors with RF fields may not be able to fully capture the effects of noise sources on the sensor. To address this, techniques and algorithms such as deep learning models can be applied on Rydberg atom sensor spectral readouts, removing the need for a master equation solution while simultaneously reducing the impact of these noise sources and permitting direct signal demodulation of complex frequency-division multiplexed signals. Similar techniques applied to unique spectral readouts of HF-band signal reception Rydberg sensor spectra as described in this disclosure can be used to investigate noise reduction and improved sensitivity performance.

To overcome environmental RF noise in the HF-band and below, methods employed in HF antenna and radar systems may be adapted to Rydberg sensors. Methods include corrections to multi-path effects, for example, such as exploiting correlations between same-carrier direct-path RF wave and multipath echoes. Adopting features of the Rydberg sensor and hybrid Rydberg sensor modalities such as potentially narrow and tunable AT/AC bandwidth, high frequency and polarization selectivity, as well as unique spectral readouts from Rydberg-atom non-linear responses in the presence of coherent RF and band-limited noise can yield novel signal processing techniques to improve sensitivity to HF-band and long-wavelength signals with Rydberg sensors in noisy environments.

### Atomic Quantum Compact, High-Frequency (HF-Band) Direction Finding (DF) Antenna Array

In one embodiment, an atomic HF-band DF antenna (whose device architecture is functional at other frequency bands) provides capabilities in over-the-horizon communications, remote sensing, and radar applications for subsystems, systems, and platforms, for example, critical to the current and future U.S. Department of Defense (DoD) signal intelligence (SIGINT), surveillance, and reconnaissance (ISR).

Due to the inherently large size of metal antennas at HF-band, HF-band signal collection platforms on air and land, such as manned aircraft, drones, and terrestrial vehicles, do not have sufficient space to install HF-band antennas or antenna arrays. Existing smaller HF DF antenna arrays result in worse performance and excessive error, making targeting difficult for combatant commands, especially at long range. These limitations of antenna technology at long-wavelength HF-bands inhibit the DoD from providing necessary force protection and mission targeting for combatant commands now and in the future. To address this capability gap, the present disclosure describs HF DF technology solutions that meet specified physical size and direction finding accuracy requirements, for example, to integrate into and test on a fixed-wing aircraft.

An atomic HF-band DF antenna front-end achieves a compact form factor, high accuracy, and performance requirements for ground, sea, air, space-based platforms, and in particular an airborne platform. The antenna front-end employs atomic RF sensing technology to provide key advantages over traditional metal antenna systems and arrays for long-wavelength signal reception and DF including: (1) Sub-wavelength compact sensing elements and dense array spacing for a lower overall system size, for example, at or below size and form factor of L36 inches×W36 inches×D16 inches (or equivalent reasonably similar size or smaller), (2) RF signal sensitivity across the 2 MHz to 30 MHZ HF-band carrier range and beyond, (3) RF phase sensitivity and angle-of-arrival resolution with root-mean-square (RMS) resolution of at least 5 degrees or better across the HF-band carrier range, (4) Operational for vertical and horizontal RF signal polarization orientations, and (5) Wide field of view from 0 to more than 30 degrees below horizon.

### Atomic RF Electric-Field Sensing Enables Fundamentally New Capabilities Unmatched By Their Classical Antenna and Electronic Counterparts

A technology overview is illustrated in FIG. 35. Atomic sensors and receivers exploit the novel properties of Rydberg atoms, which are atoms in highly excited electronic states that offer a unique set of advantages compared to traditional antennas and solid-state receivers including small sizes, high sensitivity, and wide-band response to radio-frequency (RF) electric fields across the electromagnetic spectrum from DC to THz. Rydberg atomic RF sensors provide additional performance capabilities including self-calibrated and drift-free sensing, EMI/EMP tolerance, and operational reliability in congested electromagnetic environments. Atomic sensors provide disruptive capabilities impacting industries from aerospace and defense to telecommunications and medical with applications in electromagnetic testing, metrology, remote sensing, electromagnetic warfare, security and surveillance.

A challenge for classical antenna solutions in reception and direction finding is that antenna size increases as the wavelength of interest becomes longer. At or near HF band, antenna sizes can extend from a meter to hundreds of meters in length and larger for best performance, limiting portability and performance, including increased interference. The reduction of antenna system size is driven also by the desire to reduce coupling between each antenna element in the system. For atomic receivers, sensing elements of ˜1 cm³ and smaller are possible with minimal element-to-element coupling for high array packing density. In addition, Rydberg atomic sensors exhibit high phase measurement precision at the 2 mrad level, enabling angle of arrival accuracy at the 1-degree level or better. Rydberg atomic RF sensing is a disruptive RF technology with benefits enabling next-generation long-wavelength direction finding systems with a dramatic size reduction in HF-band antenna/front-end hardware for portability and integration onto moving platforms and low radar cross section, high accuracy angle-of-arrival, wide field of view, and drift-free (atomic) signal detection for operational reliability.

### Atomic Radio: Rydberg Atom Hardware

The present disclosure advances the capabilities of atomic sensors and pushes field sensitivities beyond the current state of the art (SOTA) in both quantum and classical electric field sensing, and exploits properties of Rydberg atom reception for advanced waveform detection, quantum secure communications, and precision angle-of-arrival detection and direction finding. To deploy the unique quantum RF capabilities in real-world and harsh environments, device architectures and hardware are needed to reduce the size, weight, and power and cost of atomic quantum RF sensors, transmitters, and derivative application-specific devices, in addition to photonics and lasers, and other subsystems and components required for spectroscopy of Rydberg atoms and in Rydberg atom quantum technologies. Rydberg atom RF sensor technology was transitioned from a laboratory test bed the size of a small room (SWaP: >100 sq.ft. room, >1000 kg, and >1000 Watt) to the RFP and RFMS portable RF field probe and measurement system (e.g., size: 33×24×52 inch rack-mount unit, weight: 170 kg, power: 700 Watts).

In one embodiment, an atomic radio or Rydberg Atomic Aperture and Receiver (ARX) aperture, front-end, and receiver is shown in FIGS. 36A and 36B. The ARX is the first portable atomic quantum RF sensor and front-end that exploits Rydberg atoms for RF signal reception and detection applications at long-wavelength bands from HF-band (and below) to UHF-band and above. The ARX shown in FIG. 36A is comprised of a single, low-profile RF aperture sensor that houses an embedded atomic-vapor sensing element engineered for HF/VHF/UHF-band signal reception with extended capability into the SHF band. The ARX system can be configured for multiple purposes including angle-of-arrival measurements using atomic vapor cell sensing elements less than 1 cm³ in volume and area cross section approximately the size of a US quarter, corresponding to a size reduction of more than 100× compared to traditional HF antennas. The sensor is linked to a front-end mainframe (e.g., form factor size: L33″×W19″×D7″, weight: <50 kg, power consumption: 200 Watts) by a 10-meter cable for flexible positioning and remote operation of the sensor in application environments. The ARX form factor, size, weight, and power are designed for portability and flexibility of integration into operational testing environments and platforms. A Rydberg ARX system with a complete SDR signal processing block is illustrated in FIG. 36B at a form factor equal to the target for the solicitation. The ARX architecture itself is configured as an analog front-end that is agnostic of signal waveform type and digital signal processing back-end. With this architecture, the ARX can be interfaced with third-party software-defined radios and other hardware for digital signal processing and integration with external transmit and receive RF networks and systems.

### ARX Capabilities

The Rydberg ARX provides quantum-advantage in a broad set of RF capabilities including wide frequency response, improvements in sensitivity over traditional systems, and reduced size compared to conventional antennas for long wavelength communications. The present disclosure describes multi-band signal reception with a Rydberg atomic receiver spanning HF band to millimeter-wave band (covering a multitude of decades) and is illustrated in FIG. 37. An ARX driven atomic sensor can support simultaneous sensing of at least two arbitrary carrier signals within a spectrum range from the MF/HF-bands (1-30 MHz) to UHF (1 GHZ) and SHF (10 GHz) bands, covering spans of the electromagnetic spectrum over multiple decades. The ARX receiver achieves this utilizing the wideband response of resonant or off-resonant quantum Rydberg states and local oscillator reference fields applied to the atoms for simultaneous multi-band signal reception and demodulation. Example capabilities include simultaneous HF-band signal reception at 3 MHz and VHF-band signal reception at 300 MHZ (2 decades of electromagnetic frequency span). Similarly, simultaneous HF-band signal reception at 10 MHz and UHF-band or SHF-band signal reception at 1 GHz or 10 GHz, respectively (2 and 3 decades of electromagnetic spectrum span, respectively) is demonstrated. Fast sweeps across HF/VHF/UHF bands and sections thereof may also be performed using continuous-frequency sensitivity of atomic Rydberg states and rapid RF LO sweeps.

Atomic receiver technology performance metrics match and, in some frequency bands, exceed those of classical sensors and receivers. FIG. 37 (left) shows the classical sensitivity limit of a centimeter aperture with typical human clutter levels from 10 MHz to 1 GHz. In the HF-band and VHF-bands, the 1 cm3 ARX sensor achieves a sensitivity approaching the 10 μV/m/Hz^{0.5} level and below, exceeding the classical limit by 30 dB or more. Test cases for demonstration and evaluation may include HF-band signal reception of a 10 MHz or similar test frequency transmitted at a fixed power and stand-off distance from the sensor device under test, the ARX probe, and separately a suitable classical HF antenna receiver system. A comparison of signal levels between the two could then be performed, with the signal electric field level measured directly by the ARX probe and the signal electric field measured from the antenna voltage normalized by length to retrieve the electric field (employing the simple relationship of electric-field=voltage/antenna length, assuming a quarter-wave dipole). Similar and more rigorous comparisons may be evaluated also at other test frequencies in VHF and UHF frequency bands, and under controlled environmental conditions in an anechoic test chamber. In addition, atomic receivers exhibit enhanced frequency selectivity at the atomic aperture (prior to any electronics analog or digital signal filtering) leading to an improvement in sensitivity to target signal reception in EM-congested environments. Test cases and demonstrations can be performed on IF rejection and IMD for the ARX sensor and analog front-end compared to antennas at target frequencies in HF/VHF/UHF bands. ARX signal reception of wanted signals in a simulated or real-world EM-congested environment with application of intentional EMI signals can also be performed. ARX integration with and performance bench-marking to existing electronic HF tactical radio systems such as whip antennas on the PRC-160 digital receiver may also be evaluated.

The ARX sensor shown in FIGS. 36A and 36B has a volume of approximately 1 cm³ and weight of less than 1 kg. Compared to the size and weight of standard whip antennas in the HF-band (vertical whips such as the SB-V16/SB-V35), which typically range from 2.5 to 25 meters (30 MHz to 3 MHz, respectively) and weighing up to 9.1 kg (e.g. model SB-V35F), the ARX sensor provides up to a 1000-fold reduction in size and up to 10-fold reduction in weight. The SWAP of the front-end ARX unit is the SOTA in quantum RF sensing and provides a rack-mount form factor, fit, and function suitable for field demonstrations of quantum RF capabilities and for its practical implementation in some application domains. The ARX system is designed as an RF front-end system and, as such, is consistent with the Modular Open Systems Approach (MOSA). The signals being received by the ARX front end can be interfaced with existing digital back end signal processing and utilize existing current waveforms and protocols.

### Atom-Based Synthetic Aperture

In one embodiment of the present disclosure, a synthetic aperture is based on Rydberg atoms. Rydberg atom sensors for applications in RF imaging and synthetic apertures employ RF amplitude and phase imaging with a Rydberg atom probe, sensor array, or imager. The following are described: (1) RF amplitude and phase retrieval methods with Rydberg sensors, including on-resonant Autler-Townes, off-resonant AC Stark shift, and Floquet measurement regimes, and phase-sensitive Rydberg RF field sensing; (2) an atomic antenna probe and front-end based on Rydberg atoms, the Rydberg Field Probe (RFP), that uses electromagnetically induced transparency (EIT) with Rydberg states of an atomic cesium vapor and RF-induced shifts of Rydberg energy levels to measure RF electric fields at sub-wavelength spatial resolution at high precision; (3) atom radio/RFP wide-area high-resolution RF electric-field imaging of a 2.5 GHZ Yagi-Uda antenna near-field; and (4) direct spatial phase imaging of a 100 GHz millimeter-wave field using a Rydberg atom radio imager probe using Rydberg EIT optical fluorescence readout and RF self-homodyning.

RF Electric-Field Amplitude and Phase Determination with Atom Radio Rydberg Sensors

Rydberg states of atoms are sensitive to RF fields over an ultra-wide range of frequencies from static fields to terahertz. The effects of RF fields on atomic Rydberg states in vapors can be optically detected using Rydberg electromagnetically induced transparency (EIT) spectroscopy. In a Rydberg sensor using a two-photon Rydberg EIT readout configuration with atomic cesium (Cs), a weak probe laser is stabilized to be resonant with the Cs D2 transition (6S_{1/2} to 6P_{3/2} electric-dipole transition), transmitted through the atomic Cs vapor, and detected by a photo-detector for electrical readout of the probe laser absorption through the atomic medium. In this configuration, one detects a reduction in the laser power due to resonant scattering of the probe laser from the thermal atomic vapor. When a second coupler laser field is applied whose wavelength is set to resonantly drive an electric-dipole transition between the intermediate (6P_{3/2}) state and another state, which in the present disclosure is taken to be an nS_{1/2} Rydberg state, the atoms reside in a quantum superposition of the 6S_{1/2} and the nS_{1/2} Rydberg state (n is the principal quantum number of the Rydberg state). The quantum optical excitation amplitude into the intermediate state 6P_{3/2} state then exhibits destructive interference, resulting in a transparency of the probe laser through the atomic medium known as EIT. The probe laser transmission as a function of coupler laser frequency across a Rydberg transition reveals spectroscopic EIT lines of the field-sensitive Rydberg levels. Examples of Rydberg EIT spectra for different atom-field interaction regimes are shown in FIGS. 38A-38D.

The response of Rydberg atoms to arbitrary external RF fields can be quite complex and is dictated by the nature of atomic sub-structure, electric and magnetic properties of Rydberg states, and non-linearities exhibited by Rydberg states of atoms in certain RF electric-field amplitude and frequency regimes. This is shown in FIGS. 38A-38D, which illustrates four typical Rydberg-atom and RF field interaction regimes and exemplary Rydberg EIT spectra in response to RF fields. This includes the Autler-Townes regime, in which RF fields with a frequency resonant or near-resonant with a Rydberg-Rydberg transition generates a splitting of the Rydberg line (black curve in FIG. 38A) into two lines (purple curve in FIG. 38A). The RF electric field amplitude is given by E=hΩ/d, where Ω, d, and h are the RF Rabi frequency (proportional to frequency splitting), dipole moment of the Rydberg-Rydberg transition, and Planck's constant, respectively. For weak resonant fields, the response is in a sub-AT regime, in which the line splitting or shift is below the resolution given by the EIT linewidth (magenta curve in FIG. 38A). For far-off-resonant RF fields, the RF field induces AC Stark shifts of the Rydberg lines as shown in FIG. 38B. The RF electric field amplitude is given by E²=−4Δ_{L}/α, where Δ_{L} and α are the line shift and AC polarizability of the atomic state, respectively. As shown in FIG. 38C, to perform RF measurements over arbitrary RF amplitude and frequency ranges, RF E-field determination methods across all atom-field interaction regimes can be achieved using Floquet models of the atom-field interaction. The Floquet models are based upon a non-perturbative description of periodic atom-RF field interaction. While the Floquet models accurately describe the resonant Autler-Townes (AT) and off-resonant AC Stark atom-field interactions regimes (filled curve in FIG. 38C), their distinctive value point is that they accurately account for higher-order couplings and shifts, allowing one to push Rydberg-EIT field sensing into higher-field regimes.

RF Phase Retrieval from Rydberg Sensing Probes is Accomplished in Several Ways

Fundamentally, phase-sensitive Rydberg atom RF measurements require a reference field relative to which the phase of the RF field of interest is measured. This is typically implemented by providing either a reference field externally applied to interfere with the signal field of interest at the atom location, or by using a reference field internally applied using optical RF modulation to introduce an internal atomic-state interference for phase readout. FIG. 38D shows the readout of a phase-sensitive optical Rydberg EIT probe during a measurement of a 5 GHZ RF signal phase Φ_{RF} and amplitude \sqrt{I_{RF}}˜E as a function of reference RF optical-modulation phase ϕₒₚₜ and laser frequency detuning.

### Rydberg Probe Electric-Field Imaging of a 2.5 GHZ Yagi-Uda Antenna

For practical applications of Rydberg field measurement and sensing, the present disclosure describes the first Rydberg RF E-field probe (Rydberg Field Probe or RFP) and measurement instrument (Rydberg Field Measurement System or RFMS) employing atom-based sensing using electromagnetically induced transparency (EIT) readout of spectral signatures from RF-sensitive Rydberg states in an atomic vapor. A picture of the RFP and RFMS is shown in FIG. 39B. The RFP houses a miniature atomic vapor-cell sensing element connected via a ruggedized fiber-optic patch cable to a portable rack-mounted unit for remote probe operation and RF E-field measurement.

In an RF imaging capability demonstration, the RFP and RFMS measure and image the electric-field in the near-field of a Yagi-Uda antenna using AC shifts of the Cs 70S_{1/2} Rydberg state. In RF fields E(t)=\hat{ε}E₀ cos(ω_{RF}t) with weak to moderate electric-field amplitudes E₀, the Rydberg level shifts, Δ_{L}=−E₀²/4α₀(ω_{RF}), where α₀(ω_{RF}) is the dynamic scalar polarizability in SI units of MHz/(V/m)². The dynamic scalar polarizability is calculated from the electric-dipole matrix elements and the frequency detunings of the RF from the atomic transitions of the Rydberg atom. The electric-dipole matrix elements and frequency detunings have dependencies on fundamental constants that are SI-traceable to Planck's constant. The polarizabilities typically scale as n⁷. Sample experimental EIT spectra of the 70S_{1/2} Rydberg-EIT line without and with incident RF fields are shown in FIG. 40A, demonstrating that an applied RF field at 2.5 GHz induces a red-shift about 30 MHz. The calculated quadratic behavior of the AC shift of the 70S_{1/2} level at an RF frequency of 2.5 GHz is plotted in FIG. 40B. Field determination in the AC Stark regime benefits from a low variation of do over frequencies spanning DC to GHz.

The RF imaging setup is illustrated in FIG. 39A. A Tupavco TP513 Yagi-Uda antenna is chosen as a DUT and is connected to an RF transmission line for emission at 2.5 GHz. The transmitter and RFP are both mounted at a distance of 0.753 (5) m above a grounded plane. The RFP is translated in steps of 0.102±0.005 m both parallel and perpendicular to the axis of the transmitting antenna. For each grid point, an RF-induced AC-shifted EIT spectrum from the RFP and an RF-field-free spectrum to which the shift in the RFP spectrum is referenced are simultaneously acquired. FIG. 40A illustrates the AC-shift-based electric-field determination method. Here, the peak position in the RFP spectrum is determined relative to that of the field-free spectrum in order to obtain the RF-induced shift Δ_{L}. The apparent asymmetry in the EIT spectra, attributed in part to perturbations of the Rydberg state within the vapor cell, does not impact the RF electric-field determination because the asymmetry is static and independent of RF intensity. The effects of asymmetric line shapes in RF electric-field measurements and their contribution to measurement uncertainties can be considered.

FIG. 41 shows a composite image of the 2D electric-field distribution measured by the RFP rastered over a 1.9×0.5 m area in the near-field of the Yagi-Uda antenna. The rastering grid covers one half of a horizontally aligned near-field plane at a height equivalent with that of the antenna itself (see FIG. 39A). Since the near-field pattern on the plane is symmetric about the antenna axis, a half-plane measurement is sufficient. At each RFP position on the grid, the electric field is derived from the RF-induced shift of the 70S_{1/2} Rydberg level relative to that of the field-free spectrum. From the shift, the pre-calculated Δ_{L}-versus-E₀ Floquet curve shown in FIG. 40B is used to obtain the RF electric field amplitude E₀. This yields an SI-traceable electric-field amplitude measurement at each grid position in the near-field of the transmitting antenna and the resulting image shown in FIG. 41. Here, the RF field strength is plotted in units of in dBI, where dBI=10 log [½cε₀E₀²/(W/m²)]; Not to be confused with dBi, which represents the antenna gain relative to an isotropic emitter.

In FIG. 41 it is seen that even in the near-field most of the field is concentrated along the boresight of the antenna along z, with an apparent lobe along directions ≤15° from the z-axis. There is also a rapid drop-off in field strength as a function of distance from the antenna, as expected for the near field. The employed AC Stark shift measurement mode of the RFP affords a dynamic range of ˜40 dB for the case shown. The mean values and standard deviations of the field measurements are calculated, yielding an upper-bound to the relative measurement uncertainty of 5.5%, accounting for statistical uncertainty of the EIT peak-finding algorithm, laser-frequency non-linearity, and RFP positioning. The net uncertainty is dominated by the RFP positioning uncertainty, while the measurement uncertainty from the atomic field determination alone is below 1%.

### Atomic Quantum Synthetic Aperture Radar: Atomic Millimeter-Wave Spatial Phase Imaging

Rydberg atom sensitivities to an ultra-wide range of RF frequencies enable RF imaging with Rydberg probes into millimeter-wave bands. FIG. 42 shows a two-dimensional image of a 100 GHz RF signal phase obtained with a Rydberg imager based on Rydberg EIT fluorescence readout from an atomic vapor. Here, a 100 GHz field signal field is propagated (blue arrow) into a Rydberg atomic cell at an angle θ relative to the optical beam propagation direction (vertical axis). The RF field is retro-reflected to generate a standing wave electric field across the atomic sensor optical beam. Rydberg EIT optical fluorescence from the beam is collected by an optical imaging subsystem, yielding an intensity level at each pixel proportional to the local electric field strength of the superposition of incident and reflected 100 GHz waves. The image reveals the local standing wave phase across the image. The leading standing-wave period within the image is given by δr=λ/2=1.5 mm for the 100 GHz field (vacuum wavelength 3 mm), demonstrating the phase sensitivity of the measurement system. Weak, higher-order fringes in the phase image are attributed to RF perturbations by the vapor cell detector material and RF scatter from objects near the atomic imager.

The present disclosure describes different regimes of atom-field responses and RF amplitude and phase determination methods for Rydberg EIT probes, atom radio, and atom-based quantum synthetic aperture radar. Wide-area high-resolution electric field imaging in the near-field of a 2.5 GHZ Yagi-Uda antenna DUT is demonstrated using a portable Rydberg atom probe and integrated front-end. A composite image of the two-dimensional antenna pattern is realized at a spatial resolution of λ/2 reaching field measurement uncertainties of 5.5%. The present disclosure describes atomic RF phase-sensing and imaging at millimeter-wave bands, for example, phase imaging of a 100 GHZ field using a Rydberg fluorescence imager.

### Atom Radio Transmitter, Transceiver, THz Source, and Maser

Advances in communications technology, THz imaging, security and other applications require progress in compact high performance THz sources and detectors. In communications, cellular devices and WLAN occupy bands up to about 2 GHz and 5.8 GHz, respectively. A general squeeze in radio bandwidth is a growing problem, with mobile-device data traffic estimated to be increasing by over 50% every year, as just one example. 5G networks will address this problem, in part, by using directional transmitters and receivers, enabled by phased antenna arrays in base stations and devices. For a generic relief in available bandwidth, it is desired to expand into previously untapped ranges of the electromagnetic spectrum. The way to go is up into the 10-100 GHz microwave, the sub-THz 100 to 300 GHz, and the THz ranges, because the density of channels that can be accommodated per carrier-frequency percentage increases linearly with frequency (assuming a fixed demand in baseband bandwidth). In imaging, remote-sensing, homeland security and other applications, there is a desire to progress from human-sized THz imaging and screening technology to whole-room, wide field-of-view imaging. These applications require efficient THz sources for THz illumination and focal-plane, pixelated, room-temperature and yet highly sensitive THz receivers.

The present under-utilization of the sub-THz and THz ranges of the electromagnetic spectrum in these fields largely arises from a lack in technology in THz sources and detectors/receivers. At frequencies greater than 30 GHZ, current technology includes frequency multiplication using RF circuits, solid-state devices, vacuum electronics devices, difference-frequency generation using lasers and nonlinear optics, and molecular FIR/THz lasers (e.g., https://www.edinst.com/products/firl-100-pumped-fir-system/). Despite the availability of these sources, THz technology has not yet found its way into mainstream communications. This is, in part, due to intrinsic power inefficiencies, cost, weight, and size limitations of existing THz sources, detectors and receivers. For instance, frequency multiplication of high-quality microwave signals is very inefficient at higher frequencies and carries a prohibitive price tag. Quantum cascade lasers (QCL) typically operate at higher frequencies (10 to 100 THz); QCLs approaching 1 THz (from above) typically require cryogenic operation. Conversion of laser light into THz by difference-frequency generation is intrinsically inefficient. On the receiver/detector side, standard bolometric sensors lack bandwidth in the baseband, while highly sensitive transition edge sensors require cryogenics, and pixelated devices with thousands of pixels are mostly still in their development stages.

The present disclosure describes atom-based RF/THz sources and detectors, transmitter, receivers, and transceivers. The Rydberg-atom THz laser can generate a coherent, narrow band, tunable source of RF radiation including the range between 0.1 and a few THz with THz emissions from Rydberg-atom vapors at substantial powers (e.g. 0.1 to 1 mW and higher). On the receiver side, an atom-based field sensor such as an atom radio receiver are used to detect and demodulate THz signals emitted from frequency-matched atom-based sources. Both Rydberg-maser transmitters and receivers are scalable into pixelated arrays. The matched Rydberg-atom-based transmitter and receiver units are suitable for sensing and imaging applications and, when combined with atom-based modulation and demodulation methods, for applications in communications.

### Operating Principles

A dense sample of Rydberg atoms presents, in certain limits, an ideal maser gain medium. The present disclosure describes a high-frequency (THz) maser (microwave amplification by stimulated emission of radiation) with a bound-bound masing transition between a pair of Rydberg states. FIG. 43 shows the proposed concept of a Rydberg THz source or transmitter (Tx). The Rydberg gain medium is contained in a thermal vapor cell of cesium or rubidium, and is pumped by lasers from the ground-into a Rydberg state by a suitable one-or multi-photon excitation process. To achieve a reasonable conversion efficiency of laser energy into THz radiation, it is required that a large fraction of the laser light becomes absorbed. In the most generic case of two-photon excitation, the lower transition can be on the D2 line, for which Beer's absorption coefficient can be easily temperature-tuned into the range of several cm⁻¹. This is large enough to ensure efficient absorption. However, the upper (Rydberg) transition will always have absorption coefficients ranging below 1% cm⁻¹. This problem can be addressed by injecting the upper-transition pump light using an optical cavity. The cavity serves two purposes, first to increase the effective absorption length in the medium, and second to increase the upper-transition Rabi frequency while maintaining a small device size. The optical pumping beams propagate transversely to an elongated cell that contains or is embedded within a tunable THz cavity with a moderate Q-value. The THz masing occurs into a longitudinal Gaussian mode of the resonator. Maser radiation is extracted into free space through a coupling hole that is impedance-matched by choosing a suitable hole diameter and length (coupling losses=other cavity losses). The coupling-hole geometry and detailed shape also determines the diffraction-limited output mode of the THz maser. In some embodiments, as shown in FIG. 43, the high-frequency (TH) maser can have a longitudinal length of about 10 cm or less along an axis of the THz beam.

The linewidth of Rydberg masers has been the subject of considerable study in the 1990's. Anticipating a need for narrow-line, low-noise sources, it is desired to use moderately high-Q resonators and large mode volumes. The present disclosure includes studies into both the good-cavity and bad-cavity limits, in which the linewidth is dominated by the cavity or atomic line broadening, respectively.

A Rydberg THz receiver (Rx) can be implemented, in some and possibly most respects, by reversing FIG. 43. The THz field is then detected by Rydberg electromagnetically-induced transparency (Ryderg-EIT) on the lower (852-nm) transition. In Rx mode, the 852-nm beam functions as EIT probe, while the upper transition as EIT coupler. The symmetry in the atomic physics methods and the RF engineering between the proposed Tx and Rx Rydberg-maser and -receiver units ensures considerable effectiveness, both in terms of the fundamental conception of matched Tx and Rx devices.

### Rydberg-Maser Threshold

The present disclosure describes THz and optical emissions from Rydberg samples cascading through lower-lying levels. The achievement of Rydberg superfluorescence and masing, which leads to coherence of the emitted field, presents a somewhat unexpected challenge. To explain this point, the present disclosure describes superfluorescence in an elongated pump medium with a length that is much larger than the wavelength and with a cross-sectional area larger than one square-wavelength. In this case, superfluorescence occurs if the Rydberg-density exceeds the inverse cubic wavelength λ⁻³ (item a) times the ratio g_{dipole}/gₘₐₛₑᵣ (item b) between the dipole relaxation rate, g_{dipole}, and the spontaneous decay rate of the masing transition, gₘₐₛₑᵣ. Item a appears deceivingly favorable, as a 300-GHz field corresponds to one Rydberg atom per mm³ (i.e., almost nothing). Item b may make Rydberg superfluorescene and masing challenging. As an example, the 25D level of rubidium in a 300 K radiation field has an overall decay rate of gₐₗₗ=90,000 per second at 300 K, which includes all spontaneous decays, all upward and downward black-body bound-bound transitions, and black-body ionization. The most favorable masing transition, 25D to 25P, has a spontaneous decay rate gₘₐₛₑᵣ of 59 per second (this is calculated at 0 K). The resonant field is at 150 GHz and has about 42 thermal photons at 300 K. In one embodiment, one may set g_{dipole}˜gₐₗₗ. This would suggest a ratio (item b) of about g_{dipole}/gₘₐₛₑᵣ˜90,000/60˜10³, corresponding to a critical Rydberg-atom density of 10⁵ per cm³ (at 150 GHz). Note, that the Rydberg transition is also broadened by interaction-time broadening, Rydberg interactions, and stray electric and magnetic fields. These additional broadening mechanisms typically cause a dipole relaxation rate on the order of g_{dipole}˜10⁶ to 10⁷ s⁻¹, leading to a ratio (item b) of g_{dipole}/gₘₐₛₑᵣ˜10⁵. While the corresponding critical Rydberg-atom density of 10⁷ to 10⁸ per cm³ (at 150 GHz) is achievable (see below), it is not a trivial task. The fact that the medium is embedded in a THz cavity will lower the critical (masing) density of Rydberg atoms by a small factor.

The present disclosure also describes cold-atom Rydberg masers. It is useful to comment on cold-atom masers with Rydberg states because this topic has received a lot of attention. Cold-atom Rydberg masers are somewhat different from thermal (e.g., 300 K) vapor-cell-pumped Rydberg masers. In cold-atom Rydberg masers inhomogeneous broadening is largely eliminated by providing a very low density, collision-less, and cryogenic environment, as well as a very-high-Q superconducting microwave cavity that is resonant with the masing transition. Because of this unique constellation, the cold-atom Rydberg maser operates with a small number of atoms within the cavity (one atom is enough, in some cases). These systems ensure maximal cooperativity and minimal maser field energies (that is, typically, measured in numbers of microwave photons). These systems have been used for high-profile efforts in cavity-QED, quantum-state control and quantum engineering.

### Rydberg-Atom Interactions

Rydberg atoms interact via long-range multipolar interactions, which lead to attractive and repulsive molecular potentials. From the viewpoint of building a maser, these lead to unwanted level shifts of the optical Rydberg-atom excitation and of the masing transition. The present disclosure describes the equilibrium distance of long-range Rydberg macro-molecules scales as the effective quantum number to the 2.5-th power. This scaling appears to hold across several species and quantum states, and gives expected sizes of Rb 25D Rydberg-pair macro-molecules of about 0.3 microns. The present disclosure describes calculations for Rb 25D_{5/2}, a Rydberg state that has a strong maser transition at 150 GHz. FIGS. 44A and 44B show interaction potentials of pair states (Rb 25D_{5/2})2, for one case of total angular momentum M along the internuclear axis. Bound molecular states may exist around an internuclear separation of R=0.3 micrometer, and that van-der-Waals shifts drop below 2 MHz at R=1.5 micrometer, corresponding to a Rydberg-atom density in the low-10¹¹ cm⁻³ range. Noting that the order of magnitude of the interactions does not depend much on M, the calculation indicates that van-der-Waals shifts should not severely limit maser operation with Rb 25D. Similar results can be expected for Cs systems.

### Rydberg-Atom Excitation

For given Rabi frequencies on the lower and upper transitions, the Lindblad equation can be solved to find the Rydberg-atom population averaged over the Maxwell velocity distribution in the cell. FIGS. 45A and 45B show an example for Rb at a cell temperature of 350 K. The absorption on the lower transition (780 nm) is about 1 cm⁻¹, which is on the order of the path length of the respective beam through the vapor cell. The upper transition has an absorption coefficient of only 0.3 m⁻¹. To ensure reasonable optical-to-THz energy conversion, an optical cavity for the upper-transition light can be specified with a finesse on the order of 30. The cavity increases the effective path length of the beam in the medium to near one meter, leading to an improved deposition of upper-transition laser energy into the Rydberg pump medium. Finally, approximately 1% of atoms of all velocity classes in the cell can be promoted into the Rydberg state. For an atom density of about 5×10¹¹ cm⁻³, the atom density of Rb-85 at 350 K, a Rydberg-atom density is estimated on the order of 5×10⁹ cm⁻³. This value is more than one order of magnitude higher than the estimated critical density for superfluorescence on the Rb 25D to 26P transition, and more than one order of magnitude lower than the density at which van-der-Waals shifts become important.

Reduction of the EIT linewidth translates into an overall reduced interaction-induced line broadening (see Rydberg-Atom Interactions section above), a reduced laser power to pump the Rydberg-atom gain medium, a reduced density threshold to achieve superfluorecence and masing, and a better-defined maser linewidth in the bad-cavity limit. All of these features are desired, and therefore narrow-line Rydberg-EIT and narrow-line Rydberg-atom pumping using multi-photon methods that reduce the residual Doppler broadening in atomic vapors are useful attributes of the atom radio source/transmitter.

### THz Source

Miniaturized atom Rb and Cs vapor cells with inner diameters typically ranging 1 mm and several cm, with lengths of typically 1 mm and higher are used. In one embodiment, the THz source vapor cells may be glass (e.g., Pyrex) cylinders with anodically bonded float zone (FZ) Si discs in place of optical windows. While Pyrex glass absorbs THz radiation, FZ silicon has low absorption and a high dielectric constant in the THz range, allowing transmission of THz and a low-finesse THz cavity to be formed within the cell. The cell comprises bonded integrated structures such as cavities and optics, including FZ-glass vapor cells.

In one embodiment, the THz cavity has a fixed-position exit disk of FZ silicon with a shape-optimized aperture for directed emission of THz from the cavity. The rear THz cavity mirror is a solid disk without an embedded THz exit structure. The outside surfaces of both FZ silicon reflectors will be coated with metallic surfaces to ensure minimal radiation losses and a high Q-value of the THz cavity. For frequency tuning of the THz cavity, the rear THz reflector may be a position-tunable component that is embedded within the cell and that can be translated back and forth with an external actuation device. Different shapes and material choices of the exit port will yield good and suitable output coupling, a diffraction-limited beam, impedance matching (cavity absorption losses=coupling losses), and mechanical stability against the exterior atmospheric pressure. Different methods for frequency tunability of the THz cavity are possible.

In some embodiments, as shown in FIGS. 43 and 46, the atom sample is transversely pumped. For example, as shown in FIG. 46, the pumping occurs with counter-aligned lower- and upper-transition laser beams. It is seen in FIG. 45B, that the Rydberg population, ρ₃₃, reaches values around 2% of all atoms (meaning that resonant atoms that have the correct velocity in pump beam direction have ρ₃₃ on the order of 50%). At an atom density of 5×10¹¹ cm⁻³ (Rb-85 at 350 K), one may therefore expect a Rydberg-atom density of about 10¹⁰ cm⁻³, low enough to avoid interactions and high enough to be well above the above estimated masing threshold. Subsystem hardware may include the narrow-linewidth lasers, optics, electronics, and atomic frequency referencing.

The achievable output power is limited by the quantum conversion efficiency of optical light into THz and the Rydberg-atom population time scale. The ionization energy of Rb is 4.2 cV, hence the quantum efficiency at 150 GHz is 1.5×10⁻⁴. At a pump intensity of a several tens of mW cm⁻² and a pump cross section of 10 cm², one may expect several tens of micro-Watts of output in coherent, narrow-band THz radiation delivered into a diffraction-limited beam. At a location where the main radiation lobe covers 1 m², the THz electric field is on the order of 0.1 V/m, a value that is well above the sensitivity limit of Rydberg-EIT-based field sensing methods.

A reduction of EIT linewidth can be achieved via velocity-selective optical pumping within the entirety of the Rydberg-medium preparation volume and via multi-photon EIT for three-dimensional cancellation of Doppler effects.

In some embodiments, the lower masing levels in Rydberg masers can efficiently deplete through spontaneous decay, which is faster for lower-lying Rydberg states than for higher-lying ones. For example, it is possible to harvest THz emissions from an entire Rydberg cascade whose uppermost rung is the initially populated Rydberg level. This scheme would, obviously, increase the overall optical-to-THz energy conversion efficiency. Finally, in case the lower maser level is found to deplete too slowly to allow for cw THz emissions, the decay rate of the lower level of the Rydberg-maser transition can be accelerated by optical quenching. In this method, the lower Rydberg-maser level is coupled to 5P_{1/2} (in Rb) or 6P_{1/2} (in Cs) using a quenching laser. The atoms then rapidly decay via spontaneous emission on the D1 line into the ground state. The quenching laser would be an additional auxiliary laser introduced into the source (Tx) cell.

### THz Receiver

As shown in FIG. 46, Rydberg atom radio serve for both the generation and the detection of tunable, highly coherent THz radiation. On the source (Tx) side, the aforementioned strategies will allow maser-line narrowing, efficient use of the optically prepared Rydberg-atom medium, and the achievement of high THz power. Perfect matching of source and receiver (Rx) frequencies is an inherent advantage of atom-based THz technologies. Rx technology is based on Rydberg-EIT, Autler-Townes (AT) splitting, and high-field (Floquet) effects of the radiation in the atomic medium. As indicated, the Rydberg levels in the Rx cell are probed with a combination of EIT probe and coupler beams that have similar frequencies as the pump beams in the Tx cell. The absorption of the probe beam exhibits an EIT signal when the coupler is resonant with a Rydberg level (cascade EIT). Field-induced level shifts and AT splittings of the sensor Rydberg state are observed by scanning the coupler-laser frequency across the atomic Rydberg resonance and recording the probe transmission. The observed spectrum yields the radio-frequency (RF) electric field. In the present disclosure, this method of RF field sensing has been investigated and developed towards field-sensing devices and products. Here, for example, a THz Rx cell will be used to measure THz output from the Tx cell. The same strategies that allow for line narrowing and increase of coherence time and length of the THz radiation on the Tx component will also allow us to reduce the linewidth of the Rx component. In this way, the Rydberg Rx will effectively serve as an ideally-matched, narrow-band spectrum analyzer for the radiation emitted by the Tx.

It is noted that the Rydberg Tx and Rx cells (e.g., shown in FIG. 46), associated optics and THz components can be used and tested independently from each other. For instance, standard bolometric broadband THz sensors can be employed for initial verification of basic THz emission functionality of the atom-based Tx cell. Similarly, the functionality of the atom-based Rx cell can be verified by measuring THz emissions of a commercial THz source. Finally, while the proposed scheme focuses on implementations with a thermal vapor, cold/low-velocity atoms in a compact cavity architecture may also be considered and evaluated to reduce source linewidth, for example, depending on overall practical and performance trade-offs, as well as the near-term and long-term target performance objectives.

The present disclosure describes a THz source using Rydberg atoms for high-coherence THz signal generation and transmission (Tx) and a fully atomic transmit-receive (Tx-Rx) communication system. Performance metrics of interest include THz power, frequency, tuning range, and linewidth of Rydberg THz sources. Design and fabrication of vapor-cell Rydberg THz sources is included in the effort. Rydberg THz receivers (Rx), which are naturally matched in frequency with the sources, as both Tx and Rx utilize identical atomic transitions, and Rydberg THz Rx provide suitable frequency-matched sensitivities and dynamic range. The method and apparatuses have modulation capabilities, switching, etc. Other (non-atom) THz technologies include QCL, optical mixers, molecular lasers, and solid-state devices such as harmonic mixers. Critical aspects of interest, such as size, weight, and power, cost, operational capability, and basic survivability in adverse environments are described.

Cesium and other vapors can operate as the atomic masing medium, offering all operating modes in frequency coverage that are also afforded by Rubidium. The former is tunable over a wide frequency range (about 50 percent around a center frequency) at very low principal quantum number n (e.g. n˜13), where atomic interactions are minimized. The present disclosure describes THz source tuning via laser tuning and synchronous tuning of a cell-internal electric field. In addition, Cs sources run at a lower cell temperature than Rb, which reduces SWaP and complexity in the system.

In some embodiments, the laser design, largely shared between Tx and Rx, includes a relatively low-power 852-nm laser and two high-power systems around 530-nm and around 515-nm for two-photon optical pumping of the Rydberg maser. The frequencies of the green lasers can be selected based on suitable choices of THz frequency windows, for example, for the 140, 220, 340, and 410 GHz bands that have relatively low atmospheric loss. Higher-frequency bands including 650 and 850 GHz, which are also of interest, may also be accessed. The THz frequencies and the atomic spectrum then determine what is a good choice for the exact wavelength range of the green lasers. Specifically, the first green laser can be tunable around 515 nm and can allow access to Rydberg levels with the principal quantum number, n, of the upper THz maser level ranging from about n=20 to 35. The first laser can be designed to cover the lower range of the targeted spectrum (below about 250 GHz). The second green laser can be centered around 530 nm and can have a tuning range that can allow access to low Rydberg nD states for broadband-tunable THz masers on nD to (n+1) P transitions in the above −200 GHz range. In some embodiments, n can be about 13. The facts that at low n the absorption depth of the 530-nm light in the medium is much shorter than at high n, and that low-n Rydberg states experience less collisions and are less sensitive to stray electric fields, indicate good Rydberg maser operation at a higher atomic density and with a green field enhancement cavity with a lesser finesse. In some embodiments, breaching the 1-THz threshold is possible. These exemplify different architectures for Rydberg THz sources.

### Performance Metrics

One key metric is frequency. Since the Rydberg (sub-) THz bands provide near-continuous coverage, in state-dependent chunks, it will always be possible to select bands within atmospheric transmission windows. It is also noted that detailed research in the lower frequency range (140 GHz to 250 GHz) is highly valuable because atmospheric absorption generally is a less limiting factor at lower frequencies than it is at higher ones. As the frequency increases, absorption leads to a reduced spatial Tx range, higher cell-tower density in cellular networks and satellite signals, and increased importance of narrow-angle Tz and Tx (with increasingly complex phased arrays). Hence, one may surmise that the sub-THz range will not be disposable for a very long time (even if it is just to buy time for a push to 1 THz, which will take its time). Another key metric is tunability, which can be addressed in straightforward ways using Tx/Rx-synchronized Stark tuning using Rydberg vapor cell-internal structures.

Another metric is on modulation capabilities. The atom Tx may generate pulsed, AM, FM, FSK, PSK, QAM, FHSS, and other modulated waveform and signal transmissions. On the Tx side, the maser pump and emission dynamics is not restricted by the natural decay behavior, and stimulated emission and maser pump time scales are not limited by potentially long natural atomic decay times. Modulation methods include optical maser pump AM and FM (for example), as well as maser level (Rydberg-state) modulation using RF fields (IF range from near DC into the hundreds of MHz range) for modulation of Rydberg Tx in the sub-THz-and-above range. On the Rx side, demodulation via Rydberg-EIT can be utilized, but limited in IF frequency range due to EIT dynamics (which is latched onto the intermediate-state decay rate). Novel approaches involving fast coherent dynamics and transients, which are de-coupled from natural atomic-decay time scales, are also possible.

An atom radio transmission, receiver, or transceiver system, systems, communications links, or networks can be comprised of one or multiple atom radio apparatuses, or derived, or incorporate key subsystems or components of such apparatuses, such as Rydberg laser systems and atomic vapors or gas cells, or atomic references for Rydberg laser stabilization and operation. As such they can also be comprised of atom radio and non-atom radio systems such as a communication link between a base station antenna and an atom radio or a satellite transmission to an atom radio apparatus.

### High-Power Visible Laser Systems

Quantum sensor technologies such as atomic clocks, inertial, gravity, and electromagnetic sensors are exceeding the capabilities of their classical counterparts and driving a paradigm shift in sensing, measurement, navigation, and timing. Quantum sensing of radio-frequency (RF) signals using Rydberg atoms is an emerging technology platform that stands to revolutionize a broad range of dual-use RF applications including metrology, test and measurement, communications, radar, surveillance and security. The novel properties of quantum RF sensors directly impact the quantum technology focus area, but will also provide significant capability impact in the electronic warfare, 5G/6G, and commercial leap ahead technology areas.

There is a critical capability gap in domestic design and fabrication of high-power narrow-linewidth visible laser chips, which are required for quantum RF systems and other existing and future quantum technologies. One of the largest leaps in reducing SWAP-C for deployment of quantum RF systems in harsh environments in defense applications and their broader commercialization will come from the development of high-power narrow-linewidth laser sources at visible wavelengths at 510 nm for cesium Rydberg atoms and 480 nm for rubidium Rydberg atoms. The state of the art power output of narrow-linewidth diodes at these and similar wavelengths in the VIS remains at or below the 10 mW level, while greater than 100 mW levels are required for quantum RF and other QIS applications. At present there is a need for such VIS laser chips or systems that meet the required performance specifications. There is an immediate need in the broader quantum technology industry for a source or system of narrow linewidth lasers at visible wavelengths with higher average power that exist today that are optionally tunable and usable in harsh environments out of labs well as in the labs.

To address this capability gap, the present disclosure describes single-mode laser diodes at 510 nm and 480 nm that can operate continuous-wave (CW) at powers up to several hundred milliWatt. The critical wavelengths in the visible are accessible to GaN material systems requiring specific stoichiometry of the GaN system to achieve high power at the wavelengths of need. GaN foundries can support all manufacturing of single chips. The diodes are packaged into a micro-integrated external-cavity diode laser assembly (and or including photonically-integrated circuits), and integrated with atom or atom-optical/photonic integrated circuit subsystems for visible and IR laser frequency-stabilization, frequency tuning, and atomic referencing, for the system and Rydberg atom excitation, spectroscopy, or quantum technology.

Optical devices and classical “microchips” for the realization of deployable low size, weight, and power and cost atom quantum RF sensors and other quantum sensing devices and technologies are described. Specifically, new visible laser sources and atom-photonic integrated circuits to realize deployable and scalable quantum RF sensor systems are also described. Systems, subsystems, and components may include: (1) high-power (>200 mW) single-mode narrow linewidth (<10 kHz) visible semiconductor laser diodes and integrated tunable micro-lasers at 510 nm (for cesium) and 480 nm (for rubidium), (2) atom-photonic circuits for 510 nm and 480 nm VIS and IR laser frequency stabilization and absolute referencing to atomic wavelength standards, (3) photonic waveguides for wavelength/frequency tracking and narrow-linewidth laser tuning that can cover ranges from 1 GHz up to several nanometers, (4) an integrated monolithic quantum RF device with state-of-the-art size, weight, and power (SWaP) with <10 liter volume, and (5) capable of operation/RF signal transmission/reception in a harsh environment on a moving platform on land, sea, air, or space.

FIG. 18 shows an example embodiment of an integrated Rydberg atom quantum RF system and the Rydberg laser subsystems in a micro-integrated multi-module/chip platform, optionally including one or more photonic circuits for special active/passive functions, for Rydberg atom quantum technologies. In this embodiment, a semiconductor (GaN) high-power (>100 mW) VIS 480 nm and 510 nm laser source (FIG. 18, inset shows wavelength) with an internal feedback (e.g. DFB chip) or external feedback (e.g. external cavity diode laser (ECDL) including cat-eye, or injection locking) for narrow linewidth (<10 MHZ) and wavelength tunability (>1 GHz to nanometers), as well as atomic gas units for laser-frequency stabilization/referencing/locking.

### Micro-Integrated Modules for Rydberg Spectroscopy

Lasers and optical frequency references stabilized to atomic vapors promise to be key subsystem of compact fieldable optical atomic clocks and quantum sensors, driving the rapid advancement of compact optical frequency references and underlying laser, atomic, and stabilization technologies. The present disclosure describes a prototype absolute frequency referenced 852 nm laser module using a compact micro-integrated cat-eye external cavity diode laser (ECDL) and precision cesium atomic vapor spectroscopy for absolute frequency stabilization. Excluding control electronics and signal processing, the present disclosure describes a laser-module size, weight, and power below 50 cm³, 100 g, and 1 W power consumption, respectively, and a frequency instability reaching 10⁻¹¹ Hz at 1 second averaging time or better. Compared to other approaches the disclosed module architecture aims to improve performance of compact optical frequency references in harsh environments, increase adaptability for integration with sensor systems, and reduce module complexity in assembly and fabrication towards scalable manufacturing. Generally, systems such as these require high-quality temperature stabilization and magnetic-field shielding, next to superior overall design.

The present disclosure describes a micro-integrated/PIC laser system with cesium atoms that can be operated without laser frequency modulation if so desired, that employs a cat-eye ECDL architecture, a design known for excellent passive linewidth, and that allows a choice of several types of spectroscopic measurement modes. The threshold-level line width and long-term drift is 3.5 kHz with the SWaP parameters listed above (e.g., volume=50 cm³, mass=100 g, power=1 W), which are for the laser module excluding control electronics and signal processing. Vibration stability of the laser module is critical. The present disclosure incorporates laser technology, electronics, miniature optical systems assembly and fabrication, and in-house fabrication of miniature spectroscopic vapor cells (including cesium and rubidium). Further, the module has an option for tuning using a MEMS or similar actuation of the filter element for electronic control of wavelength tuning (up to nanometers) and frequency scans (typically in Hz to GHz ranges), as well as laser power, subsystem thermal and mechanical stabilization.

Generally, the micro-integrated referenced laser module is assembled in a three-dimensional micro-machined structure, assembly of micro-machined structures, sub-assembly or assembly of microstructures and components that have a smaller size, improved performance, and better reliability than many other laser sources. Typical sizes of Rydberg sensors, photonic modules, and quantum sensors can range from one micron to hundreds of millimeters. Micro-integrated and photonic modules and atomic quantum sensors incorporate a set of hardware sub-systems including micro-integrated lasers, light sources, electro-optical (EQ) systems, micro-electromechanical (MEMS) devices, optical frequency stabilization, scanning, switching, and tuning systems, and compact atomic vapor cells and references, with packaging, analog and digital electronics, and software.

FIG. 9A shows a block diagram of one embodiment of a micro-integrated, compact atomic frequency-stabilized Rydberg (852 nm) laser module. The micro-integrated module is comprised of four primary subsections: (1) Sub-module L: a micro-integrated cats-eye external cavity diode laser including an 852 nm diode, a cats-eye reflector external cavity for optical feedback and linewidth-narrowing, an intra-cavity tuning (interference) filter for wavelength selection, beam shaping optics, and micro-isolator, (2) Sub-module C: a micro-integrated vapor-cell spectroscopy unit including a miniature insulated cesium vapor cell with an integrated miniature solenoid for magnetic field generation and a magnetic shield housing cell and solenoid, polarization optics, mirrors, Peltier elements and thermistors for optional active temperature stabilization, and photodetectors in a EMI-shielded enclosure-configurable for polarization spectroscopy, saturation spectroscopy, or Zeeman-modulation spectroscopy, (3) Sub-module O: integrated optical distribution optics for routing the free-space laser light to the atomic reference and output fiber coupling of the stabilized 852 nm light, and (4) Sub-module X: optional light routing to external peripherals such as external electro-optic modulators, wavemeters, etc. Additional components not showns in the figure can include gain stage (tapered amplifier/MOPA), frequency multiplying (PPLN frequency doubler), optical isolators, etc.

The module architecture shown in FIG. 9A has several anticipated benefits compared to other lasers and optical references. A primary benefit comes in using a cats-eye ECDL architecture (sub-module L) which takes advantage of the well-established high mechanical stability of its self-aligning external cavity design compared to grating-based external cavity laser architectures, combined with improved optical feedback efficiency and linewidth narrowing of an ECDL compared to chip-scale grating lasers such as DBR that suffer from greater intrinsic linewidths. The cats-eye ECDL also benefits from a linear form factor which is amenable to substantial size reduction and micro-integration, as well as flexibility in coarse wavelength tuning and selection over nanometers using only a passive interference filter element. Another benefit of the proposed module architecture is the integration of a cesium atomic vapor reference (sub-module C) with the cats-eye ECDL, which provides inherently drift-free (absolute) frequency stabilization on an atomic transition at near room temperature and in a small package. This is preferred to other (non-atomic) references such as optical cavities which are intrinsically susceptible to drift. In this architecture, atomic polarization spectroscopy also provides the notable advantage of being able to achieve sub-kHz frequency stabilization with a large lock capture range, comparably low-power consumption, all with no direct laser modulation, compared to optical references requiring direct frequency modulation of the laser for stabilization to atomic lines. The architecture of the polarization spectroscopy sub-module is also readily adaptable between Doppler-free polarization spectroscopy, saturation spectroscopy, Zeeman-modulation spectroscopy, or even optical modulation spectroscopy with an external optical modulator, for example, using the external optics routing (sub-module X) on the board. This provides flexibility with the module to implement different atomic spectroscopy frequency stabilization methods for target applications and system integration. In total, the laser module is customizable between at least four modes of saturation spectroscopy that address differing needs. The configuration selection for individual customers occurs via the final placement of one or two optical elements in sub-module C in the final assembly phase.

The (Rydberg) atomic reference in the laser systems provides one or more of the following functions for the laser and atom radio/system operations: (1) provides a laser-frequency lock to an atomic spectral line or feature such as saturation spectroscopy, polarization spectroscopy, as well as field-modulated spectroscopy.

### Laser Frequency-Stabilization in Rydberg Atom Radio and Laser Modules

Laser stabilization methods (e.g., for 852-nm laser stabilization) incorporated into the systems may include one or more of the following:
(1) Saturation spectroscopy. In basic saturation spectroscopy of two-level transitions, dating back into the early years of laser spectroscopy, a pump beam saturates a velocity class of an atomic-vapor medium, while a counter-propagating probe beam reads out lower versus upper-level populations at the opposite velocity (velocities measured relative to beam propagation directions). Reduced absorption, known as Lamb dip, occurs at zero velocity. The method ideally yields a Lorentzian feature with a line width given by the homogeneous linewidth, which is about 6 MHz wide in Cs and Rb and therefore much narrower than the 1-GHz Doppler-broadened linewidth. The scheme readily translates to atoms with multiple hyperfine peaks, where strong cross-over transitions occur. Saturation spectroscopy can be widely employed to lock lasers. The advantage of saturation spectroscopy relies in simplicity, as this is the most basic saturation scheme. Lasers are locked using what is well-known as a ‘side lock.’ It offers a wide-bandwidth lock, as no intermediate modulation of lasers, polarizations or magnetic fields are required, nor does it require a polarization or polarization-rotation analysis of the probe beam. The method is prone to frequency drifts of the lock point due to pressure drifts, laser-intensity drifts, background-light drifts etc. While these shortcomings are typically alleviated to a large extent measuring the difference of a pair of probe beams-one with and one without a counter-propagating pump-experience shows that such drifts are somewhat unpredictable, their complete elimination can become quite hard. Other methods, discussed next, typically win out when unconditional reliability is required.
(2) Polarization spectroscopy. In this method, applicable to atoms with a magnetic substructure such as Cs and Rb, a circularly polarized pump introduces circular dichroism, or birefringence for the circular components of the probe light. This leads to a polarization rotation of the probe that is symmetric about the line center. It is read out by a crossed-polarizer readout of the probe, or, better, by measuring polarization rotation by passing the probe through a balanced differential-detection analyzer (which can be a half-wave plate followed by a polarizing beam cube with two photodiodes at the exit ports). The method yields a dispersive error signal centered near the transition center, it is cw and high bandwidth, as no modulation is required, and it works well on the cycling transitions (which are weak in method 1). It is still prone to frequency drifts of the lock point, as a variety of instabilities can simply cause the error signal to drift up or down, causing the lock point to move left or right in the frequency axis.
(3) FM saturation spectroscopy. This method is, optically, equivalent to method 1, but the laser is frequency-modulated, and the probe is demodulated in a typical phase-sensitive manner on the fundamental of the modulation signal using a lock-in. The lock-in output is dispersive. A differential setup with a two probe beams-one with and one without a counter-propagating pump—is unnecessary. In addition, the lock point is stable to all the drifts that plague methods (1) and (2). Method (3) can be hard-wired into a range of commercially available laser drives (as are methods (1) and (2)). A drawback of the method relies in the fact that there is loss in PID (servo) lock bandwidth, as the lock bandwidth is somewhat less than the FM frequency. As the FM can be made quite fast (on the order of 1 MHZ) by modulating laser current or by using an AOM or an EOM, the lock bandwidth can still easily be hundreds of kHz, which is fast enough for all but the most frontier applications. Another drawback of FM spectroscopy for the application of laser locking is that the laser light is FM-modulated, if one chooses FM modulation by laser-current modulation. Laser-current modulation is the simplest and cheapest method of diode-laser FM, and it is often chosen for these reasons. Finally, parasitic intensity modulation that may occur when FM-modulating the laser (or the laser beam) shifts the lock point and causes frequency drifts.
(4) Modulation transfer spectroscopy. This method is similar to method (3), the difference being that only the pump is modulated, while the probe is not modulated. An advantage of this method over method (3) is that the effect of parasitic intensity modulation, a possible side effect of laser or laser-beam FM, is greatly reduced. In addition, since both a modulated and an unmodulated beam are needed, laser-current modulation cannot be used to implement the FM. This is an advantage in applications that require the main portion of the laser light to remain unmodulated as would be preferred in Rydberg lasers for Rydberg atom radio and radar.
(5) Zeeman modulation methods. These methods are similar to polarization rotation spectroscopy method (2) in that a dispersive error signal is generated by circular birefringence. The birefringence is generated by an FM-modulated longitudinal magnetic field. Demodulation of the probe signal from a balanced differential probe analyzer yields a dispersive error signal. This method shares most features of method 3, but the laser remains entirely unmodulated. In addition, a weak RF magnetic field is lower-SWaP and lower-cost than light modulation with an AOM or EOM.
(6) Dichroic Atomic Vapor Laser Lock (DAVLL) system. Sub-Doppler implementations are somewhat similar to polarization rotation spectroscopy method (2), but it employs all linearly polarized pump and probe beams, while a differential behavior for the circular components of the light is introduced via a weak longitudinal magnetic field. A probe analyzer measures the dichroism by taking the difference in absorption via a balanced differential-detection analyzer, which consists of a quarter-wave plate followed by a polarizing beam cube with two photodiodes at the exit ports. The method yields a dispersive signal without requiring any FM (or time dependence). It therefore can have a higher lock bandwidth than FM methods, but the error signal is susceptible to lock point drifts.

### Atomic Frequency Stabilization of the Coupler Laser

In two-photon Rydberg-EIT, counter-propagating probe and coupler lasers are passed through a vapor cell. Assuming the probe (852-nm) laser is already locked to sub-100 kHz using a method from the laser stabilization methods described above, the coupler (510-nm) laser is scanned to obtain an EIT line shape at the Rydberg resonance that is also being used for RF reception. The width of the EIT line is similar to typical lines used for locking the 852-nm laser; hence similar PID laser-locking methods can be used. Dispersive error signals suitable for locking (and also tuning) the coupler laser are achieved by methods and devices including one or more of the following:
(1) FM-modulating the probe light passed through the EIT cell and demodulating the probe-beam power at the fundamental using a lock-in amplifier. The lock-in output serves as an error signal that has a dispersive line shape as a function of coupler laser frequency. It is centered in the middle of the EIT line. Since the method is an FM technique, it is robust against various drifts (beam powers, cell temperature etc.) that can be hard to avoid without additional active stabilization. The coupler laser can then be locked using PID servo loops that are similar to those in FM-locking the 852-nm laser. This method can be employed by the Rydberg atomic vapor cell apparatus such as the one described in FIG. 20 and FIG. 21.
(2) Optical-frequency stabilization via Rydberg atom (Stark) field modulation spectroscopy. Stark modulation spectroscopy via AM/PM/FM-modulating an electric field applied to the inside of the EIT reference cell while fixed-frequency probe light is passed through the EIT cell. The field applied to the Rydberg atoms in cell then has the form, for example, E=E_{DC}+E_{AC} cos(ωt). The DC component (or low-frequency AC) is used to Stark-tune the lock point to a frequency that can be offset from the field-free EIT line by amounts up to about one GHz. This feature tunes the RF field sensor to the exact RF frequencies and operating points of interest, with a continuous RF tuning range around the Rydberg resonance exceeding 1 GHz. The AC component of the electric field, E_{AC}, leads to a low-amplitude oscillation of the EIT line viewed as a function of couple laser frequency (oscillation amplitude typically less than the EIT linewidth). The oscillation vanishes and flips phase at certain coupler laser frequencies. Hence, the EIT probe signal, demodulated at the electric-field modulation frequency, has a dispersive shape. The EIT coupler laser can then be locked on the dispersive shape, resulting in a stable and tight coupler-laser FM lock with a lock point that is tunable via E_{DC}. Since the Stark shift is quadratic, for certain ratios of E_{AC} relative to E_{DC} the demodulation may have to occur at the second harmonic of the field modulation frequency, with all other parts of the lock circuit remaining unchanged. This method can be employed by the Rydberg atomic vapor cell apparatus such as the one described in FIG. 20 and FIG. 21.
(3) In addition to the FM and Stark-modulation spectroscopy stabilization approaches described above, other laser-stabilization and locking schemes can be implemented with the atomic reference cells and units such as those shown in FIG. 20 and FIG. 21, that has a compact form factor and robustness for integration into lasers and atom/quantum systems and for deployment on sea, land, air and space platforms and flight missions.
(4) Optimized frequency-stabilization of a electronically-tunable micro-integrated frequency-doubled 1020 nm Rydberg 510 nm laser or photonic laser in vibration environments incorporates temperature control and phase matching on the doubling stage, where fluctuations of second harmonic generation may bring some challenges to stabilizing the amplified fundamental 1020 nm laser. Lookup tables relating laser wavelength and temperature set-points for example, automated maintenance cycles that recalibrate the tables as needed, etc. for example are implemented. The instantaneous bandwidth of a typical lithium niobate non-linear crystal is wide enough to allow for fast RF frequency spread-spectrum protocols in atom radios; large RF frequency hops can utilize look-up tables or feedback loops on component parameters. Additional real-time active feedback from subsystem monitoring sensors such as power monitoring photodiodes and thermistors on hardware components, as well as from signal readouts of error signals and spectrum behaviors for monitoring optical harmonic content etc. provide additional stability.
(5) In addition to FM and Stark-modulation spectroscopy stabilization approaches, other laser-stabilization and locking schemes combined with the Rydberg laser system, or components thereof, provide high frequency stability, accuracy (low drift), as well as hardware scalability to low size and compact form factor for deployment. Alternative laser-stabilization approaches with a Rydberg laser system include similar techniques to those described above for 852-nm-laser stabilization, such as polarization spectroscopy and modulation transfer spectroscopy but with Rydberg states and spectra instead of low-lying atomic states and spectra such as D1 and D2 lines in alkali atoms, for example.

The present disclosure describes compact 852 nm probe and 510 nm coupler Rydberg laser architectures that provide fixed-frequency and wavelength tunability and switching over nanometers to access Cs Rydberg states within a range of principal quantum numbers, for example, from below n=30 extending to above n=70, and absolute frequency-stabilization of the lasers to target nS or nD Rydberg atom quantum states for signal reception on on and off resonant Rydberg transitions in K-band (e.g. 20.7 GHZ resonant 33D to 34P transition) and S-band (e.g. 2.38 GHz 66D to 67P transition) with a residual laser-frequency noise of 100 kHz or below. The present disclosure describes an optimized frequency-stabilization subsystem for Rydberg atom quantum technologies.

It is noted that the two-photon Rydberg laser and frequency-stabilization architecture described can be readily extended to Rydberg laser subsystems with three-photon and other multi-photon Rydberg EIT approaches for Rydberg atom quantum technologies and sensing as well as multi-photon Rydberg EIT schemes for other atoms such as rubidium, all of which require similar wavelength tuning and frequency-stability performance of at least one coupler laser.

It is to be understood that the phraseology or terminology herein is for the purpose of description and not of limitation, such that the terminology or phraseology of the present specification is to be interpreted by those skilled in relevant art(s) in light of the teachings herein.

The following examples are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific embodiments have been described above, it will be appreciated that the embodiments may be practiced otherwise than as described. The description is not intended to limit the scope of the claims.

It is to be appreciated that the Detailed Description section, and not the Summary and Abstract sections, is intended to be used to interpret the claims. The Summary and Abstract sections may set forth one or more but not all exemplary embodiments as contemplated by the inventor(s), and thus, are not intended to limit the embodiments and the appended claims in any way.

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the embodiments that others can, by applying knowledge within the skill of the art, readily modify and/or adapt for various applications such specific embodiments, without undue experimentation, without departing from the general concept of the embodiments. Therefore, such adaptations and modifications are intended to be within the meaning and range of equivalents of the disclosed embodiments, based on the teaching and guidance presented herein.

The breadth and scope of the embodiments should not be limited by any of the above-described exemplary embodiments, but should be defined only in accordance with the following claims and their equivalents.

The present invention may also be described in accordance with the following clauses:

Clause 1. An atom radio apparatus comprising:
a compartment enclosing a gas of atoms in one or more excited states, wherein the gas of atoms is configured to receive and/or transmit an electromagnetic radio signal;
a conduit coupled to the compartment and configured to transport electromagnetic, optical, or electronic signals to and/or from the gas of atoms;
a front-end coupled to the conduit and configured to generate and transmit an input electromagnetic, optical, or electronic signal to and/or receive an output electromagnetic, optical, or electronic signal from the gas of atoms;
a controller configured to adjust a parameter of the electromagnetic, optical, or electronic signal in the front-end sent to or received from the gas of atoms;
a signal processor connected to the front-end and configured to process electromagnetic, optical, or electronic input and output signals to and from the front-end; and
a user interface and computer configured to control or monitor control signals, input signals, or output signals from the signal processor, controller, front-end, conduit, compartment, or the gas of atoms.

Clause 2. The atom radio apparatus of clause 1, wherein an input electromagnetic signal comprises a plurality of input electromagnetic signals.

Clause 3. The atom radio apparatus of clause 1 or clause 2, wherein the input signal comprises an electronic voltage signal, an electronic current signal, or an electromagnetic signal.

Clause 4. The atom radio apparatus of clause 3, wherein the electromagnetic signal comprises an optical signal, a radio-frequency (RF) signal, a static field (DC) signal, a modulated signal, or a combination thereof.

Clause 5. The atom radio apparatus of any one of clauses 1 to 4, wherein the conduit comprises an electrical cable, a fiber optics cable, a conductor, a waveguide, a mode for free-space electromagnetic wave propagation, or a combination thereof.

Clause 6. The atom radio apparatus of any one of clauses 1 to 5, wherein the front-end comprises at least one of a photonic circuit, a light source, a frequency-stabilized laser, an isolator, a modulator, an amplifier, a frequency doubler, DC electronics, RF electronics, an atomic gas cell, a signal generator, a voltage-controlled oscillator, optics, a frequency comb, or a light detector.

Clause 7. The atom radio apparatus of clause 6, wherein the light detector comprises a silicon photodetector.

Clause 8. The atom radio apparatus of any one of clauses 1 to 7, wherein the input signal generated by the front-end and transmitted to the gas of atoms comprises a local oscillator (LO) signal.

Clause 9. The atom radio apparatus of any one of clauses 1 to 8, wherein electromagnetic, optical, or electronic signals in the conduit from the atoms comprise an atomic response of the gas of atoms to one or more electromagnetic radio signals or electromagnetic waves.

Clause 10. The atom radio apparatus of any one of clauses 1 to 9, wherein the input signal generated by the front-end and transmitted to the gas of atoms is an electromagnetic, optical, or electronic signal that comprises an electromagnetic radio signal.

Clause 11. The atom radio apparatus of any one of clauses 1 to 10, wherein the electromagnetic radio signal received and/or transmitted by the gas of atoms has a frequency from static field (DC) to terahertz (THz).

Clause 12. The atom radio apparatus of any one of clauses 1 to 11, wherein an electromagnetic radio signal is received and/or transmitted by the gas of atoms.

Clause 13. The atom radio apparatus of any one of clauses 1 to 12, wherein the transmitted electromagnetic radio signal from the gas of atoms comprises:
a tuned or modulated electromagnetic radio signal; and
an RF field, local oscillator (LO) reference field, and/or an optical field.

Clause 14. The atom radio apparatus of any one of clauses 1 to 13, further comprising an interface for input and output of signals to and from a radio operator or other system integrated with the atom radio.

Clause 15. The atom radio apparatus of any one of clauses 1 to 14, further comprising a system for tuning the received or transmitted signal.

Clause 16. The atom radio apparatus of any one of clauses 1 to 15, wherein the system for tuning comprises a widely tunable laser for Rydberg spectroscopy.

Clause 17. The atom radio apparatus of any one of clauses 1 to 16, wherein the widely tunable laser comprises a photonic integrated circuit configured to stabilize, tune, or switch a wavelength, a phase, a frequency, an amplitude, a power, a polarization, or a combination thereof of the light beam.

Clause 18. The atom radio apparatus of any one of clauses 1 to 17, wherein the widely tunable laser comprises a controller configured to adjust the wavelength, the frequency, the amplitude, the power, the phase, the polarization, or a combination thereof of the light beam.

Clause 19. The atom radio apparatus of any one of clauses 1 to 18, wherein the widely tunable laser comprises a micro-electro-mechanical systems (MEMS) element configured to tune the wavelength, the frequency, or a combination thereof of the light in the photonic integrated circuit.

Clause 20. The atom radio apparatus of any one of clauses 1 to 19, wherein the MEMS element comprises an integrator heator, a piezoelectric actuator, or a combination thereof.

Clause 21. The atom radio apparatus of any one of clauses 1 to 20, wherein the widley tunable laser comprises an atomic reference, an optical-cavity reference, or a combination thereof.

Clause 22. The atom radio apparatus of any one of clauses 1 to 21, wherein the atomic reference, the optical-cavity reference, or the combination thereof is configured to stabilize or lock the widely tunable laser.

Clause 23. The atom radio apparatus of any one of clauses 1 to 22, further comprising an atomic reference, an optical-cavity reference, or a combination thereof.

Clause 24. The atom radio apparatus of any one of clauses 1 to 23, wherein the atomic reference, the optical-cavity reference, or the combination thereof is configured to stabilize or lock one or more lasers of the atom radio.

Clause 25. The atom radio apparatus of any one of clauses 1 to 24, wherein the atom radio apparatus is coupled to an antenna radio, a base station, a satellite, an airplane, a ship, a submarine, a mobile phone, a radio, a computer, an RF signal transmitter, an RF signal receiver, an RF signal transceiver, or a combination thereof.

Clause 26. The atom radio apparatus of any one of clauses 1 to 25, wherein the atom radio apparatus is configured for deployment on sea, land, air, flight missions, space platforms, or a combination thereof.

Clause 27. A radio communication system comprising:
a first atom radio apparatus;
a second atom radio apparatus operatively coupled to the first atom radio apparatus;
a first communication signal transmitted from the first atom radio apparatus and received by the second atom radio apparatus;
a second communication signal transmitted from the second atom radio apparatus and received by the first atom radio apparatus; and
a system for synchronizing the first and second radio apparatuses.

Clause 28. The radio communication system of clause 27, wherein the system for synchronizing the first and second radio apparatuses comprises a clock signal, an atomic clock signal, a GPS signal, or a combination thereof.

Clause 29. The radio communication system of clause 27 or clause 28, wherein the second atom radio apparatus is coupled to an antenna radio, a base station, a satellite, an airplane, a ship, a submarine, a mobile phone, a radio, a computer, an RF signal transmitter, an RF signal receiver, or an RF signal transceiver.

Clause 30. The radio communication system of any one of clauses 27 to 29, wherein at least one of the first and second atom radio apparatuses operates at below HF-band, HF-band, VHF-band, UHF-band, EHF-band, above EHF-band, or a combination thereof.

Clause 31. An electronically-controlled frequency-agile cat-eye laser comprising:
a laser diode configured to generate a light beam;
a lens configured to shape and transmit the light beam;
an interference filter configured to filter the light beam;
a micro-electro-mechanical systems (MEMS) actuator coupled to the interference filter and configured to tune the wavelength of the light;
a cat-eye reflector configured to feedback to the laser, stabilize and scan the laser frequency;
a piezoelectric actuator coupled to the cat-eye reflector;
an electronic signal to control the interference filter for wavelength tuning and piezoelectric actuator for cavity scans; and
a light conditioning element.

Clause 32. The cat-eye laser of clause 31, wherein the light conditioning element comprises an isolator, an amplifier, a non-linear crystal, a modulator, an atomic reference, a cavity reference, a photonic integrated circuit, or a combination thereof.

Clause 33. The cat-eye laser of clause 31 or clause 32, wherein components of the cat-eye laser are micro-integrated.

Clause 34. The cat-eye laser of any one of clauses 31 to 33, wherein the light beam of the laser diode has:
a wavelength spanning from 100 nm to 10 microns; and
an optical power spanning from 1 nW to 50 mW.

Clause 35. The cat-eye laser of clause 34, wherein the wavelength of the light beam comprises 852 nm, 780 nm, 510 nm, and 480 nm.

Clause 36. The cat-eye laser of any one of clauses 31 to 35, wherein the laser diode is stabilized to a linewidth of 10 MHz or smaller.

Clause 37. The cat-eye laser of any one of clauses 31 to 36, wherein the MEMS actuator displaces or rotates the interference filter electronically based on the electronic control signal.

Clause 38. The cat-eye laser of any one of clauses 31 to 37, wherein a wavelength and a frequency of the light beam is tuned or changed electronically using the piezoelectric actuator, a voltage or current of the laser diode, the MEMS actuator, or a combination thereof.

Clause 39. A widely tunable laser for Rydberg spectroscopy, the laser comprising:
a light source configured to generate a light beam;
a photonic integrated circuit configured to stabilize, tune, or switch a wavelength, a phase, a frequency, an amplitude, a power, or a polarization of the light beam;
a controller configured to adjust the wavelength, the frequency, the amplitude, the power, the phase, or the polarization of the light beam;
one or more optical isolators to reduce optical feedback;
an optical amplifier configured to amplify or generate light power;
a non-linear crystal configured to double or change the light frequency;
an optical modulator configured to modulate the phase, frequency, amplitude, or direction of the light;
an atomic reference or an optical-cavity reference; and
a micro-electro-mechanical systems (MEMS) element configured to tune the wavelength or the frequency of the light in the photonic integrated circuit.

Clause 40. A micro-integrated module for Rydberg excitation, spectroscopy, and quantum technology, the module comprising:
a light source configured to generate a light beam;
a micro-electro-mechanical systems (MEMS) device or an electro-optical device configured to stabilize, tune, or switch a wavelength, a frequency, an amplitude, a power, or a polarization of the light beam;
a controller configured to adjust the wavelength, the frequency, the amplitude, the power, or the polarization of the light beam;
one or more optical isolators;
an optical amplifier;
a non-linear crystal;
an optical modulator;
an atomic reference or an optical-cavity reference; and
a micro-electro-mechanical systems (MEMS) tuning element.

What is claimed is:

1. An atom radio apparatus comprising:
a compartment enclosing a gas of atoms in one or more excited states, wherein the gas of atoms is configured to receive and/or transmit an electromagnetic radio signal;
a conduit coupled to the compartment and configured to transport electromagnetic, optical, or electronic signals to and/or from the gas of atoms;
a front-end coupled to the conduit and configured to generate and transmit an input electromagnetic, optical, or electronic signal to and/or receive an output electromagnetic, optical, or electronic signal from the gas of atoms;
a controller configured to adjust a parameter of the electromagnetic, optical, or electronic signal in the front-end sent to or received from the gas of atoms;
a signal processor connected to the front-end and configured to process electromagnetic, optical, or electronic input and output signals to and from the front-end; and
a user interface and computer configured to control or monitor control signals, input signals, or output signals from the signal processor, controller, front-end, conduit, compartment, or the gas of atoms.

2. The atom radio apparatus of claim 1, wherein an input electromagnetic signal comprises a plurality of input electromagnetic signals.

3. The atom radio apparatus of claim 1, wherein the input signal comprises an electronic voltage signal, an electronic current signal, or an electromagnetic signal.

4. The atom radio apparatus of claim 3, wherein the electromagnetic signal comprises an optical signal, a radio-frequency (RF) signal, a static field (DC) signal, a modulated signal, or a combination thereof.

5. The atom radio apparatus of claim 1, wherein the conduit comprises an electrical cable, a fiber optics cable, a conductor, a waveguide, a mode for free-space electromagnetic wave propagation, or a combination thereof.

6. The atom radio apparatus of claim 1, wherein the front-end comprises at least one of a photonic circuit, a light source, a frequency-stabilized laser, an isolator, a modulator, an amplifier, a frequency doubler, DC electronics, RF electronics, an atomic gas cell, a signal generator, a voltage-controlled oscillator, optics, a frequency comb, or a light detector.

7. The atom radio apparatus of claim 6, wherein the light detector comprises a silicon photodetector.

8. The atom radio apparatus of claim 1, wherein the input signal generated by the front-end and transmitted to the gas of atoms comprises a local oscillator (LO) signal.

9. The atom radio apparatus of claim 1, wherein electromagnetic, optical, or electronic signals in the conduit from the atoms comprise an atomic response of the gas of atoms to one or more electromagnetic radio signals or electromagnetic waves.

10. The atom radio apparatus of claim 1, wherein the input signal generated by the front-end and transmitted to the gas of atoms is an electromagnetic, optical, or electronic signal that comprises an electromagnetic radio signal.

11. The atom radio apparatus of claim 1, wherein the electromagnetic radio signal received and/or transmitted by the gas of atoms has a frequency from static field (DC) to terahertz (THz).

12. The atom radio apparatus of claim 1, wherein an electromagnetic radio signal is received and/or transmitted by the gas of atoms.

13. The atom radio apparatus of claim 1, wherein the transmitted electromagnetic radio signal from the gas of atoms comprises:
a tuned or modulated electromagnetic radio signal; and
an RF field, local oscillator (LO) reference field, and/or an optical field.

14. A radio communication system comprising:
a first atom radio apparatus;
a second atom radio apparatus operatively coupled to the first atom radio apparatus;
a first communication signal transmitted from the first atom radio apparatus and received by the second atom radio apparatus;
a second communication signal transmitted from the second atom radio apparatus and received by the first atom radio apparatus; and
a system for synchronizing the first and second radio apparatuses.

15. The radio communication system of claim 14, wherein the system for synchronizing the first and second radio apparatuses comprises a clock signal, an atomic clock signal, a GPS signal, or a combination thereof.

16. The radio communication system of claim 14, wherein the second atom radio apparatus is coupled to an antenna radio, a base station, a satellite, an airplane, a ship, a submarine, a mobile phone, a radio, a computer, an RF signal transmitter, an RF signal receiver, or an RF signal transceiver.

17. The radio communication system of claim 14, wherein at least one of the first and second atom radio apparatuses operates at below HF-band, HF-band, VHF-band, UHF-band, EHF-band, above EHF-band, or a combination thereof.
